(19) United States
(12) Patent Application Publication
(10) Pub. No.: US 2024/0359372 A1
(43) Pub. Date: Oct. 31, 2024

(54) METHOD OF FABRICATING MOLDS FOR FORMING WAVEGUIDES AND RELATED SYSTEMS AND METHODS USING THE WAVEGUIDES

(71) Applicant: Magic Leap, Inc., Plantation, FL (US)

(72) Inventors: Shuqiang YANG, Austin, TX (US); Vikramjit SINGH, Pflugerville, TX (US); David James LENTZ, Leander, TX (US); Frank Y. XU, Austin, TX (US); Marlon Edward MENEZES, Austin, TX (US); Yanhua WANG, Austin, TX (US)

(21) Appl. No.: 18/686,440

(22) PCT Filed: Aug. 17, 2022
(86) PCT No.: PCT/US22/40625

§ 371 Date: Feb. 26, 2024

Related U.S. Application Data
(60) Provisional application No. 63/238,057, filed on Aug. 27, 2021.

(51) Int. Cl. B29C 43/02; B29C 33/42; B29C 43/40; B29L 11/00

(52) U.S. Cl. CPC B29C 43/021; B29C 33/424; B29C 43/40; B29C 2043/025; B29L 2011/0075

(57) ABSTRACT

Methods are disclosed for fabricating molds for forming waveguides with integrated spacers for forming eyepieces. The molds are formed by etching features (e.g., 1 μm to 1000 μm deep) into a substrate comprising single crystalline material using an anisotropic wet etch. The etch masks for defining the large features may comprise a plurality of holes, wherein the size and shape of each hole at least partially determine the depth of the corresponding large feature. The holes may be aligned along a crystal axis of the substrate and the etching may automatically stop due to the crystal structure of the substrate. The patterned substrate may be utilized as a mold onto which a flowable polymer may be introduced and allowed to harden. Hardened polymer in the holes may form a waveguide with integrated spacers. The mold may be also used to fabricate a platform comprising a plurality of vertically extending microstructures of precise heights, to test the curvature or flatness of a sample, e.g., based on the amount of contact between the microstructures and the sample.

### CROSS-REFERENCE TO RELATED APPLICATIONS

This application claims priority to U.S. Provisional Patent Application No. 63/238,057, filed on Aug. 27, 2021, which is incorporated herein by reference in its entirety. This application incorporates by reference the entirety of each of the following patent applications: U.S. Application Publication No. 2021/0157032, published on May 27, 2021, entitled HYBRID POLYMER WAVEGUIDE AND METHODS FOR MAKING THE SAME; and U.S. application Ser. No. 17/186,902, filed on Feb. 26, 2021, entitled METHOD OF FABRICATING MOLDS FOR FORMING EYEPIECES WITH INTEGRATED SPACERS.

### BACKGROUND OF THE INVENTION

### Field

The present disclosure relates to display systems and, more particularly, to augmented reality display systems.

### Description of the Related Art

Modern computing and display technologies have facilitated the development of systems for so called “virtual reality” or “augmented reality” experiences, wherein digitally reproduced images or portions thereof are presented to a user in a manner wherein they seem to be, or may be perceived as, real. A virtual reality, or “VR”, scenario typically involves presentation of digital or virtual image information without transparency to other actual real-world visual input; an augmented reality, or “AR”, scenario typically involves presentation of digital or virtual image information as an augmentation to visualization of the actual world around the user. A mixed reality, or “MR”, scenario is a type of AR scenario and typically involves virtual objects that are integrated into, and responsive to, the natural world. For example, in an MR scenario, AR image content may be blocked by or otherwise be perceived as interacting with objects in the real world.

Referring to FIG. 1, an augmented reality scene 10 is depicted wherein a user of an AR technology sees a real-world park-like setting 20 featuring people, trees, buildings in the background, and a concrete platform 30. In addition to these items, the user of the AR technology also perceives that he “sees” “virtual content” such as a robot statue 40 standing upon the real-world platform 30, and a cartoon-like avatar character 50 flying by which seems to be a personification of a bumble bee, even though these elements 40, 50 do not exist in the real world. Because the human visual perception system is complex, it is challenging to produce an AR technology that facilitates a comfortable, natural-feeling, rich presentation of virtual image elements amongst other virtual or real-world imagery elements.

Systems and methods disclosed herein address various challenges related to AR and VR technology.

### SUMMARY OF THE INVENTION

In some embodiments, a method is provided for forming molds for casting. The mold may be utilized to form waveguides having integrated spacers. The method for forming a mold for casting comprises: providing a substrate comprising a layer of single crystalline material; forming an etch mask layer on the substrate, the etch mask layer having a pattern of holes extending therethrough, the holes aligned with a crystal axis of the layer of single crystalline material; and etching the substrate through the etch mask layer to form openings in the substrate, wherein the mold comprises the etched substrate. In some embodiments, the single crystalline material is silicon or germanium.

In some embodiments, the substrate is a silicon on insulator (SOI) substrate. In some embodiments, the layer of single crystalline material is not (111) oriented. In some embodiments, 2-dimensional shape, as seen in a top-down view, of at least one hole in the etch mask is a rectangle. In some embodiments, the shape of an opening in the substrate corresponding to the at least one hole is an inverted pyramid or an inverted frustum. In some embodiments, a thickness of the single crystalline material is larger than a depth of the opening, and the 3-dimensional shape of the opening is an inverted pyramid. In some embodiments, aligning the holes with a crystal axis comprises aligning at least one edge of the holes with a crystal axis so that the at least one edge is parallel with the crystal axis. In some embodiments, the substrate is a (100) silicon wafer and the crystal axis is one of <110> crystal axes. In some embodiments, the pattern of holes comprises holes of different sizes, wherein the openings corresponding to the pattern of holes have different depths. In some embodiments, the etch mask layer comprises photoresist. In some embodiments, etching the substrate through the etch mask layer comprises subjecting the substrate to a wet etch. In some embodiments, the method for forming a mold for casting further comprises removing the etch mask layer after etching the substrate. In some embodiments, a depth of one or more of the openings in the substrate is more than about 1 micrometer.

In some other embodiments, a method for forming a mold for casting is provided. The second method for forming a mold for casting comprises: providing a substrate comprising a layer of single crystalline material; forming a first etch mask layer on the substrate, the first etch mask layer comprising a plurality of first holes and a plurality of second holes, the plurality of first holes aligned with a crystal axis of the single crystalline material; forming a second etch mask layer on the first etch mask layer, the second etch mask layer exposing the plurality of second holes while extending over the plurality of first holes; etching the substrate through the plurality of second holes of the first and second etch mask layers to form a plurality of second openings corresponding to the plurality of second holes; forming a third etch mask layer on the substrate, the third etch mask layer exposing the plurality of first holes while extending over the plurality of second openings; and etching the substrate through the third etch mask layer to form a plurality of first openings corresponding to the plurality of first holes.

In some embodiments, the second method for forming a mold for casting further comprises etching the substrate through the third etch mask layer automatically stops at a stable crystalline plane. In some embodiments, the plurality of second holes are sized and spaced to define a diffractive grating for redirecting light of visible wavelengths. In some embodiments, final depths of the plurality of first openings in the mold are more than about 1 micrometer. In some embodiments, final depths of the plurality of second openings in the mold are less than about 500 nm. In some embodiments, etching the substrate through the plurality of second holes of the first and second etch mask layers comprises a dry etch. In some embodiments, etching the substrate through the third etch mask layer comprises a wet etch. In some embodiments, the single crystalline material comprises one or both of silicon and germanium. In some embodiments, the substrate is a silicon wafer or a silicon on insulator (SOI) substrate. In some embodiments, the layer of single crystalline material is not (111) oriented. In some embodiments, the first etch mask layer comprises photoresist. In some embodiments, the second etch mask layer comprises photoresist. In some embodiments, the second method for forming a mold for casting further comprises removing the first and second etch mask layers before forming the third etch mask layer. In some embodiments, the second method for forming a mold for casting further comprises removing the third etch mask layer.

In some embodiments, a method for forming a waveguide is provided. The method for forming a waveguide comprises: forming a mold according to the second method for forming a mold for casting discussed above; applying a flowable polymer on the mold to fill the plurality of first and second openings and to form a polymer layer with a thickness on the mold; hardening the polymer; and removing the hardened polymer from the mold, wherein the waveguide comprises the hardened polymer.

In some embodiments, a third method is provided for forming molds for casting. The mold may be utilized to form waveguides having integrated spacers. The third method for forming a mold for casting comprises: providing a substrate comprising a layer of single crystalline material and a second etch mask layer on the single crystalline material; forming a first etch mask layer on the second etch mask layer, the first etch mask layer comprising a plurality of first holes and a plurality of second holes, the plurality of first holes aligned with a crystal axis of the single crystalline material; etching the substrate through the first etch mask layer to a depth to form a plurality of first openings corresponding to the plurality of first holes and a plurality of second openings corresponding to the plurality of second holes, wherein the depth is less than thickness of the first etch mask layer; forming a third etch mask layer on the substrate, the third etch mask layer exposing the plurality of first openings while extending over the plurality of second openings; etching the second etch mask layer through the third etch mask layer until the plurality of first openings extend to the layer of crystalline material; removing the first etch mask layer and the third etch mask layer; etching the substrate through the second etch mask layer; further etching the substrate through the second etch mask layer until the plurality of second openings reach a desired depth in the layer of crystalline material; and removing the second etch mask layer.

In some embodiments, the third method for forming molds for casting further comprises forming a fourth etch mask layer on the second etch mask layer, the fourth etch mask layer exposing the plurality of first openings while extending over the plurality of second openings before further etching through the second etch mask layer. In some embodiments, etching the substrate through the first etch mask layer comprises a dry etch. In some embodiments, etching the substrate through the third etch mask layer comprises a dry etch. In some embodiments, etching the substrate through the second etch mask layer comprises a wet etch. In some embodiments, the third method for forming a mold for casting further comprises etching the substrate through the second etch mask layer comprises a dry etch. In some embodiments, the plurality of second holes are sized and spaced to define a diffractive grating for redirecting light of visible wavelengths. In some embodiments, final depths of the plurality of first openings in the mold are more than about 1 micrometer. In some embodiments, final depths of the plurality of second openings in the mold are less than about 500 nm. In some embodiments, the first etch mask layer comprises photoresist. In some embodiments, the second etch mask layer comprises silicon oxide. In some embodiments, the third etch mask layer comprises metal. In some embodiments, the fourth etch mask layer comprises metal.

In some embodiments, a method for forming a waveguide is provided. The method for forming a waveguide comprises: forming a mold according to the third method for forming a mold for casting discussed above; applying a flowable polymer on the mold to fill the plurality of first and second openings and to form a polymer layer with a thickness on the mold; hardening the polymer; and removing the hardened polymer from the mold, wherein the waveguide comprises the hardened polymer. In some embodiments, the waveguide comprises a plurality of spacers formed in the plurality of first openings and a plurality of diffractive optical elements formed in the plurality of second openings.

In some embodiments, a method for forming a waveguide structure is provided. The method for forming a waveguide structure comprises: providing a first cover plate comprising a plurality of first spacers on a major surface of the cover plate, the first spacers defining a first curvature; providing a second cover plate comprising a plurality of second spacers on a major surface of the second cover plate, the second spacers defining a second curvature; disposing one or more waveguides between the first cover plate and the second cover plate to impart the first and second curvatures onto the one or more waveguides.

In some embodiments, the one or more waveguides comprises a stack of waveguides. In some embodiments, disposing the one or more waveguides comprises sequentially stacking different ones of the one or more waveguides on the first or the second cover plate. In some embodiments, each of the waveguides comprises associated spacers, wherein the spacers are different waveguides impart different curvatures to immediately neighboring waveguides. In some embodiments, a curvature of the one or more waveguides is configured to provide image content at a depth plane corresponding to the curvature of the one or more waveguides.

In some embodiments, providing the first cover plate comprises: forming a first mold comprising a first plurality of openings by etching a first substrate comprising a single crystalline material through a first etch mask comprising a first pattern of holes; and forming the first cover plate with the first mold, the first cover plate comprising the plurality of first spacers corresponding to the first plurality of openings. In some embodiments, providing the second cover plate comprises: forming a second mold comprising a second plurality of openings by etching a second substrate comprising a single crystalline material through a second etch mask comprising a second pattern of holes; and forming the second cover plate with the second mold, the second cover plate comprising the plurality of second spacers corresponding to the second plurality of openings.

In some embodiments, a method for analyzing a flatness or curvature of a sample is provided. The method for analyzing a flatness or curvature of a sample comprises: providing a platform comprising a plurality of vertically-extending microstructures; placing the sample on the plurality of vertically-extending microstructures; determining a light pattern formed by contact between the microstructures and the sample; and determining a curvature of the sample based upon the light pattern, wherein the platform is formed by casting. In some embodiments, a mold used for casting is formed by etching a substrate comprising single crystalline material through a etch mask comprising a pattern of holes. In some embodiments, holes in the pattern are arranged to form corresponding microstructure in the platform. In some embodiments, the holes are squares. In some embodiments, determining a curvature comprises correlating the light pattern to determine a degree of the contact between the microstructures and the sample.

In some embodiments, a waveguide stack is provided. The waveguide stack comprises: a first waveguide comprising at least one spacer; a second waveguide immediately adjacent and above the first waveguide; and a layer of a first cured resin between a bottom surface of the second waveguide and a top surface of the at least one spacer; wherein the layer of first cured resin absorbs light of a first wavelength range. In some embodiments, a layer of a second cured resin is between the layer of first cured resin and the bottom surface of the second waveguide. In some embodiments, the layer of the second cured resin is an adhesive. In some embodiments, the layer of the first cured resin comprises a pigment.

In some embodiments, a method for forming a waveguide stack is provided. The method for forming a waveguide stack comprises: providing a first waveguide comprising at least one spacer; dispensing a layer of a first resin onto a top surface of the at least one spacer; curing the first resin; and stacking a second waveguide above the first waveguide, a bottom surface of the second waveguide in contact with the layer of the first resin on the top surface of the at least one spacer, wherein the layer of the first resin absorbs light of a first wavelength range. In some embodiments, the dispensing a layer of a first resin comprises drop-on-demand inkjet printing. In some embodiments, the method for forming a waveguide stack further comprises dispensing a layer of a second resin on the layer of the first resin, wherein the second resin is an adhesive.

### BRIEF DESCRIPTION OF THE DRAWINGS

FIG. 1 illustrates a user's view of augmented reality (AR) through an AR device.

FIG. 2 illustrates a conventional display system for simulating three-dimensional imagery for a user.

FIGS. 3A-3C illustrate relationships between radius of curvature and focal radius.

FIG. 4A illustrates a representation of the accommodation-vergence response of the human visual system.

FIG. 4B illustrates examples of different accommodative states and vergence states of a pair of eyes of the user.

FIG. 4C illustrates an example of a representation of a top-down view of a user viewing content via a display system.

FIG. 4D illustrates another example of a representation of a top-down view of a user viewing content via a display system.

FIG. 5 illustrates aspects of an approach for simulating three-dimensional imagery by modifying wavefront divergence.

FIG. 6 illustrates an example of a waveguide stack for outputting image information to a user.

FIG. 7 illustrates an example of exit beams outputted by a waveguide.

FIG. 8 illustrates an example of a stacked waveguide assembly in which each depth plane includes images formed using multiple different component colors.

FIG. 9A illustrates a cross-sectional side view of an example of a set of stacked waveguides that each includes an incoupling optical element.

FIG. 9B illustrates a perspective view of an example of the plurality of stacked waveguides of FIG. 9A.

FIG. 9C illustrates a top-down plan view of an example of the plurality of stacked waveguides of FIGS. 9A and 9B.

FIG. 9D illustrates an example of wearable display system.

FIG. 10A illustrates an example of a waveguide comprising spacers.

FIG. 10B illustrates an example of a stack of waveguides comprising spacers.

FIG. 11A illustrates an example of a waveguide comprising spacers with light scattering features.

FIG. 11B illustrates an example of a stack of waveguides comprising spacers and light leakage prevention material at the interface between spacers and immediately neighboring waveguides.

FIGS. 11C-11D illustrate an example method of dispensing a light leakage prevention material onto waveguide spacers.

FIG. 11E illustrates another example of a stack of waveguides comprising spacers and light leakage prevention material at the interface between the spacers and immediately neighboring waveguides.

FIG. 11F illustrates another example method of dispensing light leakage prevention materials onto waveguide spacers.

FIG. 11G illustrates another example method of dispensing a light leakage prevention material onto waveguide spacers.

FIG. 11H illustrates another example of a stack of waveguides comprising spacers and light leakage prevention material at the interface between the spacers and immediately neighboring waveguides.

FIG. 12A illustrates examples of 3-dimensional shapes for spacers.

FIGS. 12B-12D illustrate examples of waveguides comprising spacers of different shapes.

FIGS. 12E-F illustrate examples of a stack of waveguides comprising spacers of different shapes, such as those show in FIGS. 12B-12D.

FIG. 12G illustrate an example of a stack of curved waveguides with flat plates on the top and bottom of the waveguide stack.

FIGS. 13A-13B illustrate examples of top-down plan views of waveguides comprising spacers.

FIGS. 14A-B illustrate an example of a method for forming a waveguide with spacers.

FIGS. 14C-E illustrate SEM images of examples of spacers.

FIG. 15A illustrates an example of a mold with large and small openings.

FIG. 15B illustrates an examples of a mold formed by a single crystalline silicon substrate.

FIG. 15C illustrates an examples of a mold formed by a SOI substrate.

FIG. 15D illustrates an example of the result of isotropic etching of a substrate.

FIG. 15E illustrates an example of SOI substrate.

FIGS. 16A-E illustrate an example method of fabricating a mold.

FIGS. 17A-B are top-down views of the substrate covered by an etch mask before and after etching, respectively.

FIG. 17C is a SEM image of an example of mold.

FIG. 17D is a SEM image of an example of spacers formed by molds.

FIGS. 18A-J illustrate examples of 3-dimensional shapes and the corresponding top-down view for spacers fabricated with different etch mask patterns and substrates.

FIGS. 19A-E illustrate an example method for forming a mold.

FIGS. 20A-E illustrate an example method for forming a mold.

FIG. 21 illustrates a flow chart of a method for forming a mold.

FIGS. 22A-H illustrate an example method for forming a mold.

FIG. 23 illustrates a flow chart of a method for forming a mold.

FIGS. 24A-C illustrate an example of a top-down plan view of fabricated eye pieces with molds and spacer.

FIG. 25 illustrate a system for checking the flatness or curvature of a sample.

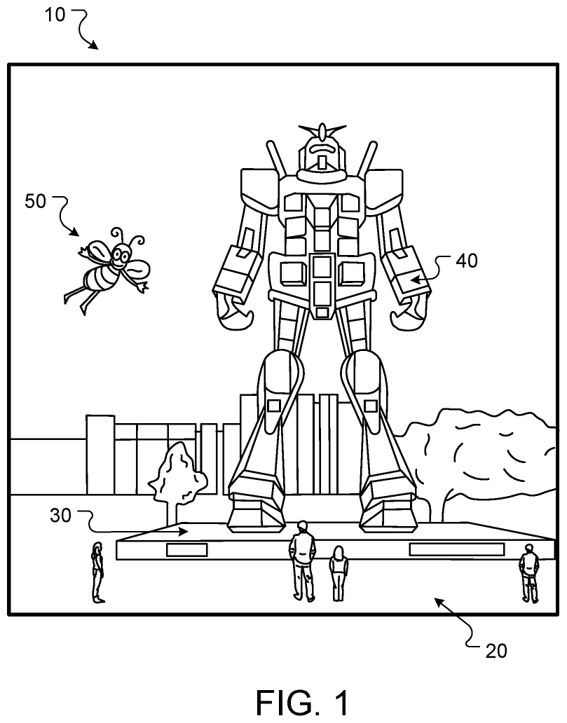

### DETAILED DESCRIPTION

Near-eye augmented and virtual reality display systems may include eyepieces for directing image information into the eyes of a viewer. The eyepieces may be formed of stacks of waveguides that are spaced apart by intervening beads of glue. It will be appreciated that the sizes of the beads and the separation between the waveguides provided by the beads may impact the optical performance of the eyepiece and the perceived image quality of the display system. For example, the beads may be formed at specific locations and then an overlying waveguide may be pressed onto the beads at specific pressures, after which the beads may be hardened by curing. As a result, formation of the spacers may require precise alignment and controlled pressure to maintain a constant separation distance between the waveguides throughout the stack of waveguides. It may be challenging to provide such precise alignment and pressure control. In addition, where the waveguides are formed of polymers, the polymer waveguides may be flexible and utilizing beads of material to separate the waveguides may not provide sufficient mechanical or structural stability for maintaining the desired separation between waveguides.

To provide greater control over spacing, one or more waveguides, which may be used to form a stack of waveguides, may include integral spacers for providing a desired separation with overlying or underlying structures, such as other waveguides. The waveguides may each include surface relief features, e.g. diffractive optical elements (such as diffractive gratings) that are formed simultaneously with the spacer. The spacers and the main body of the waveguides may form a monolithic structure. In some embodiments, the waveguide may be a hybrid waveguide comprising a plurality of layers, one of which may include the spacers and the diffractive optical elements.

It will be appreciated that waveguides with integral spaces may be formed by casting, using a mold with openings corresponding to a negative of the desired spacers and any other features, such as diffractive gratings. For example, a liquid phase polymer material may be pored on a mold, or a mold may be used to compress the liquid phase polymer material, to define the spacers and other protruding features and to form a solid phase waveguide of the polymer material. The polymer material may subsequently be hardened and the mold may be removed from the hardened material, leaving a pattern of spacers and other features on the surface of the waveguide.

Such a casting process may have an undesirably low yield for forming waveguides with integral spacers. It has been found that the low yields may result from complications caused by the mold used in casting. For example, the molds may be formed by wet etching a mold substrate through an etch mask. However, the wet etch may be isotropic, etching both downwards and laterally, such that the resulting opening has a broad rounded bottom and bulges laterally. Such an opening may be difficult to fill completely, leading to spacers and other features which are not fully formed. In addition, the outward bulging may make removal of the mold difficult and may also cause mechanical damage to the spacers or other structures during this removal, since portions of the spacers or other structures in this bulge portion may become stuck. It has also been found that these mold openings may be difficult to completely fill, with bubbles of air becoming trapped during the fill. This is believed to be caused by the broad bottom profile of the opening.

In addition, the molds themselves may be difficult to form, particularly where features with variable heights are desired. For example, typical etches have a particular etch rate, such that regulating the depth of an opening may involve selecting a particular etch duration. Variability in the etch rate or etch duration, however, may undesirably cause variations in the etch depth.

In some embodiments, molds are formed using an auto-etch stop, in which the etching of an opening automatically stops at a desired depth. In some embodiments, this auto-etch stop may be formed using a crystalline substrate and an etch mask that is aligned with a crystal axis of the crystalline substrate. For example, the etch mask may have a pattern of holes with rectangular cross sections, with an edge of the holes substantially parallel with the crystal axis. As the substrate is etched through these openings, preferably using a wet etch, material is preferentially removed based on the crystal planes in the substrate, thereby forming a pyramid-like opening generally having the shape of an inverted pyramid. It will be appreciated that, during the etch, the opening grows larger until the opening is defined by crystal planes that meet the vertical walls of the corresponding opening in the etch mask and extend continuously to the bottom of the opening. At this point, the etch may be understood to automatically stop since the etch rate may significantly decrease at that stage, due to lower susceptibility of the crystal planes to etching. In some embodiments, the etch rate decreases by 40% or more, 50% or more, 60% or more, 70% or more, or 80% or more, relative to the etch rate before the size of the opening is sufficiently large that crystal planes in the substrate meet sidewalls of the holes in the overlying etch mask, and may also meet at a point or line at the bottom of the opening or meet an etch stop layer. Thus, the depth of the etch and resulting opening may be regulated by selecting a corresponding width for the hole in the etch mask; that is, a wider hole would form a deeper opening than a narrower hole, since more material would need to be removed from the wider hole before the crystal planes meet the vertical walls of that hole, and also at a point or line at the bottom of the opening or at an etch stop layer. As a result, well-controlled processes for defining the widths of holes in the etch mask may be used to provide a high degree of control over the depth of openings formed in the substrate.

In some embodiments, the shape of the opening in the substrate may be further regulated using a physical etch stop at a desired depth, to form a flat bottom for the opening, rather than a pointed bottom (e.g., to define a truncated inverted-pyramid). For example, a layer of etch stop material may be present at the desired depth in the substrate. Once the etch reaches that etch stop layer, the etch proceeds no further downwards, but continues to expand the width of the opening until the crystal planes converge with the vertical sidewalls of the etch mask hole. The resulting spacer or other future formed in this opening would have a flat plateau.

In some embodiments, different openings, having different shapes and/or depths, may be formed by separately forming the different openings. For example, to form openings of different depths, openings of the different depths may be formed in different process steps, and already-formed openings may be protected while other openings are being formed. In some embodiments, in order to form openings with flat bottoms, a dry etch may be applied to etch those openings down to a desired depth, while a wet etch may be applied to etch other openings, such as for forming spacers. It will be appreciated that the depth of the openings formed by the dry etch may be selected based upon the duration of the dry etch, while the wet etch is subjected to an auto etch top, as disclosed herein. In addition, the dry etch and wet etch may be performed at different times, with other features which are not desired to be etched protected by a protective mask. Without being limited by theory, the dry etch is believed to relatively uniformly remove material exposed to the dry etch, such that openings with a flat bottom are formed. On the other hand, as discussed herein, a wet etch forms an inverted-pyramid shape defined by the crystal planes of the substrate.

Advantageously, the resulting etched substrate forms a mold with openings having highly-precise depths and sloped sidewalls. The sloped sidewalls of the mold openings facilitate filling of the openings with waveguide material, since the sloped sidewalls help funnel the material towards the bottom of the openings. In addition, after hardening of the material, removal may be facilitated by this sloped shape, which, for example, avoids outward lateral bulges that may cause hardened material to become stuck in the openings.

The high precision with which openings of a desired depth are formed advantageously allows high uniformity in the heights of spacers and other features formed by casting these features in the mold. This high uniformity provides tight control over the spacing between waveguides formed in a stack and separated by the spacers. This may provide a high degree of parallelism between the stacked waveguides, which has been found to improve image quality in displays using the waveguides to output image light of different colors. For example, it has been found that image light outputted from the waveguides, e.g., using diffractive optical elements, may have different intensities depending on angle. As a result, where different waveguides output different component colors to form a full-color image, non-parallel waveguides of different colors may cause unintended color shifts as light propagates to the viewer's eye at different exit angles from the waveguide. Thus, the highly parallel waveguides formed using molds as disclosed herein may form displays which provide a high degree of color accuracy.

In some amendments, the high precision achieved in setting the heights of the spacers may be applied to using the spacers as a platform for testing the curvature (or flatness) of a sample, such as a waveguide. For example, the spacers may be formed with varying heights, with tops of the spacers corresponding to the desired curvature of the sample. The sample may then be placed in contact with the spacers (or as many spacers as will contact the sample). It will be appreciated that if the sample follows the desired curve, then contact would be made with all of the spacers, thereby forming a particular light pattern when light is directed to the sample and the spacers. It will be appreciated that a lack of contact with one or more spacers will cause a different pattern to form. As a result, how closely the sample conforms to the desired curvature may be determined based on an analysis of the light pattern that is formed by the spacers which contact the sample. Without being bound by theory, light reflection, interference and diffraction associated with contact between the spacer and the sample may affect the light pattern.

Reference will now be made to the drawings, in which like reference numerals refer to like parts throughout. Unless indicated otherwise, the drawings are schematic and not necessarily drawn to scale.

### Example Display Systems

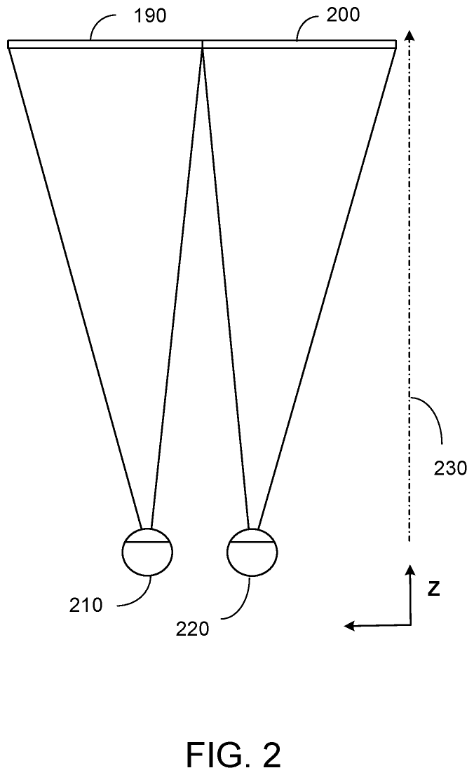

FIG. 2 illustrates a conventional display system for simulating three-dimensional imagery for a user. It will be appreciated that a user's eyes are spaced apart and that, when looking at a real object in space, each eye will have a slightly different view of the object and may form an image of the object at different locations on the retina of each eye. This may be referred to as binocular disparity and may be utilized by the human visual system to provide a perception of depth. Conventional display systems simulate binocular disparity by presenting two distinct images 190, 200 with slightly different views of the same virtual object-one for each eye 210, 220—corresponding to the views of the virtual object that would be seen by each eye were the virtual object a real object at a desired depth. These images provide binocular cues that the user's visual system may interpret to derive a perception of depth.

With continued reference to FIG. 2, the images 190, 200 are spaced from the eyes 210, 220 by a distance 230 on a z-axis. The z-axis is parallel to the optical axis of the viewer with their eyes fixated on an object at optical infinity directly ahead of the viewer. The images 190, 200 are flat and at a fixed distance from the eyes 210, 220. Based on the slightly different views of a virtual object in the images presented to the eyes 210, 220, respectively, the eyes may naturally rotate such that an image of the object falls on corresponding points on the retinas of each of the eyes, to maintain single binocular vision. This rotation may cause the lines of sight of each of the eyes 210, 220 to converge onto a point in space at which the virtual object is perceived to be present. As a result, providing three-dimensional imagery conventionally involves providing binocular cues that may manipulate the vergence of the user's eyes 210, 220, and that the human visual system interprets to provide a perception of depth.

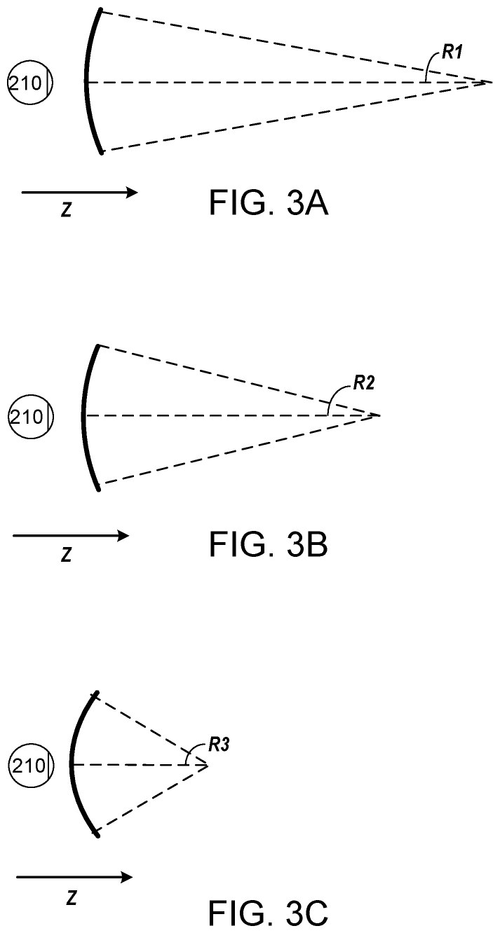

Generating a realistic and comfortable perception of depth is challenging, however. It will be appreciated that light from objects at different distances from the eyes have wavefronts with different amounts of divergence. FIGS. 3A-3C illustrate relationships between distance and the divergence of light rays. The distance between the object and the eye 210 is represented by, in order of decreasing distance, R1, R2, and R3. As shown in FIGS. 3A-3C, the light rays become more divergent as distance to the object decreases. Conversely, as distance increases, the light rays become more collimated. Stated another way, it may be said that the light field produced by a point (the object or a part of the object) has a spherical wavefront curvature, which is a function of how far away the point is from the eye of the user. The curvature increases with decreasing distance between the object and the eye 210. While only a single eye 210 is illustrated for clarity of illustration in FIGS. 3A-3C and other figures herein, the discussions regarding eye 210 may be applied to both eyes 210 and 220 of a viewer.

With continued reference to FIGS. 3A-3C, light from an object that the viewer's eyes are fixated on may have different degrees of wavefront divergence. Due to the different amounts of wavefront divergence, the light may be focused differently by the lens of the eye, which in turn may require the lens to assume different shapes to form a focused image on the retina of the eye. Where a focused image is not formed on the retina, the resulting retinal blur acts as a cue to accommodation that causes a change in the shape of the lens of the eye until a focused image is formed on the retina. For example, the cue to accommodation may trigger the ciliary muscles surrounding the lens of the eye to relax or contract, thereby modulating the force applied to the suspensory ligaments holding the lens, thus causing the shape of the lens of the eye to change until retinal blur of an object of fixation is eliminated or minimized, thereby forming a focused image of the object of fixation on the retina (e.g., fovea) of the eye. The process by which the lens of the eye changes shape may be referred to as accommodation, and the shape of the lens of the eye required to form a focused image of the object of fixation on the retina (e.g., fovea) of the eye may be referred to as an accommodative state.

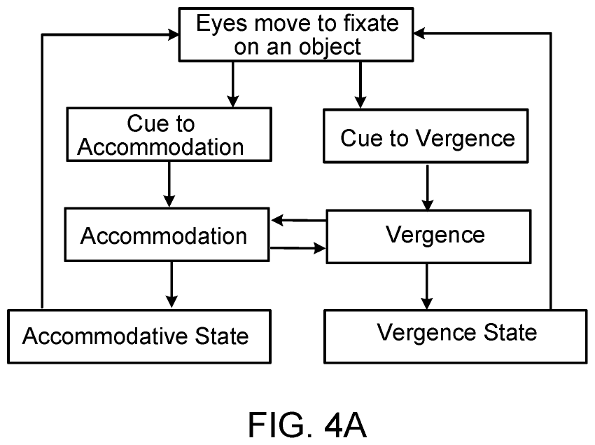

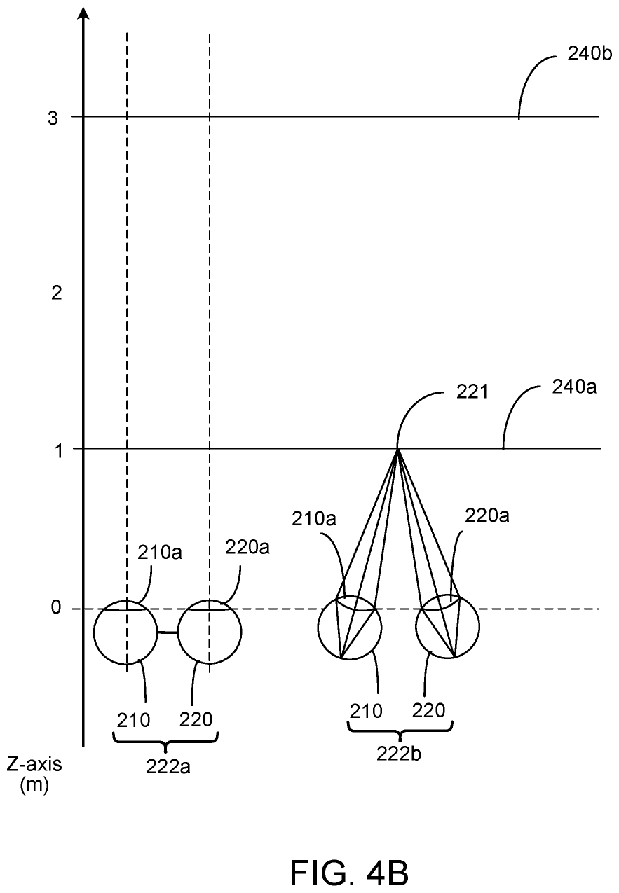

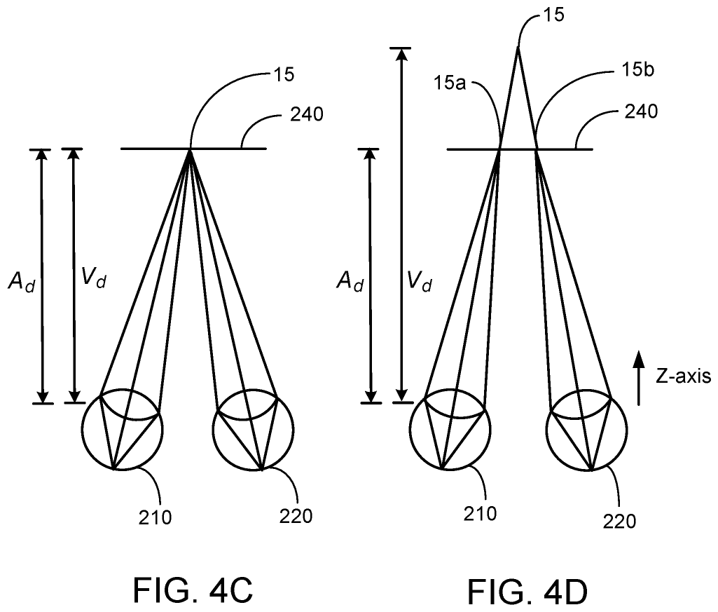

With reference now to FIG. 4A, a representation of the accommodation-vergence response of the human visual system is illustrated. The movement of the eyes to fixate on an object causes the eyes to receive light from the object, with the light forming an image on each of the retinas of the eyes. The presence of retinal blur in the image formed on the retina may provide a cue to accommodation, and the relative locations of the image on the retinas may provide a cue to vergence. The cue to accommodation causes accommodation to occur, resulting in the lenses of the eyes each assuming a particular accommodative state that forms a focused image of the object on the retina (e.g., fovea) of the eye. On the other hand, the cue to vergence causes vergence movements (rotation of the eyes) to occur such that the images formed on each retina of each eye are at corresponding retinal points that maintain single binocular vision. In these positions, the eyes may be said to have assumed a particular vergence state. With continued reference to FIG. 4A, accommodation may be understood to be the process by which the eye achieves a particular accommodative state, and vergence may be understood to be the process by which the eye achieves a particular vergence state. As indicated in FIG. 4A, the accommodative and vergence states of the eyes may change if the user fixates on another object. For example, the accommodated state may change if the user fixates on a new object at a different depth on the z-axis.

Without being limited by theory, it is believed that viewers of an object may perceive the object as being “three-dimensional” due to a combination of vergence and accommodation. As noted above, vergence movements (e.g., rotation of the eyes so that the pupils move toward or away from each other to converge the lines of sight of the eyes to fixate upon an object) of the two eyes relative to each other are closely associated with accommodation of the lenses of the eyes. Under normal conditions, changing the shapes of the lenses of the eyes to change focus from one object to another object at a different distance will automatically cause a matching change in vergence to the same distance, under a relationship known as the “accommodation-vergence reflex.” Likewise, a change in vergence will trigger a matching change in lens shape under normal conditions.

With reference now to FIG. 4B, examples of different accommodative and vergence states of the eyes are illustrated. The pair of eyes 222a is fixated on an object at optical infinity, while the pair eyes 222b are fixated on an object 221 at less than optical infinity. Notably, the vergence states of each pair of eyes is different, with the pair of eyes 222a directed straight ahead, while the pair of eyes 222 converge on the object 221. The accommodative states of the eyes forming each pair of eyes 222a and 222b are also different, as represented by the different shapes of the lenses 210a, 220a.

Undesirably, many users of conventional “3-D” display systems find such conventional systems to be uncomfortable or may not perceive a sense of depth at all due to a mismatch between accommodative and vergence states in these displays. As noted above, many stereoscopic or “3-D” display systems display a scene by providing slightly different images to each eye. Such systems are uncomfortable for many viewers, since they, among other things, simply provide different presentations of a scene and cause changes in the vergence states of the eyes, but without a corresponding change in the accommodative states of those eyes. Rather, the images are shown by a display at a fixed distance from the eyes, such that the eyes view all the image information at a single accommodative state. Such an arrangement works against the “accommodation-vergence reflex” by causing changes in the vergence state without a matching change in the accommodative state. This mismatch is believed to cause viewer discomfort. Display systems that provide a better match between accommodation and vergence may form more realistic and comfortable simulations of three-dimensional imagery.

Without being limited by theory, it is believed that the human eye typically may interpret a finite number of depth planes to provide depth perception. Consequently, a highly believable simulation of perceived depth may be achieved by providing, to the eye, different presentations of an image corresponding to each of these limited numbers of depth planes. In some embodiments, the different presentations may provide both cues to vergence and matching cues to accommodation, thereby providing physiologically correct accommodation-vergence matching.

With continued reference to FIG. 4B, two depth planes 240, corresponding to different distances in space from the eyes 210, 220, are illustrated. For a given depth plane 240, vergence cues may be provided by the displaying of images of appropriately different perspectives for each eye 210, 220. In addition, for a given depth plane 240, light forming the images provided to each eye 210, 220 may have a wavefront divergence corresponding to a light field produced by a point at the distance of that depth plane 240.

In the illustrated embodiment, the distance, along the z-axis, of the depth plane 240 containing the point 221 is 1 m. As used herein, distances or depths along the z-axis may be measured with a zero-point located at the exit pupils of the user's eyes. Thus, a depth plane 240 located at a depth of 1 m corresponds to a distance of 1 m away from the exit pupils of the user's eyes, on the optical axis of those eyes with the eyes directed towards optical infinity. As an approximation, the depth or distance along the z-axis may be measured from the display in front of the user's eyes (e.g., from the surface of a waveguide), plus a value for the distance between the device and the exit pupils of the user's eyes. That value may be called the eye relief and corresponds to the distance between the exit pupil of the user's eye and the display worn by the user in front of the eye. In practice, the value for the eye relief may be a normalized value used generally for all viewers. For example, the eye relief may be assumed to be 20 mm and a depth plane that is at a depth of 1 m may be at a distance of 980 mm in front of the display.

With reference now to FIGS. 4C and 4D, examples of matched accommodation-vergence distances and mismatched accommodation-vergence distances are illustrated, respectively. As illustrated in FIG. 4C, the display system may provide images of a virtual object to each eye 210, 220. The images may cause the eyes 210, 220 to assume a vergence state in which the eyes converge on a point 15 on a depth plane 240. In addition, the images may be formed by a light having a wavefront curvature corresponding to real objects at that depth plane 240. As a result, the eyes 210, 220 assume an accommodative state in which the images are in focus on the retinas of those eyes. Thus, the user may perceive the virtual object as being at the point 15 on the depth plane 240.

It will be appreciated that each of the accommodative and vergence states of the eyes 210, 220 are associated with a particular distance on the z-axis. For example, an object at a particular distance from the eyes 210, 220 causes those eyes to assume particular accommodative states based upon the distances of the object. The distance associated with a particular accommodative state may be referred to as the accommodation distance, Ad. Similarly, there are particular vergence distances, Vd, associated with the eyes in particular vergence states, or positions relative to one another. Where the accommodation distance and the vergence distance match, the relationship between accommodation and vergence may be said to be physiologically correct. This is considered to be the most comfortable scenario for a viewer.

In stereoscopic displays, however, the accommodation distance and the vergence distance may not always match. For example, as illustrated in FIG. 4D, images displayed to the eyes 210, 220 may be displayed with wavefront divergence corresponding to depth plane 240, and the eyes 210, 220 may assume a particular accommodative state in which the points 15a, 15b on that depth plane are in focus. However, the images displayed to the eyes 210, 220 may provide cues for vergence that cause the eyes 210, 220 to converge on a point 15 that is not located on the depth plane 240. As a result, the accommodation distance corresponds to the distance from the exit pupils of the eyes 210, 220 to the depth plane 240, while the vergence distance corresponds to the larger distance from the exit pupils of the eyes 210, 220 to the point 15, in some embodiments. The accommodation distance is different from the vergence distance. Consequently, there is an accommodation-vergence mismatch. Such a mismatch is considered undesirable and may cause discomfort in the user. It will be appreciated that the mismatch corresponds to distance (e.g., Vd-Ad) and may be characterized using diopters.

In some embodiments, it will be appreciated that a reference point other than exit pupils of the eyes 210, 220 may be utilized for determining distance for determining accommodation-vergence mismatch, so long as the same reference point is utilized for the accommodation distance and the vergence distance. For example, the distances could be measured from the cornea to the depth plane, from the retina to the depth plane, from the eyepiece (e.g., a waveguide of the display device) to the depth plane, from the center of rotation of an eye, and so on.

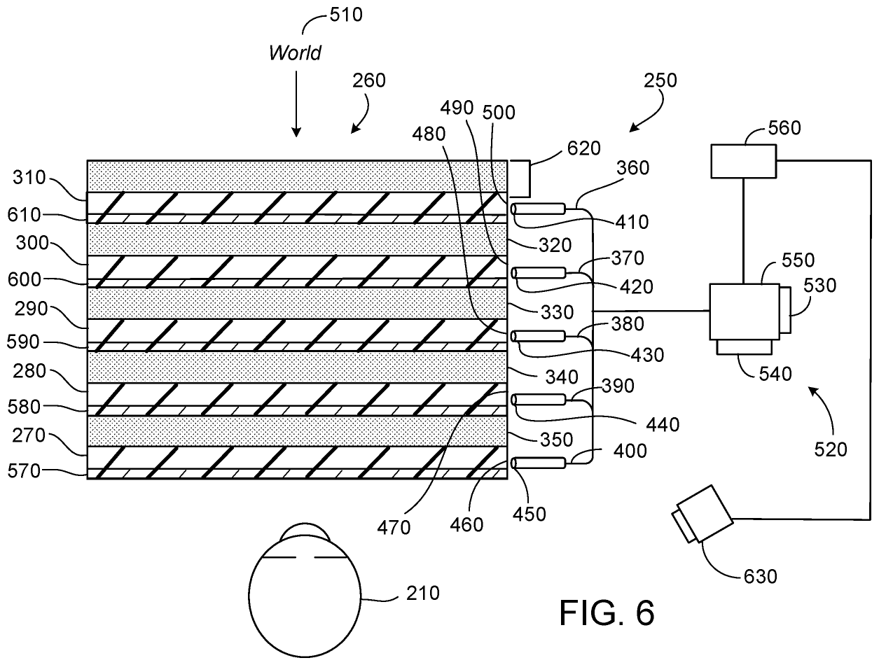

Without being limited by theory, it is believed that users may still perceive accommodation-vergence mismatches of up to about 0.25 diopter, up to about 0.33 diopter, and up to about 0.5 diopter as being physiologically correct, without the mismatch itself causing significant discomfort. In some embodiments, display systems disclosed herein (e.g., the display system 250, FIG. 6) present images to the viewer having accommodation-vergence mismatch of about 0.5 diopter or less. In some other embodiments, the accommodation-vergence mismatch of the images provided by the display system is about 0.33 diopter or less. In yet other embodiments, the accommodation-vergence mismatch of the images provided by the display system is about 0.25 diopter or less, including about 0.1 diopter or less.

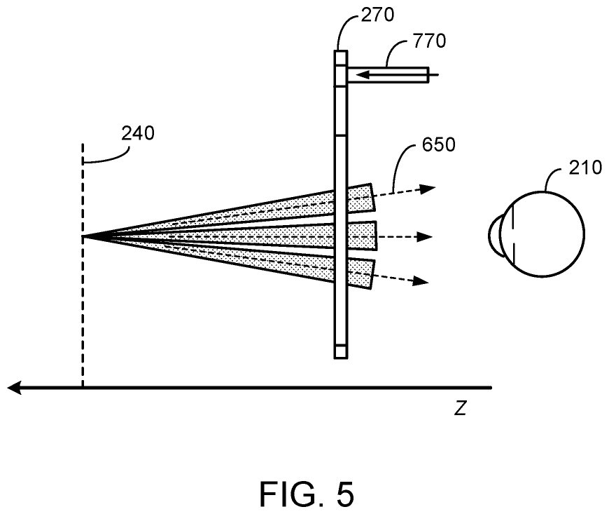

FIG. 5 illustrates aspects of an approach for simulating three-dimensional imagery by modifying wavefront divergence. The display system includes a waveguide 270 that is configured to receive light 770 that is encoded with image information, and to output that light to the user's eye 210. The waveguide 270 may output the light 650 with a defined amount of wavefront divergence corresponding to the wavefront divergence of a light field produced by a point on a desired depth plane 240. In some embodiments, the same amount of wavefront divergence is provided for all objects presented on that depth plane. In addition, it will be illustrated that the other eye of the user may be provided with image information from a similar waveguide.

In some embodiments, a single waveguide may be configured to output light with a set amount of wavefront divergence corresponding to a single or limited number of depth planes and/or the waveguide may be configured to output light of a limited range of wavelengths. Consequently, in some embodiments, a plurality or stack of waveguides may be utilized to provide different amounts of wavefront divergence for different depth planes and/or to output light of different ranges of wavelengths. As used herein, it will be appreciated that a depth plane may follow the contours of a flat or a curved surface. In some embodiments, advantageously for simplicity, the depth planes may follow the contours of flat surfaces.

FIG. 6 illustrates an example of a waveguide stack for outputting image information to a user. A display system 250 includes a stack of waveguides, or stacked waveguide assembly, 260 that may be utilized to provide three-dimensional perception to the eye/brain using a plurality of waveguides 270, 280, 290, 300, 310. It will be appreciated that the display system 250 may be considered a light field display in some embodiments. In addition, the waveguide assembly 260 may also be referred to as an eyepiece.

In some embodiments, the display system 250 may be configured to provide substantially continuous cues to vergence and multiple discrete cues to accommodation. The cues to vergence may be provided by displaying different images to each of the eyes of the user, and the cues to accommodation may be provided by outputting the light that forms the images with selectable discrete amounts of wavefront divergence. Stated another way, the display system 250 may be configured to output light with variable levels of wavefront divergence. In some embodiments, each discrete level of wavefront divergence corresponds to a particular depth plane and may be provided by a particular one of the waveguides 270, 280, 290, 300, 310.

With continued reference to FIG. 6, the waveguide assembly 260 may also include a plurality of features 320, 330, 340, 350 between the waveguides. In some embodiments, the features 320, 330, 340, 350 may be one or more lenses. The waveguides 270, 280, 290, 300, 310 and/or the plurality of lenses 320, 330, 340, 350 may be configured to send image information to the eye with various levels of wavefront curvature or light ray divergence. Each waveguide level may be associated with a particular depth plane and may be configured to output image information corresponding to that depth plane. Image injection devices 360, 370, 380, 390, 400 may function as a source of light for the waveguides and may be utilized to inject image information into the waveguides 270, 280, 290, 300, 310, each of which may be configured, as described herein, to distribute incoming light across each respective waveguide, for output toward the eye 210. Light exits an output surface 410, 420, 430, 440, 450 of the image injection devices 360, 370, 380, 390, 400 and is injected into a corresponding input surface 460, 470, 480, 490, 500 of the waveguides 270, 280, 290, 300, 310. In some embodiments, each of the input surfaces 460, 470, 480, 490, 500 may be an edge of a corresponding waveguide, or may be part of a major surface of the corresponding waveguide (that is, one of the waveguide surfaces directly facing the world 510 or the viewer's eye 210). It will be appreciated that the major surfaces of a waveguide correspond to the surfaces of the waveguide between which the thickness of the waveguide extends. In some embodiments, a single beam of light (e.g. a collimated beam) may be injected into each waveguide to output an entire field of cloned collimated beams that are directed toward the eye 210 at particular angles (and amounts of divergence) corresponding to the depth plane associated with a particular waveguide. In some embodiments, a single one of the image injection devices 360, 370, 380, 390, 400 may be associated with and inject light into a plurality (e.g., three) of the waveguides 270, 280, 290, 300, 310.

In some embodiments, the image injection devices 360, 370, 380, 390, 400 are discrete displays that each produce image information for injection into a corresponding waveguide 270, 280, 290, 300, 310, respectively. In some other embodiments, the image injection devices 360, 370, 380, 390, 400 are the output ends of a single multiplexed display which may, e.g., pipe image information via one or more optical conduits (such as fiber optic cables) to each of the image injection devices 360, 370, 380, 390, 400. It will be appreciated that the image information provided by the image injection devices 360, 370, 380, 390, 400 may include light of different wavelengths, or colors (e.g., different component colors, as discussed herein).

In some embodiments, the light injected into the waveguides 270, 280, 290, 300, 310 is provided by a light projector system 520, which comprises a light module 530, which may include a light emitter, such as a light emitting diode (LED). The light from the light module 530 may be directed to and modified by a light modulator 540, e.g., a spatial light modulator, via a beam splitter 550. The light modulator 540 may be configured to change the perceived intensity of the light injected into the waveguides 270, 280, 290, 300, 310 to encode the light with image information. Examples of spatial light modulators include liquid crystal displays (LCD) including a liquid crystal on silicon (LCOS) displays. It will be appreciated that the image injection devices 360, 370, 380, 390, 400 are illustrated schematically and, in some embodiments, these image injection devices may represent different light paths and locations in a common projection system configured to output light into associated ones of the waveguides 270, 280, 290, 300, 310. In some embodiments, the waveguides of the waveguide assembly 260 may function as ideal lens while relaying light injected into the waveguides out to the user's eyes. In this conception, the object may be the spatial light modulator 540 and the image may be the image on the depth plane.

In some embodiments, the display system 250 may be a scanning fiber display comprising one or more scanning fibers configured to project light in various patterns (e.g., raster scan, spiral scan, Lissajous patterns, etc.) into one or more waveguides 270, 280, 290, 300, 310 and ultimately to the eye 210 of the viewer. In some embodiments, the illustrated image injection devices 360, 370, 380, 390, 400 may schematically represent a single scanning fiber or a bundle of scanning fibers configured to inject light into one or a plurality of the waveguides 270, 280, 290, 300, 310. In some other embodiments, the illustrated image injection devices 360, 370, 380, 390, 400 may schematically represent a plurality of scanning fibers or a plurality of bundles of scanning fibers, each of which are configured to inject light into an associated one of the waveguides 270, 280, 290, 300, 310. It will be appreciated that one or more optical fibers may be configured to transmit light from the light module 530 to the one or more waveguides 270, 280, 290, 300, 310. It will be appreciated that one or more intervening optical structures may be provided between the scanning fiber, or fibers, and the one or more waveguides 270, 280, 290, 300, 310 to, e.g., redirect light exiting the scanning fiber into the one or more waveguides 270, 280, 290, 300, 310.

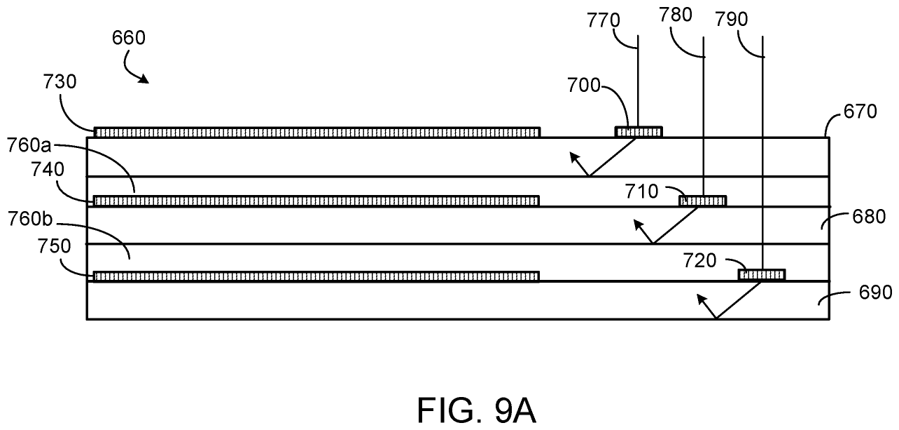

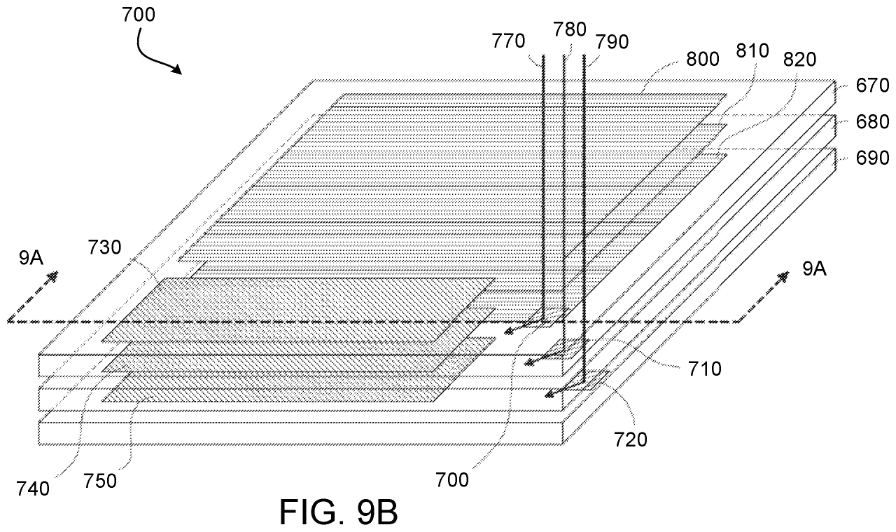

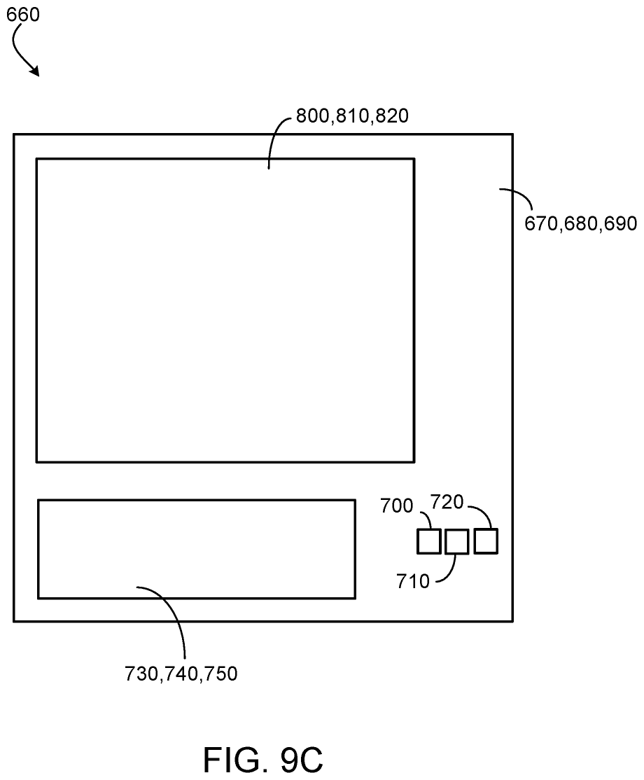

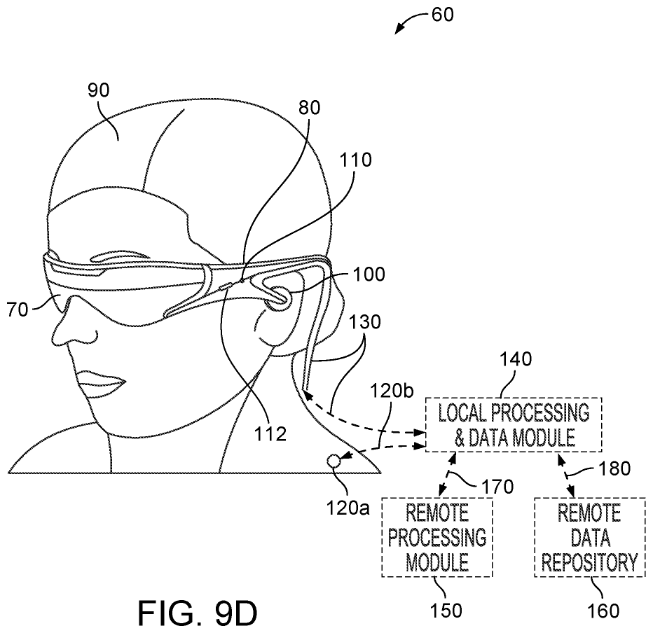

A controller 560 controls the operation of one or more of the stacked waveguide assembly 260, including operation of the image injection devices 360, 370, 380, 390, 400, the light source 530, and the light modulator 540. In some embodiments, the controller 560 is part of the local data processing module 140. The controller 560 includes programming (e.g., instructions in a non-transitory medium) that regulates the timing and provision of image information to the waveguides 270, 280, 290, 300, 310 according to, e.g., any of the various schemes disclosed herein. In some embodiments, the controller may be a single integral device, or a distributed system connected by wired or wireless communication channels. The controller 560 may be part of the processing modules 140 or 150 (FIG. 9D) in some embodiments.

With continued reference to FIG. 6, the waveguides 270, 280, 290, 300, 310 may be configured to propagate light within each respective waveguide by total internal reflection (TIR). The waveguides 270, 280, 290, 300, 310 may each be planar or have another shape (e.g., curved), with major top and bottom surfaces and edges extending between those major top and bottom surfaces. In the illustrated configuration, the waveguides 270, 280, 290, 300, 310 may each include out-coupling optical elements 570, 580, 590, 600, 610 that are configured to extract light out of a waveguide by redirecting the light, propagating within each respective waveguide, out of the waveguide to output image information to the eye 210. Extracted light may also be referred to as out-coupled light and the out-coupling optical elements light may also be referred to light extracting optical elements. An extracted beam of light may be outputted by the waveguide at locations at which the light propagating in the waveguide strikes a light extracting optical element. The out-coupling optical elements 570, 580, 590, 600, 610 may, for example, be gratings, including diffractive optical features, as discussed further herein. While illustrated disposed at the bottom major surfaces of the waveguides 270, 280, 290, 300, 310, for ease of description and drawing clarity, in some embodiments, the out-coupling optical elements 570, 580, 590, 600, 610 may be disposed at the top and/or bottom major surfaces, and/or may be disposed directly in the volume of the waveguides 270, 280, 290, 300, 310, as discussed further herein. In some embodiments, the out-coupling optical elements 570, 580, 590, 600, 610 may be formed in a layer of material that is attached to a transparent substrate to form the waveguides 270, 280, 290, 300, 310. In some other embodiments, the waveguides 270, 280, 290, 300, 310 may be a monolithic piece of material and the out-coupling optical elements 570, 580, 590, 600, 610 may be formed on a surface and/or in the interior of that piece of material.

With continued reference to FIG. 6, as discussed herein, each waveguide 270, 280, 290, 300, 310 is configured to output light to form an image corresponding to a particular depth plane. For example, the waveguide 270 nearest the eye may be configured to deliver collimated light (which was injected into such waveguide 270), to the eye 210. The collimated light may be representative of the optical infinity focal plane. The next waveguide up 280 may be configured to send out collimated light which passes through the first lens 350 (e.g., a negative lens) before it may reach the eye 210; such first lens 350 may be configured to create a slight convex wavefront curvature so that the eye/brain interprets light coming from that next waveguide up 280 as coming from a first focal plane closer inward toward the eye 210 from optical infinity. Similarly, the third up waveguide 290 passes its output light through both the first 350 and second 340 lenses before reaching the eye 210; the combined optical power of the first 350 and second 340 lenses may be configured to create another incremental amount of wavefront curvature so that the eye/brain interprets light coming from the third waveguide 290 as coming from a second focal plane that is even closer inward toward the person from optical infinity than was light from the next waveguide up 280.

The other waveguide layers 300, 310 and lenses 330, 320 are similarly configured, with the highest waveguide 310 in the stack sending its output through all of the lenses between it and the eye for an aggregate focal power representative of the closest focal plane to the person. To compensate for the stack of lenses 320, 330, 340, 350 when viewing/interpreting light coming from the world 510 on the other side of the stacked waveguide assembly 260, a compensating lens layer 620 may be disposed at the top of the stack to compensate for the aggregate power of the lens stack 320, 330, 340, 350 below. Such a configuration provides as many perceived focal planes as there are available waveguide/lens pairings. Both the out-coupling optical elements of the waveguides and the focusing aspects of the lenses may be static (i.e., not dynamic or electro-active). In some alternative embodiments, either or both may be dynamic using electro-active features.

In some embodiments, two or more of the waveguides 270, 280, 290, 300, 310 may have the same associated depth plane. For example, multiple waveguides 270, 280, 290, 300, 310 may be configured to output images set to the same depth plane, or multiple subsets of the waveguides 270, 280, 290, 300, 310 may be configured to output images set to the same plurality of depth planes, with one set for each depth plane. This may provide advantages for forming a tiled image to provide an expanded field of view at those depth planes.

With continued reference to FIG. 6, the out-coupling optical elements 570, 580, 590, 600, 610 may be configured to both redirect light out of their respective waveguides and to output this light with the appropriate amount of divergence or collimation for a particular depth plane associated with the waveguide. As a result, waveguides having different associated depth planes may have different configurations of out-coupling optical elements 570, 580, 590, 600, 610, which output light with a different amount of divergence depending on the associated depth plane. In some embodiments, the light extracting optical elements 570, 580, 590, 600, 610 may be volumetric or surface features, which may be configured to output light at specific angles. For example, the light extracting optical elements 570, 580, 590, 600, 610 may be volume holograms, surface holograms, and/or diffraction gratings. In some embodiments, the features 320, 330, 340, 350 may not be lenses; rather, they may simply be spacers (e.g., cladding layers and/or structures for forming air gaps).

In some embodiments, the out-coupling optical elements 570, 580, 590, 600, 610 are diffractive features that form a diffraction pattern, or “diffractive optical element” (also referred to herein as a “DOE”). Preferably, the DOE's have a sufficiently low diffraction efficiency so that only a portion of the light of the beam is deflected away toward the eye 210 with each intersection of the DOE, while the rest continues to move through a waveguide via TIR. The light carrying the image information is thus divided into a number of related exit beams that exit the waveguide at a multiplicity of locations and the result is a fairly uniform pattern of exit emission toward the eye 210 for this particular collimated beam bouncing around within a waveguide.

In some embodiments, one or more DOEs may be switchable between “on” states in which they actively diffract, and “off” states in which they do not significantly diffract. For instance, a switchable DOE may comprise a layer of polymer dispersed liquid crystal, in which microdroplets comprise a diffraction pattern in a host medium, and the refractive index of the microdroplets may be switched to substantially match the refractive index of the host material (in which case the pattern does not appreciably diffract incident light) or the microdroplet may be switched to an index that does not match that of the host medium (in which case the pattern actively diffracts incident light).

In some embodiments, a camera assembly 630 (e.g., a digital camera, including visible light and infrared light cameras) may be provided to capture images of the eye 210 and/or tissue around the eye 210 to, e.g., detect user inputs and/or to monitor the physiological state of the user. As used herein, a camera may be any image capture device. In some embodiments, the camera assembly 630 may include an image capture device and a light source to project light (e.g., infrared light) to the eye, which may then be reflected by the eye and detected by the image capture device. In some embodiments, the camera assembly 630 may be attached to the frame 80 (FIG. 9D) and may be in electrical communication with the processing modules 140 and/or 150, which may process image information from the camera assembly 630. In some embodiments, one camera assembly 630 may be utilized for each eye, to separately monitor each eye.

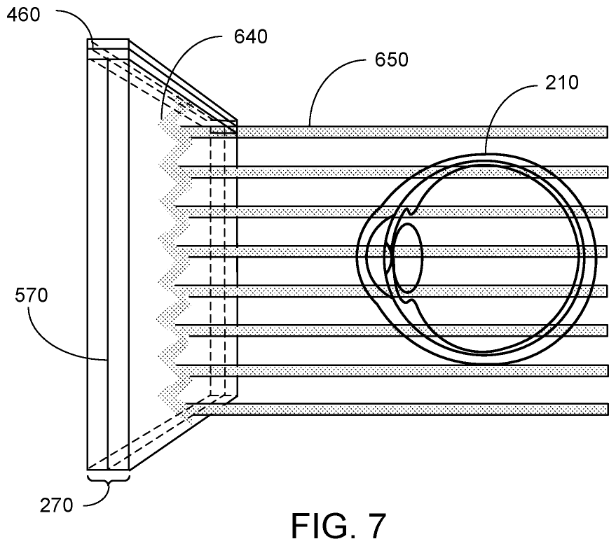

With reference now to FIG. 7, an example of exit beams outputted by a waveguide is shown. One waveguide is illustrated, but it will be appreciated that other waveguides in the waveguide assembly 260 (FIG. 6) may function similarly, where the waveguide assembly 260 includes multiple waveguides. Light 640 is injected into the waveguide 270 at the input surface 460 of the waveguide 270 and propagates within the waveguide 270 by TIR. At points where the light 640 impinges on the DOE 570, a portion of the light exits the waveguide as exit beams 650. The exit beams 650 are illustrated as substantially parallel but, as discussed herein, they may also be redirected to propagate to the eye 210 at an angle (e.g., forming divergent exit beams), depending on the depth plane associated with the waveguide 270. It will be appreciated that substantially parallel exit beams may be indicative of a waveguide with out-coupling optical elements that out-couple light to form images that appear to be set on a depth plane at a large distance (e.g., optical infinity) from the eye 210. Other waveguides or other sets of out-coupling optical elements may output an exit beam pattern that is more divergent, which would require the eye 210 to accommodate to a closer distance to bring it into focus on the retina and would be interpreted by the brain as light from a distance closer to the eye 210 than optical infinity.

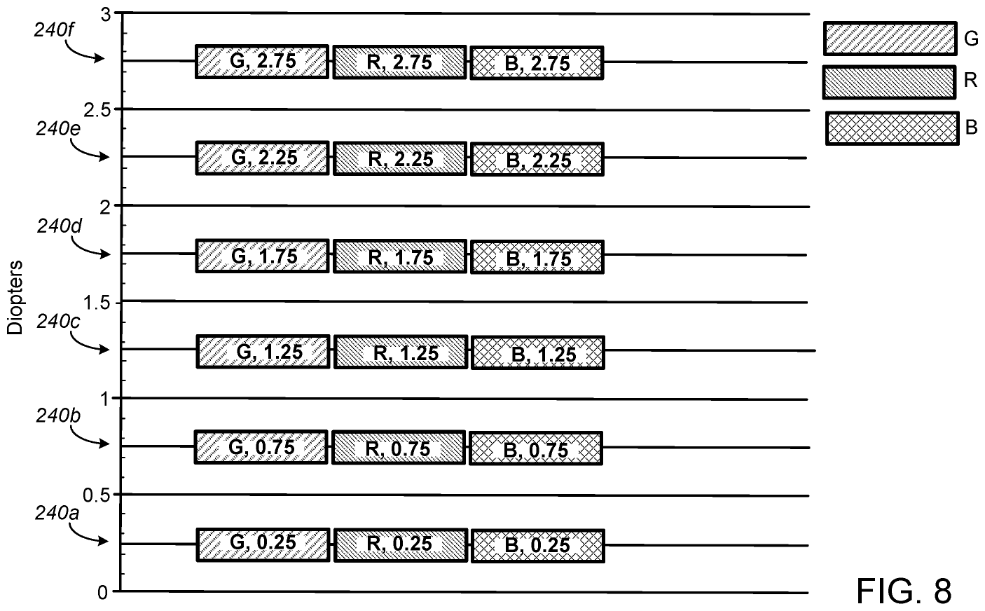

In some embodiments, a full color image may be formed at each depth plane by overlaying images in each of the component colors, e.g., three or more component colors. FIG. 8 illustrates an example of a stacked waveguide assembly in which each depth plane includes images formed using multiple different component colors. The illustrated embodiment shows depth planes 240a-240f, although more or fewer depths are also contemplated. Each depth plane may have three or more component color images associated with it, including: a first image of a first color, G; a second image of a second color, R; and a third image of a third color, B. Different depth planes are indicated in the figure by different numbers for diopters (dpt) following the letters G, R, and B. Just as examples, the numbers following each of these letters indicate diopters (l/m), or inverse distance of the depth plane from a viewer, and each box in the figures represents an individual component color image. In some embodiments, to account for differences in the eye's focusing of light of different wavelengths, the exact placement of the depth planes for different component colors may vary. For example, different component color images for a given depth plane may be placed on depth planes corresponding to different distances from the user. Such an arrangement may increase visual acuity and user comfort and/or may decrease chromatic aberrations.

In some embodiments, light of each component color may be outputted by a single dedicated waveguide and, consequently, each depth plane may have multiple waveguides associated with it. In such embodiments, each box in the figures including the letters G, R, or B may be understood to represent an individual waveguide, and three waveguides may be provided per depth plane where three component color images are provided per depth plane. While the waveguides associated with each depth plane are shown adjacent to one another in this drawing for ease of description, it will be appreciated that, in a physical device, the waveguides may all be arranged in a stack with one waveguide per level. In some other embodiments, multiple component colors may be outputted by the same waveguide, such that, e.g., only a single waveguide may be provided per depth plane.

With continued reference to FIG. 8, in some embodiments, G is the color green, R is the color red, and B is the color blue. In some other embodiments, other colors associated with other wavelengths of light, including magenta and cyan, may be used in addition to or may replace one or more of red, green, or blue.

It will be appreciated that references to a given color of light throughout this disclosure will be understood to encompass light of one or more wavelengths within a range of wavelengths of light that are perceived by a viewer as being of that given color. For example, red light may include light of one or more wavelengths in the range of about 620-780 nm, green light may include light of one or more wavelengths in the range of about 492-577 nm, and blue light may include light of one or more wavelengths in the range of about 435-493 nm.

In some embodiments, the light source 530 (FIG. 6) may be configured to emit light of one or more wavelengths outside the visual perception range of the viewer, for example, infrared and/or ultraviolet wavelengths. In addition, the in-coupling, out-coupling, and other light redirecting structures of the waveguides of the display 250 may be configured to direct and emit this light out of the display towards the user's eye 210, e.g., for imaging and/or user stimulation applications.

In some embodiments, the waveguide stack 260 may include waveguides configured to output light with wavefront divergence corresponding to only a single depth plane. Preferably, the accommodation cues outputted by these waveguides correspond to a depth plane that is less than optical infinity. For example, in some embodiments, the depth plane may be 1 dpt or more, 1.25 dpt or more, or 1.3 dpt or more closer to the user than optical infinity. Advantageously, it has been found that users may have a tolerance for accommodation-vergence mismatching, such that it may be possible to utilize only a single depth plane (based on accommodation cues), inwards from optical infinity, to provide three-dimensional virtual content while maintaining a comfortable viewing experience. The single depth plane may be understood to be within an accommodation-vergence mismatch tolerance of optical infinity, such that virtual content displayed at optical infinity using accommodation cues corresponding to this single depth plane does not cause undesirable viewing discomfort. In addition, virtual content displayed at close distances to the user, but within the accommodation-vergence mismatch tolerance also does not cause undesirable viewing discomfort. In some embodiments, the waveguide stack 260 may utilize one set of waveguides, each displaying different component colors (for example, red, green, and blue). However, the eyepiece may include only a single waveguide for each component color.

With reference now to FIG. 9A, in some embodiments, light impinging on a waveguide may need to be redirected to in-couple that light into the waveguide. An in-coupling optical element may be used to redirect and in-couple the light into its corresponding waveguide. FIG. 9A illustrates a cross-sectional side view of an example of a plurality or set 660 of stacked waveguides that each includes an in-coupling optical element. The waveguides may each be configured to output light of one or more different wavelengths, or one or more different ranges of wavelengths. It will be appreciated that the stack 660 may correspond to the stack 260 (FIG. 6) and the illustrated waveguides of the stack 660 may correspond to part of the plurality of waveguides 270, 280, 290, 300, 310, except that light from one or more of the image injection devices 360, 370, 380, 390, 400 is injected into the waveguides from a position that requires light to be redirected for in-coupling.

The illustrated set 660 of stacked waveguides includes waveguides 670, 680, and 690. Each waveguide includes an associated in-coupling optical element (which may also be referred to as a light input area on the waveguide), with, e.g., in-coupling optical element 700 disposed on a major surface (e.g., an upper major surface) of waveguide 670, in-coupling optical element 710 disposed on a major surface (e.g., an upper major surface) of waveguide 680, and in-coupling optical element 720 disposed on a major surface (e.g., an upper major surface) of waveguide 690. In some embodiments, one or more of the in-coupling optical elements 700, 710, 720 may be disposed on the bottom major surface of the respective waveguide 670, 680, 690 (particularly where the one or more in-coupling optical elements are reflective, deflecting optical elements). As illustrated, the in-coupling optical elements 700, 710, 720 may be disposed on the upper major surface of their respective waveguide 670, 680, 690 (or the top of the next lower waveguide), particularly where those in-coupling optical elements are transmissive, deflecting optical elements. In some embodiments, the in-coupling optical elements 700, 710, 720 may be disposed in the body of the respective waveguide 670, 680, 690. In some embodiments, as discussed herein, the in-coupling optical elements 700, 710, 720 are wavelength selective, such that they selectively redirect one or more wavelengths of light, while transmitting other wavelengths of light. While illustrated on one side or corner of their respective waveguide 670, 680, 690, it will be appreciated that the in-coupling optical elements 700, 710, 720 may be disposed in other areas of their respective waveguide 670, 680, 690 in some embodiments.

As illustrated, the in-coupling optical elements 700, 710, 720 may be laterally offset from one another. In some embodiments, each in-coupling optical element may be offset such that it receives light without that light passing through another in-coupling optical element. For example, each in-coupling optical element 700, 710, 720 may be configured to receive light from a different image injection device 360, 370, 380, 390, and 400 as shown in FIG. 6, and may be separated (e.g., laterally spaced apart) from other in-coupling optical elements 700, 710, 720 such that it substantially does not receive light from the other ones of the in-coupling optical elements 700, 710, 720.

Each waveguide also includes associated light distributing elements, with, e.g., light distributing elements 730 disposed on a major surface (e.g., a top major surface) of waveguide 670, light distributing elements 740 disposed on a major surface (e.g., a top major surface) of waveguide 680, and light distributing elements 750 disposed on a major surface (e.g., a top major surface) of waveguide 690. In some other embodiments, the light distributing elements 730, 740, 750, may be disposed on a bottom major surface of associated waveguides 670, 680, 690, respectively. In some other embodiments, the light distributing elements 730, 740, 750, may be disposed on both top and bottom major surface of associated waveguides 670, 680, 690, respectively; or the light distributing elements 730, 740, 750, may be disposed on different ones of the top and bottom major surfaces in different associated waveguides 670, 680, 690, respectively.

The waveguides 670, 680, 690 may be spaced apart and separated by, e.g., gas, liquid, and/or solid layers of material. For example, as illustrated, layer 760a may separate waveguides 670 and 680; and layer 760b may separate waveguides 680 and 690. In some embodiments, the layers 760a and 760b are formed of low refractive index materials (that is, materials having a lower refractive index than the material forming the immediately adjacent one of waveguides 670, 680, 690). Preferably, the refractive index of the material forming the layers 760a, 760b is 0.05 or more, or 0.10 or less than the refractive index of the material forming the waveguides 670, 680, 690. Advantageously, the lower refractive index layers 760a, 760b may function as cladding layers that facilitate total internal reflection (TIR) of light through the waveguides 670, 680, 690 (e.g., TIR between the top and bottom major surfaces of each waveguide). In some embodiments, the layers 760a, 760b are formed of air. While not illustrated, it will be appreciated that the top and bottom of the illustrated set 660 of waveguides may include immediately neighboring cladding layers.

Preferably, for ease of manufacturing and other considerations, the material forming the waveguides 670, 680, 690 are similar or the same, and the material forming the layers 760a, 760b are similar or the same. In some embodiments, the material forming the waveguides 670, 680, 690 may be different between one or more waveguides, and/or the material forming the layers 760a, 760b may be different, while still holding to the various refractive index relationships noted above.

With continued reference to FIG. 9A, light rays 770, 780, 790 are incident on the set 660 of waveguides. It will be appreciated that the light rays 770, 780, 790 may be injected into the waveguides 670, 680, 690 by one or more image injection devices 360, 370, 380, 390, 400 (FIG. 6).

In some embodiments, the light rays 770, 780, 790 have different properties, e.g., different wavelengths or different ranges of wavelengths, which may correspond to different colors. The incoupling optical elements 700, 710, 720 each deflect the incident light such that the light propagates through a respective one of the waveguides 670, 680, 690 by TIR. In some embodiments, the incoupling optical elements 700, 710, 720 each selectively deflect one or more particular wavelengths of light, while transmitting other wavelengths to an underlying waveguide and associated incoupling optical element.

For example, in-coupling optical element 700 may be configured to deflect ray 770, which has a first wavelength or range of wavelengths, while transmitting rays 780 and 790, which have different second and third wavelengths or ranges of wavelengths, respectively. The transmitted ray 780 impinges on and is deflected by the in-coupling optical element 710, which is configured to deflect light of a second wavelength or range of wavelengths. The ray 790 is deflected by the in-coupling optical element 720, which is configured to selectively deflect light of third wavelength or range of wavelengths.

With continued reference to FIG. 9A, the deflected light rays 770, 780, 790 are deflected so that they propagate through a corresponding waveguide 670, 680, 690; that is, the in-coupling optical elements 700, 710, 720 of each waveguide deflects light into that corresponding waveguide 670, 680, 690 to in-couple light into that corresponding waveguide. The light rays 770, 780, 790 are deflected at angles that cause the light to propagate through the respective waveguide 670, 680, 690 by TIR. The light rays 770, 780, 790 propagate through the respective waveguide 670, 680, 690 by TIR until impinging on the waveguide's corresponding light distributing elements 730, 740, 750.

With reference now to FIG. 9B, a perspective view of an example of the plurality of stacked waveguides of FIG. 9A is illustrated. As noted above, the in-coupled light rays 770, 780, 790, are deflected by the in-coupling optical elements 700, 710, 720, respectively, and then propagate by TIR within the waveguides 670, 680, 690, respectively. The light rays 770, 780, 790 then impinge on the light distributing elements 730, 740, 750, respectively. The light distributing elements 730, 740, 750 deflect the light rays 770, 780, 790 so that they propagate towards the out-coupling optical elements 800, 810, 820, respectively.

In some embodiments, the light distributing elements 730, 740, 750 are orthogonal pupil expanders (OPE's). In some embodiments, the OPE's deflect or distribute light to the out-coupling optical elements 800, 810, 820 and, in some embodiments, may also increase the beam or spot size of this light as it propagates to the out-coupling optical elements. In some embodiments, the light distributing elements 730, 740, 750 may be omitted and the in-coupling optical elements 700, 710, 720 may be configured to deflect light directly to the out-coupling optical elements 800, 810, 820. For example, with reference to FIG. 9A, the light distributing elements 730, 740, 750 may be replaced with out-coupling optical elements 800, 810, 820, respectively. In some embodiments, the out-coupling optical elements 800, 810, 820 are exit pupils (EP's) or exit pupil expanders (EPE's) that direct light in a viewer's eye 210 (FIG. 7). It will be appreciated that the OPE's may be configured to increase the dimensions of the eye box in at least one axis and the EPE's may be to increase the eye box in an axis crossing, e.g., orthogonal to, the axis of the OPEs. For example, each OPE may be configured to redirect a portion of the light striking the OPE to an EPE of the same waveguide, while allowing the remaining portion of the light to continue to propagate down the waveguide. Upon impinging on the OPE again, another portion of the remaining light is redirected to the EPE, and the remaining portion of that portion continues to propagate further down the waveguide, and so on. Similarly, upon striking the EPE, a portion of the impinging light is directed out of the waveguide towards the user, and a remaining portion of that light continues to propagate through the waveguide until it strikes the EP again, at which time another portion of the impinging light is directed out of the waveguide, and so on. Consequently, a single beam of incoupled light may be “replicated” each time a portion of that light is redirected by an OPE or EPE, thereby forming a field of cloned beams of light, as shown in FIG. 6. In some embodiments, the OPE and/or EPE may be configured to modify a size of the beams of light.

In some embodiments, the light distributing elements 730, 740, 750 may be omitted. In such embodiments, the in-coupling optical elements 700, 710, 720 may deflect the light rays 770, 780, 790 so that they propagate by TIR directly towards the out-coupling optical elements 800, 810, 820, respectively.

Accordingly, with reference to FIGS. 9A and 9B, in some embodiments, the set 660 of waveguides includes waveguides 670, 680, 690; in-coupling optical elements 700, 710, 720; light distributing elements (e.g., OPE's) 730, 740, 750; and out-coupling optical elements (e.g., EP's) 800, 810, 820 for each component color. The waveguides 670, 680, 690 may be stacked with an air gap/cladding layer between each one. The in-coupling optical elements 700, 710, 720 redirect or deflect incident light (with different in-coupling optical elements receiving light of different wavelengths) into its waveguide. The light then propagates at an angle which will result in TIR within the respective waveguide 670, 680, 690. In the example shown, light ray 770 (e.g., blue light) is deflected by the first in-coupling optical element 700, and then continues to bounce down the waveguide, interacting with the light distributing element (e.g., OPE's) 730 and then the out-coupling optical element (e.g., EPs) 800, in a manner described earlier. The light rays 780 and 790 (e.g., green and red light, respectively) will pass through the waveguide 670, with light ray 780 impinging on and being deflected by in-coupling optical element 710. The light ray 780 then bounces down the waveguide 680 via TIR, proceeding on to its light distributing element (e.g., OPEs) 740 and then the out-coupling optical element (e.g., EP's) 810. Finally, light ray 790 (e.g., red light) passes through the waveguide 690 to impinge on the light in-coupling optical elements 720 of the waveguide 690. The light in-coupling optical elements 720 deflect the light ray 790 such that the light ray propagates to light distributing element (e.g., OPEs) 750 by TIR, and then to the out-coupling optical element (e.g., EPs) 820 by TIR. The out-coupling optical element 820 then finally out-couples the light ray 790 to the viewer, who also receives the out-coupled light from the other waveguides 670, 680.

FIG. 9C illustrates a top-down plan view of an example of the plurality of stacked waveguides of FIGS. 9A and 9B. As illustrated, the waveguides 670, 680, 690, along with each waveguide's associated light distributing element 730, 740, 750 and associated out-coupling optical element 800, 810, 820, may be vertically aligned. However, as discussed herein, the in-coupling optical elements 700, 710, 720 are not vertically aligned; rather, the in-coupling optical elements are preferably non-overlapping (e.g., laterally spaced apart as seen in the top-down view). As discussed further herein, this nonoverlapping spatial arrangement facilitates the injection of light from different resources into different waveguides on a one-to-one basis, thereby allowing a specific light source to be uniquely coupled to a specific waveguide. In some embodiments, arrangements including nonoverlapping spatially-separated in-coupling optical elements may be referred to as a shifted pupil system, and the in-coupling optical elements within these arrangements may correspond to sub pupils.

FIG. 9D illustrates an example of wearable display system 60 into which the various waveguides and related systems disclosed herein may be integrated. In some embodiments, the display system 60 is the system 250 of FIG. 6, with FIG. 6 schematically showing some parts of that system 60 in greater detail. For example, the waveguide assembly 260 of FIG. 6 may be part of the display 70.

With continued reference to FIG. 9D, the display system 60 includes a display 70, and various mechanical and electronic modules and systems to support the functioning of that display 70. The display 70 may be coupled to a frame 80, which is wearable by a display system user or viewer 90 and which is configured to position the display 70 in front of the eyes of the user 90. The display 70 may be considered eyewear in some embodiments. In some embodiments, a speaker 100 is coupled to the frame 80 and configured to be positioned adjacent the ear canal of the user 90 (in some embodiments, another speaker, not shown, may optionally be positioned adjacent the other ear canal of the user to provide stereo/shapeable sound control). The display system 60 may also include one or more microphones 110 or other devices to detect sound. In some embodiments, the microphone is configured to allow the user to provide inputs or commands to the system 60 (e.g., the selection of voice menu commands, natural language questions, etc.), and/or may allow audio communication with other persons (e.g., with other users of similar display systems. The microphone may further be configured as a peripheral sensor to collect audio data (e.g., sounds from the user and/or environment). In some embodiments, the display system 60 may further include one or more outwardly-directed environmental sensors 112 configured to detect objects, stimuli, people, animals, locations, or other aspects of the world around the user. For example, environmental sensors 112 may include one or more cameras, which may be located, for example, facing outward so as to capture images similar to at least a portion of an ordinary field of view of the user 90. In some embodiments, the display system may also include a peripheral sensor 120a, which may be separate from the frame 80 and attached to the body of the user 90 (e.g., on the head, torso, an extremity, etc. of the user 90). The peripheral sensor 120a may be configured to acquire data characterizing a physiological state of the user 90 in some embodiments. For example, the sensor 120a may be an electrode.

With continued reference to FIG. 9D, the display 70 is operatively coupled by communications link 130, such as by a wired lead or wireless connectivity, to a local data processing module 140 which may be mounted in a variety of configurations, such as fixedly attached to the frame 80, fixedly attached to a helmet or hat worn by the user, embedded in headphones, or otherwise removably attached to the user 90 (e.g., in a backpack-style configuration, in a belt-coupling style configuration). Similarly, the sensor 120a may be operatively coupled by communications link 120b, e.g., a wired lead or wireless connectivity, to the local processor and data module 140. The local processing and data module 140 may comprise a hardware processor, as well as digital memory, such as non-volatile memory (e.g., flash memory or hard disk drives), both of which may be utilized to assist in the processing, caching, and storage of data. Optionally, the local processor and data module 140 may include one or more central processing units (CPUs), graphics processing units (GPUs), dedicated processing hardware, and so on. The data may include data a) captured from sensors (which may be, e.g., operatively coupled to the frame 80 or otherwise attached to the user 90), such as image capture devices (such as cameras), microphones, inertial measurement units, accelerometers, compasses, GPS units, radio devices, gyros, and/or other sensors disclosed herein; and/or b) acquired and/or processed using remote processing module 150 and/or remote data repository 160 (including data relating to virtual content), possibly for passage to the display 70 after such processing or retrieval. The local processing and data module 140 may be operatively coupled by communication links 170, 180, such as via a wired or wireless communication links, to the remote processing module 150 and remote data repository 160 such that these remote modules 150, 160 are operatively coupled to each other and available as resources to the local processing and data module 140. In some embodiments, the local processing and data module 140 may include one or more of the image capture devices, microphones, inertial measurement units, accelerometers, compasses, GPS units, radio devices, and/or gyros. In some other embodiments, one or more of these sensors may be attached to the frame 80, or may be standalone structures that communicate with the local processing and data module 140 by wired or wireless communication pathways.

With continued reference to FIG. 9D, in some embodiments, the remote processing module 150 may comprise one or more processors configured to analyze and process data and/or image information, for instance including one or more central processing units (CPUs), graphics processing units (GPUs), dedicated processing hardware, and so on. In some embodiments, the remote data repository 160 may comprise a digital data storage facility, which may be available through the internet or other networking configuration in a “cloud” resource configuration. In some embodiments, the remote data repository 160 may include one or more remote servers, which provide information, e.g., information for generating augmented reality content, to the local processing and data module 140 and/or the remote processing module 150. In some embodiments, all data is stored and all computations are performed in the local processing and data module, allowing fully autonomous use from a remote module. Optionally, an outside system (e.g., a system of one or more processors, one or more computers) that includes CPUs, GPUs, and so on, may perform at least a portion of processing (e.g., generating image information, processing data) and provide information to, and receive information from, modules 140, 150, 160, for instance via wireless or wired connections.

### Example Waveguide Structures

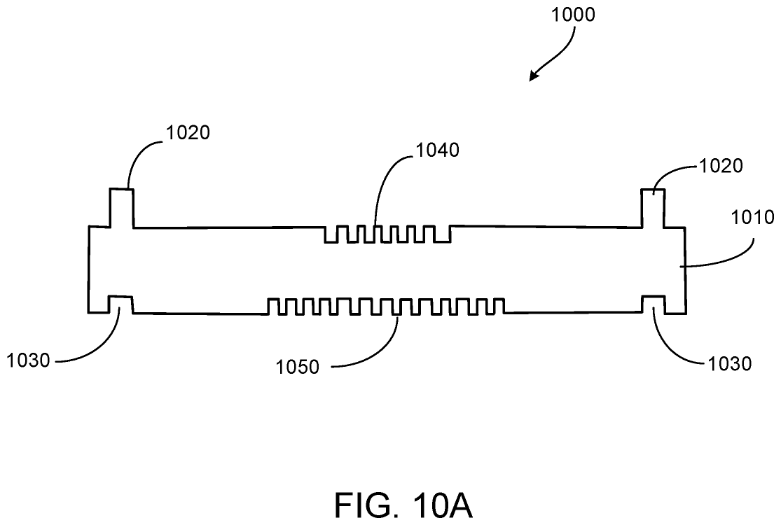

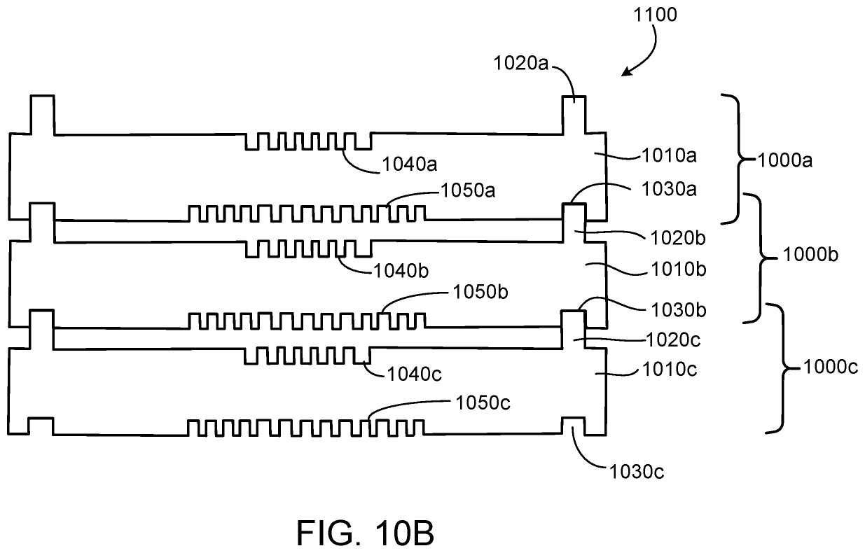

Referring now to FIG. 10A, an example of a waveguide comprising spacers is illustrated. A waveguide 1000 comprises a main optically transmissive body 1010 and spacers 1020 extending vertically from a major surface 1022 of the main body 1010. Preferably, the spacers 1020 are integral with the waveguide 1000 and form a monolithic structure with at least a part of the waveguide defining the major surface 1022. More preferably, the spacers 1020 form a monolithic structure with the entire waveguide 1000, with the material of the waveguide 1000 extending vertically to form the spacers 1020. As a result, the spacers 1020 and main body 1010 may be formed of the same material and be without an intervening boundary.

In some embodiments, the spacers 1020 may be formed of a different material than the main body 1010, such that an intervening boundary exists at the interface of the spacers 1020 and the main body 1010. For example, the spacers 1020 may comprise locally deposited material, which is then imprinted to form the spacers 1020.

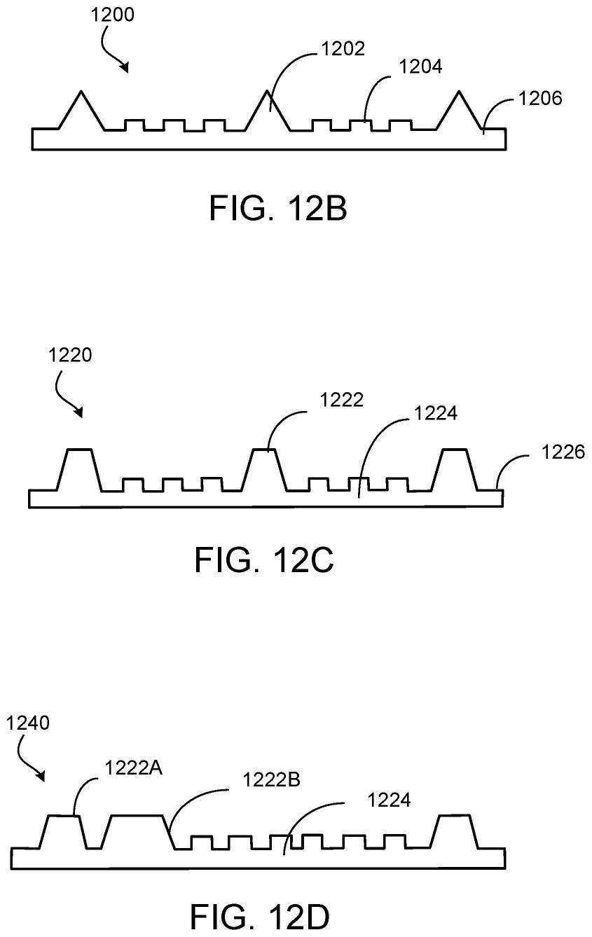

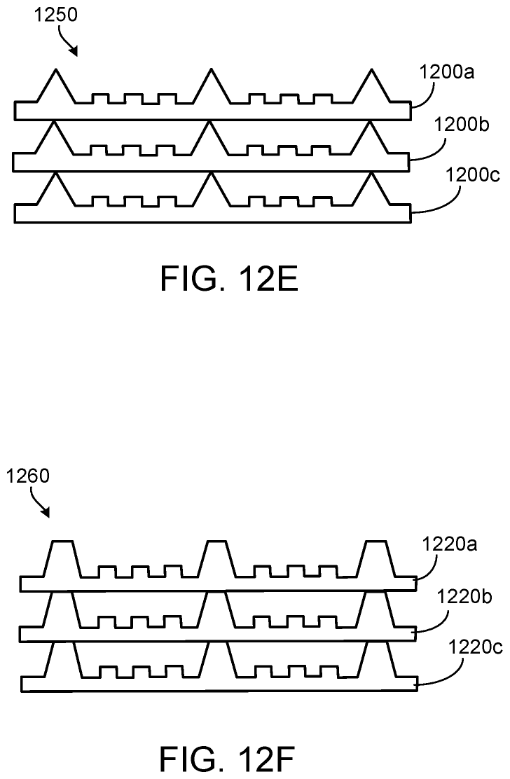

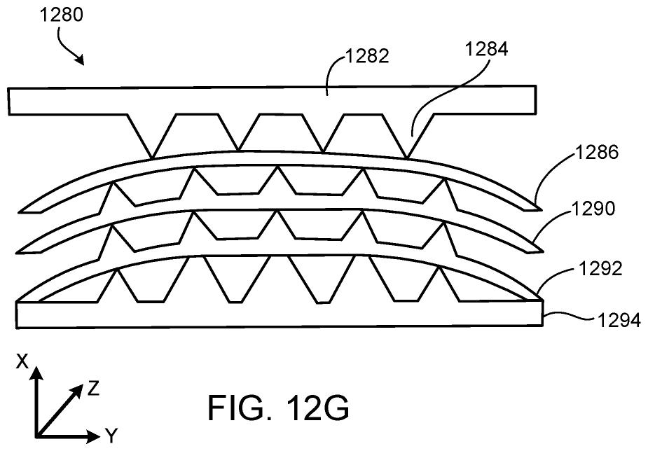

In some embodiments, indentations 1030 are provided extending into a major surface 1032 of the waveguide 1000. As illustrated, the major surface 1032 and, thus, the indentations 1030 are disposed on a side of the waveguide 1000 opposite the major surface 1022. As discussed further herein, the indentations 1030 are preferably positioned, shaped, and sized such that spacers of an underlying waveguide (not illustrated) may be accommodated within those indentations 1030. Similarly, the spacers 1020 are preferably position, shaped, and sized such that they may be accommodated within indentations of an overlying waveguide (not illustrated). In some embodiments, the waveguide 1000 may be provided without indentations 1030 and any underlying spacers may simply contact the major surface 1032, such as the embodiments as illustrated in FIGS. 12E-F. In some embodiments, the waveguide 1000 may be curved such as illustrated in FIG. 12G.

With continued reference to FIG. 10A, in some embodiments, the major surface 1022 may comprise surface relief features 1040. As illustrated, the spacers 1020 extend vertically to a height greater than the top of the surface relief features 1040. Preferably, the spacers 1020 have a height sufficient to space the waveguide 1000 from an overlying waveguide by a desired separation distance, e.g., 30 μm or more. In some embodiments, the spacers 1020 have a height of 30 μm or more. As discussed herein, the spacers 1020 may fit within the indentations 1030 of an overlying waveguide in some embodiments. In such embodiments, the height of the spacers 1020 may be equal to the desired separation between waveguides (e.g., 30 μm) plus the height of the indentations in which the spacers are inserted.

Additionally or alternatively to the surface relief features 1040, in some embodiments, the opposing major surface 1032 may comprise surface relief features 1050. In some embodiments, one or both of the surface relief features 1040 and 1050 may include a pattern of protrusions and indentations sized and arranged to form a diffractive optical element, such as diffractive gratings. It will be appreciated that such diffractive optical elements may correspond to one or more of the in-coupling optical elements 700, 710, 720; light distributing elements 730, 740, 750; or out-coupling optical elements 800, 810, 820 of FIGS. 9A-9C. In some embodiments, the waveguide 1000 may omit one or both of the surface relief features 1040, 1050 such that the major surfaces 1022, 1032 may be smooth except for spacers 1020, 1030, respectively.

In some embodiments, the surface relief features 1040, 1050 may advantageously increase the density of surface relief features across a given expanse of the waveguide 1000 and may be identical. In some other embodiments, the surface relief features 1040, 1050 may be different. For example, the surface relief features 1040 may be configured to diffract light of different wavelengths and/or different incident angles and/or to output light at different angles from the surface relief features 1050.

With continued reference to FIG. 10A, the waveguide 1000 is formed of an optically transmissive material, e.g., a highly transparent material. Preferably, the material has a high refractive index, which may provide advantages for providing a large field of view. In some embodiments, the material has a refractive index greater than 1.5, or greater than 1.65. The material forming the waveguide 1000 may be a highly transparent polymer material, e.g., an organic polymer material. Examples of high refractive index materials include polyimide-based high index resins, halogen-containing (e.g., bromine or iodine-containing) polymers, phosphorous containing polymers, thiol-ene based polymers, and high refractive index resin materials. Examples of high refractive index resin materials include those commercially available from NTT-AT of Kawasaki-shi, Kanagawa, Japan, such as the high refractive index resins sold under the name #565 and #566; and high refractive index resin materials commercially available from Akron Polymer System of Akron, Ohio, USA, such as the high refractive index resins sold under the name APS-1000, APS2004, APS-4001, and as part of the APS 3000 series.

With reference now to FIG. 10B, in some embodiments, one or more of the waveguides 1000a, 1000b, 1000c may comprise surface relief features on one or more major surfaces of those waveguides. For example, each of these waveguides may comprise surface relief features 1040a, 1050b corresponding to the surface relief features 1040, 1050 of the waveguide 1000 (FIG. 10A). In some embodiments, different ones of the waveguides 1000a, 1000b, 1000c may include diffractive optical elements configured to incouple and/or outcouple light of different wavelengths, e.g., corresponding to different component colors for forming a full-color image. For example, the waveguides 1000a, 1000b, 1000c may correspond to the waveguides 670, 680, 690 of FIGS. 9A-9C.

It will be appreciated that light may propagate through the waveguides 1000a, 1000b, 1000c by total internal reflection, e.g., from incoupling optical elements to outcoupling optical elements. In addition, light leakage between the waveguides may degrade image quality. To reduce the likelihood that the spacers 1020, 1020a, 1020b, 1020c may be conduits for light leakage between waveguides, the spacers 1020, 1020a, 1020b, 1020c are preferably disposed at locations that are out of the path of propagation of light between incoupling optical elements and outcoupling optical elements.

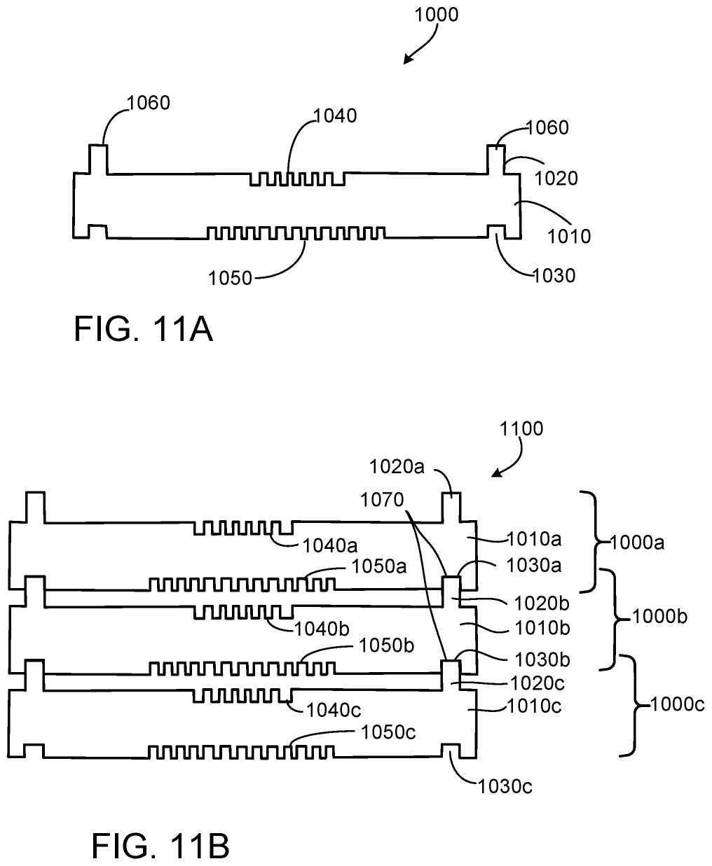

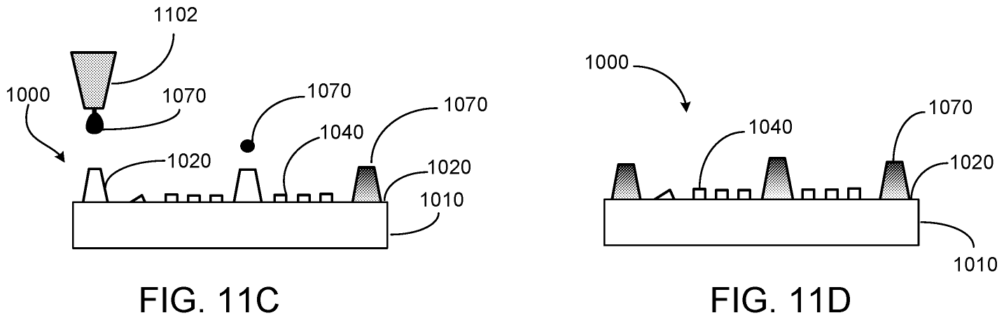

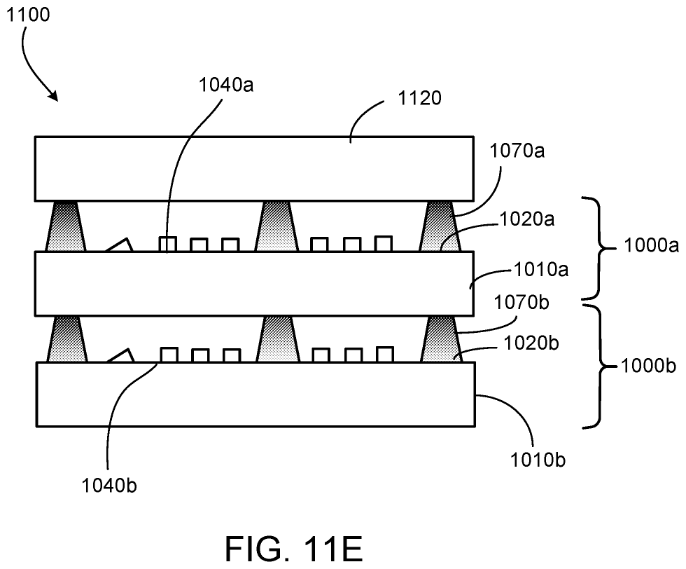

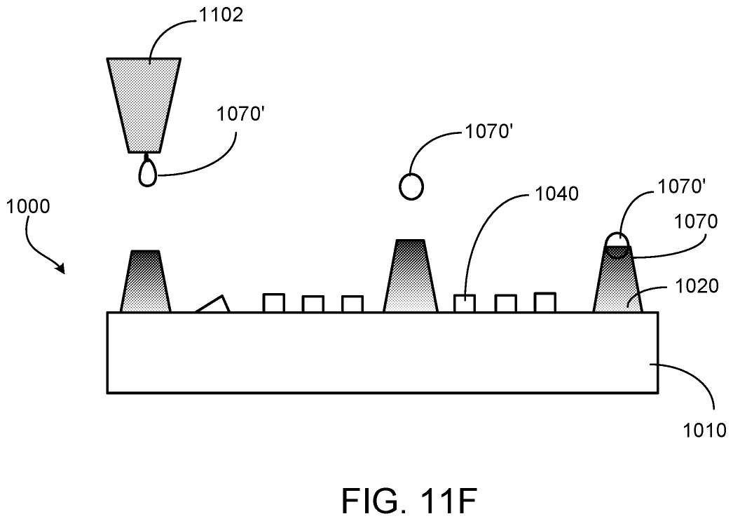

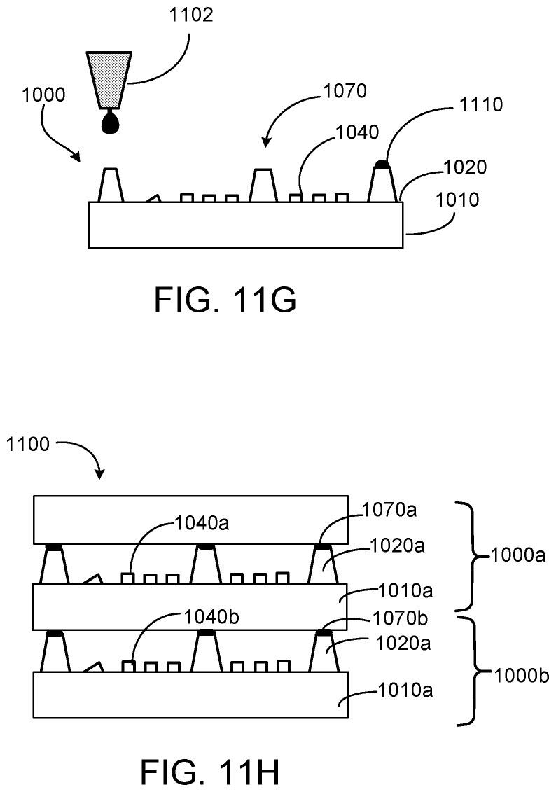

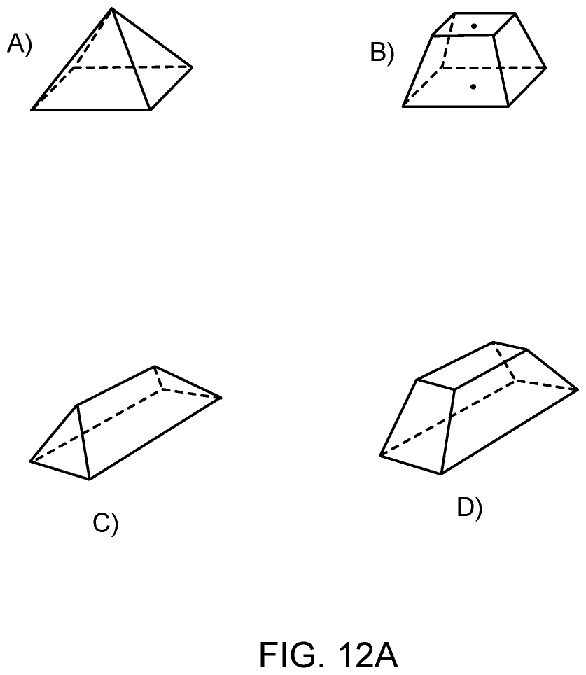

In some embodiments, light leakage between waveguides may be mitigated using one or both of light scattering features and light leakage prevention materials at the interface between spacers 1020, 1020a, 1020b, 1020c and immediately adjacent waveguides. Examples of light leakage prevention materials include light absorbing materials and layers of material forming anti-reflective coatings. FIG. 11A illustrates an example of a waveguide comprising spacers 1020 with light scattering features 1060 on surfaces of the spacers that are configured to interface with an overlying waveguide. In some embodiments, the light scattering features 1060 may take the form of peaks and valleys (e.g., irregularly oriented peaks and valleys) on the surface of the spacers 1020. In some embodiments, the light scattering features 1060 may be provided only on top surfaces of the spacers. In some other embodiments, the light scattering features 1060 may also extend on the sides of the spacers 1020. It will be appreciated that light scattering features 1060 may be formed by roughening surfaces of the spacers 1020, e.g., by abrasion. In some embodiments, the light scattering features 1060 may be formed during the formation of the spacers 1020. For example, spacers 1020 may be formed by imprinting, and the mold used to form the spacers 1020 may include a pattern to form the light scattering features 1060 at the tops of the spacers 1020 thereby advantageously allowing simultaneous formation of the waveguide features (e.g., diffractive optical elements 1040), spacers 1020, and the light scattering features 1060. It will be appreciated that conventional waveguide materials such as glasses are generally considered not compatible with such simultaneous formation, due to concerns regarding breakage of discrete integral protrusions such as spacers and an inability to accurately reproduce the constituent features that form the diffractive optical elements 1040 and light scattering features 1060.

As noted above, in some embodiments, one or more layers of material may be utilized to prevent light leakage between spacers and waveguides. FIG. 11B illustrates an example of a stack of waveguides 1100 comprising spacers 1020a, 1020b, 1020c and light leakage prevention material 1070 at the interface between the spacers and immediately neighboring ones of the waveguides 1000a, 1000b, 1000c. For example, light leakage prevention material 1070 may be a light absorbing material and/or one or more layers of material forming an antireflective coating. The light leakage prevention material 1070 may be provided between spacers 1020b and waveguide 1000a. Light leakage prevention material 1070 may also be provided between spacers 1020c and waveguide 1000b. In some embodiments, the light leakage prevention material 1070 may be applied to the spacers before attaching the spacers to another waveguide. For example, light leakage prevention material 1070 may be deposited on surfaces of the spacers before inserting the spacers into matching indentations in an overlying waveguide. Examples of light absorbing materials to serve as the light leakage prevention material 1070 include carbon black, meso-porous carbon, carbon nanotubes (single-walled as well as multi-walled nanotubes). Example of carbon nanotubes include single atom carbon nanotubes such as VANTA BLACK® available from Surrey NanoSystems of Newhaven, the United Kingdom. In some embodiments, the light leakage prevention material 1070 may be a light absorbing adhesive which may be used to adhere the spacers to an overlying waveguide. In some embodiments, the spacers may include light scattering features and light leakage prevention materials at the interface between the spacers and an overlying waveguide.

With continued reference to FIG. 11B, the light leakage prevention material 1070 may form an anti-reflective coating. Examples of anti-reflective coatings include single and multi-layer anti-reflective coatings formed of partially reflective and partially transmissive layers of material.

In some embodiments, the light leakage prevention material 1070 may include a polymer such as a curable polymer, including a resin. In some embodiments, the light leakage prevention material 1070 may be the same material as the material of the spacer 1020, such as discussed herein. In some embodiments, the light leakage prevention material 1070 may be different from the material forming the spacer 1020. In some embodiments, the light leakage prevention material 1070 may include a curable material such as a curable resin. In some embodiments, the curable material may be a UV curable resin and/or a heat curable resin. In some embodiments, the light leakage prevention material 1070 may function as an adhesive to adhere the spacers to an overlying waveguide. In some embodiments, the light leakage prevention material 1070 may be non-adhesive, and an adhesive may further be deposited on the light leakage prevention material 1070 in some embodiments.

In some embodiments, the light leakage prevention material 1070 may comprise epoxy vinyl esters. In some embodiments, the vinyl monomer for the epoxy vinyl esters may be methyl methacrylate, difunctional or trifunctional vinyl monomers such as diacrylates, triacrylates, and dimethacrylates. In some embodiments, the monomer epoxy vinyl esters may have or not have one or more aromatic molecules. In some embodiments, the refractive index of the curable material used as the light leakage prevention material 1070 may have a high refract index, such as above about 1.5, or above about 1.65. In some embodiments, the refractive index of the curable material used as the light leakage prevention material 1070 may be within a range from about 1.5 to about 1.9, from about 1.5 to about 1.8, or from 1.5 to about 1.7.

In some embodiments, the light leakage prevention material 1070 may be colored. For example, the light leakage prevention material 1070 may be colored in black, blue, green, red, cyan, magenta, orange, or other colors. In some embodiments, the light leakage prevention material 1070 may be colored by adding pigments and/or dye to the light leakage prevention material such as UV curable and/or heat curable polymer materials, such as resins. In some implementations, the light leakage prevention material 1070 is a mixture of materials, e.g., pigments and dyes. In some embodiments, the pigments may be nanoparticle pigments, for example, carbon black, rhodamine B, tartrazine, blue 38, other commercially available pigments suitable for addition to the light leakage prevention material 1070. In some embodiments, the amount of pigment and/or dyes may be up to about 5% w/w, about 10% w/w, about 15% w/w, about 20% w/w, or other weight percentage sufficient to provide a desired light absorption. It is appreciated that in theory a light leakage prevention material 1070 in a specific color may absorb light of the same specific color, or light of a specific wavelength range. For example, a red light leakage prevention material 1070 may absorb red light or light in the range of from about 620 nm to about 750 nm. It is appreciated that a black light leakage prevention material 1070 may absorb all visible light.

In some embodiments, the light leakage prevention material 1070 may absorb light of a certain range of wavelengths, corresponding to a particular color or colors. For example, the light leakage prevention material 1070 may absorb blue, green, and/or red light. In some embodiments, the light leakage prevention material 1070 may absorb light of a narrow range or narrow ranges. For example, the light leakage prevention material 1070 may absorb light having a wavelength range centered at about 455 nm, about 530 nm, about 630 nm, or other wavelengths. In some embodiments, the width of the wavelength range of the light absorbed by the light leakage prevention material 1070 may be about 100 nm, about 80 nm, about 60 nm, about 30 nm, about 20 nm, or other ranges. In some embodiments, the light leakage prevention material 1070 may absorb light of a broad range. In some embodiments, the light leakage prevention material 1070 may absorb light from about 400 nm to about 800 nm, from about 300 nm to about 1000 nm, or any other ranges. In some embodiments, the wavelength range of the light that the light leakage prevention material 1070 absorbs may encompass or overlap the wavelength range of the light configured to be in coupled by the waveguide on which the material is deposited and/or the wavelength range of light that the overlying waveguide is configured to incouple. For example, if the overlying waveguide in contact with the spacers is configured to propagate a light of color red, a material that absorbs red light may be selected as a light leakage prevention material 1070.

In some embodiments, the light leakage prevention materials may be provided on the surfaces of the spacers, between spacers and an overlying waveguide. In some embodiments, the light leakage prevention materials 1070 may be dispensed on the surface of the spacers by inkjet printing. In some embodiments, the inkjet printing comprises drop-on-demand (DOD) inkjet printing. Advantageously, a drop-on-demand inkjet printing may be low cost, capable of high throughput, and allow a high degree of precision in selecting the quantity and location of material being dispensed.

FIGS. 11C-11H illustrate examples of drop-on-demand (DOD) inkjet printing. With reference to FIG. 11C, a waveguide 1000 comprising spacers 1020 is provided. After an inkjet printer nozzle 1102 is placed above a spacer to be coated, the inkjet printer nozzle 1102 may eject a droplet of light leakage prevention materials 1070 from the nozzle 1102. In some embodiments, the inkjet printer may comprise a piezoelectric actuator or a thermal element configured to release the droplet when the inkjet printer receives an appropriate triggering signal. Then the inkjet printer nozzle 1102 may move to the next spacer and eject another droplet of light leakage prevention material 1070 on the next spacer. In some embodiments, a plurality of inkjet printer nozzles 1102 may be provided to simultaneously deposit light leakage prevention material 1070 on multiple spacers. In some embodiments, the light leakage prevention material 1070 may have a lower viscosity and may be a flowable material. In some embodiments, after the droplet of light leakage prevention material 1070 drops on the top surface of a spacer 1020, the droplet of light leakage prevention material 1070 may spread from the top surface of the spacer 1020 down to the bottom of the spacer 1020. FIG. 11D illustrates an example waveguide 1000 after inkjet printing. In some embodiments, the light leakage prevention materials 1070 may cover most or all of the top surface of a spacer 1020, and may extend over side surfaces of the spacer, after inkjet printing as illustrated in FIG. 11D. In some embodiments, covering the side surfaces of the spacer 1020 with the light leakage prevention material 1070 may advantageously increase the amount of light absorbed due to the increased light absorbing surface area. In some embodiments, the light leakage prevention material 1070 may subsequently be exposed to UV light or heat to cure the light leakage prevention material 1070. In some embodiments, the application of heat may evaporate liquid in the light leakage prevention material 1070.

In some embodiments, an adhesive may be applied onto the light leakage prevention material 1072 to adhere the spacer 1072 to an overlying structure, such as a waveguide or a cover plate. In some embodiments, the adhesive may be a curable polymer, such as a resin.

FIG. 11E illustrates an example waveguide stack 1100 comprising waveguides 1000a and 1000b, and structure 1120. In some embodiments, structure 1120 may be another waveguide or a waveguide cover plate. It will be appreciated that an adhesive may be disposed directly between the various spacers 1070a, 1070b and the overlying waveguide 1010a or structure 1120. In some other embodiments, the light leakage prevention material may be an adhesive and may be used to adhere the spacers 1020b to the overlying waveguide 1000a or adhere the spacers 1020a to the cover plate 1120.

With reference to FIG. 11F, in some embodiments, another light leakage prevention material 1070′ may be dispensed onto the spacers 1020 after a light leakage prevention material 1070 is dispensed onto the spacers 1020 as illustrated in FIG. 11D. In some embodiments, the light leakage prevention material 1070′ is dispensed onto spacers 1020 using inkjet printing technique as discussed above. In some embodiments, the light leakage prevention material 1070′ may be any light leakage prevention material as discussed above. In some embodiments, the light leakage prevention material 1070′ may be a different material from the light leakage prevention material 1070. In some embodiments, a UV light or heat may be applied to the waveguide 1000 after the light leakage prevention material 1070′ being dispensed onto the spacers 1020 to cure the light leakage prevention material 1070′. In some embodiments, the light leakage prevention material 1070′ may have at least one property different from the light leakage prevention material 1070, such as adhesion, light absorbing property, viscosity, etc. For example, in some embodiments, the light leakage prevention material 1070′ may have better adhesive properties than the light leakage prevention material 1070. In some embodiments, the viscosity of the light leakage prevention material 1070′ may be higher than the light leakage prevention material 1070. In some embodiments, the light leakage prevention material 1070′ may not flow off the top surface of spacers 1020.

FIGS. 11G-11H illustrate another example of drop-on-demand (DOD) inkjet printing. With reference to FIGS. 11G-11H, in some embodiments, the light leakage prevention material 1070 may be an adhesive, and the amount of dispensed material and/or the viscosity of the material cause the material to be substantially localized on a top surface of the spacers 1020. In some embodiments, the light leakage prevention material 1070 may not flow or spread off the top surface of the spacers 1020 after being dispensed onto the spacers 1020. With reference to FIG. 11G, in some embodiments, when the waveguide 1000 comprising the light leakage prevention material 1070 on top of the spacers 1020 is assembled in a waveguide stack 1100 with some pressure or force, the light leakage prevention material 1070 may spread substantially evenly on the top surface of the spacers 1020 to form an adhesive layer.

In some embodiments, the spacers 1020 may have a tapered shape (or having inclined sidewalls). In some embodiments, the tops of spacers 1020 may be in contact with an overlying structure such as a waveguide. Examples of tapered shapes for spacers are shown in shapes A-D of FIG. 12A. It will be appreciated that the contact area between a spacer having such a tapered shape and an overlying structure may be smaller than the contact area between a prism or a cylinder and an overlying structure with similar base areas. As discussed above, light leakage between the waveguides may degrade image quality. Such smaller contact areas may provide the advantage of reducing or preventing the likelihood that the spacers 1020 may be conduits for light leakage between waveguides. In addition, it will be appreciated that a spacer having such a tapered shape may provide the advantage of easier to demold if the spacers are formed by imprinting using a mold comparing to a spacer having a prism or cylindrical shape. In FIGS. 11C-11H, in some embodiments, the light leakage prevention material 1070 and/or 1070′ may be colored. For example, the light leakage prevention material may be colored in black, blue, green, red, cyan, magenta, orange, or other colors. In some embodiments, the light leakage prevention material may be colored by adding pigments and/or dye to the light leakage prevention material such as UV curable and/or heat curable polymer materials, such as resins. In some implementations, the light leakage prevention material is a mixture of materials, e.g., pigments and dyes. In some embodiments, the pigments may be nanoparticle pigments, for example, carbon black, rhodamine B, tartrazine, blue 38, other commercially available pigments suitable for addition to the light leakage prevention material. In some embodiments, the amount of pigment and/or dyes may be up to about 5% w/w, about 10% w/w, about 15% w/w, about 20% w/w, or other weight percentage sufficient to provide a desired light absorption. It is appreciated that in theory a light leakage prevention material in a specific color may absorb light of the same specific color, or light of a specific wavelength range. For example, a red light leakage prevention material may absorb red light or light in the range of from about 620 nm to about 750 nm. It is appreciated that a black light leakage prevention material may absorb all visible light.

With reference to FIG. 12A, in some embodiments, the contact areas between the spacers 1020 and the surface of an overlying structure such as a waveguide may be a point, a line, or a flat surface. In some embodiments, the spacers 1020 may be a pointed shape, such as a rectangular pyramid (shape A). The contact area between a spacer having a pointed shape and an overlying structure such as a waveguide may be a point. It will be appreciated that such a point contact between a spacer and the overlying structure such as a waveguide may provide advantages for reduced or no light leakage between waveguides, easier demolding, structural stability, and mechanical strength, particularly where the waveguides are utilized to form stacks of similar waveguides.

With continued reference to FIG. 12A, in some embodiments, the spacers 1020 may have a tapered shape with a flat top surface. An example of a tapered shape with a flat top surface is a frustum, such as a frustum of a rectangular pyramid as shown in shapes B and D of FIG. 12A. It will be appreciated that such a tapered shape with a flat top surface may provide advantages for reduced light leakage, easier demolding, stronger structural stability, and mechanical strength, particularly where the waveguides are utilized to form stacks of similar waveguides. The stability and mechanical strength provided by a spacer having a tapered shape with flat top surface may be at least partially related to the area of contact surface between the spacer and the overlying structure. For example, the stability and mechanical strength may be better if the area of contact surface is larger.

With continued reference to FIG. 12A, in some embodiments, the spacers 1020 may have a laterally-elongated shape such as an elongated rectangular pyramid as shown in shape C of FIG. 12A. In some embodiments, the contact area between the spacers having a laterally-elongated shape may be a line or an area. In some embodiments, the laterally-elongated shape may be a tapered shape. It will be appreciated that a spacer having such a laterally-elongated shape may provide advantages for reduced light leakage, easier demolding, structural stability and mechanical strength, particularly where the waveguides are utilized to form stacks of similar waveguides.

It will be appreciated that if light leakage into neighboring waveguides is an issue, a spacer having a pointed structure may be particularly advantageous and if mechanical rigidity of support is more crucial, a spacer with a flat plateau may be particularly advantageous.

FIGS. 12B and 12C show example embodiments of a waveguide comprising spacers of different shapes. With reference to FIG. 12B, a waveguide 1200 comprises a main optically transmissive body 1206 and spacers 1202 extending vertically from a major surface of the main body 1206. The cross section of spacers 1202 are triangles. The three-dimensional shape of the spacers may be any shape with a triangular cross section, for example, a pyramid such as shape A of FIG. 12A, a triangular prism, an elongated pyramid such as shape C of FIG. 12A. In some embodiments, waveguide 1200 may comprise surface relief features 1204 on one or more major surfaces of waveguide 1200. In some embodiments, the surface relief features 1204 may form a diffractive grating. As illustrated, the spacers 1202 extend vertically to a height greater than the top of the surface relief features 1204. Preferably, the spacers 1202 have a height sufficient to space the waveguide 1200 from an overlying waveguide by a desired separation distance, e.g., 30 μm or more. In some embodiments, the spacers 1202 have a height of 30 μm or more. Other discussions herein of waveguide 1000 and spacers 1020 may also apply to waveguide 1200 and spacers 1202, respectively. FIG. 12E shows a stack 1250 of waveguides 1200.

With reference to FIG. 12C, a waveguide 1220 comprises a main optically transmissive body 1226 and spacers 1222 extending vertically from a major surface of the main body 1226. The cross sectional shapes of spacers 1222 may be trapezoids. The three-dimensional shape of the spacers 1222 may be any shape with a trapezoidal cross section, for example, a frustum of a rectangular pyramid as shown in shapes B and D of FIG. 12A. In some embodiments, waveguide 1220 may comprise surface relief features 1224 on one or more major surfaces of waveguide 1220. In some embodiments, the surface relief features 1204 may form a diffractive grating. As illustrated, the spacers 1222 extend vertically to a height greater than the top of the surface relief features 1224. Preferably, the spacers 1222 have a height sufficient to space the waveguide 1220 from an overlying waveguide by a desired separation distance, e.g., 30 μm or more. In some embodiments, the spacers 1222 have a height of 30 μm or more. Other discussions herein of waveguide 1000 and spacers 1020 may also apply to waveguide 1220 and spacers 1222, respectively. FIG. 12F shows a stack of waveguides 1220.

In some embodiments, a waveguide may comprise spacers 1020 of varying dimensions and/or shapes. With reference to FIG. 12D, it will be appreciated that some spacers 1222 may be wider than others, for example, spacer 1222B may be wider than spacer 1222A. The widths of the spacers 1222 may vary depending upon their location on the waveguide 1240. For example, spacers 1222 at locations less likely to interact with light may be wider than spacers 1222 at locations in which the spacers 1222 which are in the active display area; in the display area, the spacers 1222 are preferably sized and spaced such that they are substantially not visible to the user. Similarly, it will be appreciated that some spacers may be different shapes than other spacers. The shape of the spacers may vary depending upon their location on the waveguide, the desired mechanical stability and strength, and other factors. For example, spacers at locations less likely to interact with light may have a shape with smaller top surface area.

With reference to FIG. 12G, a mold may also be used to form a flat cover plate for curved waveguides. As shown in FIG. 12G, the stack of waveguides comprises curved waveguides 1286, 1290, 1292. The curved waveguides may be desirable for providing a more uniform distance to the user's eye at different locations across the waveguide. However, it will be appreciated that a flat waveguide stack may be easier to interface with a mechanical frame and other optics of the wearable display system. Consequently, to provide a flat form factor, the stack of waveguides may be provided with flat cover plates 1282, 1294.

To accommodate the curvature of the waveguides, the flat cover plates may comprise a plurality of microstructures 1284, such as spacers disclosed herein. In some embodiments, the microstructures have pointed shapes. In some embodiments, the stack of waveguides 1286, 1290, 1292 are not curved in the direction of the z-axis, and the top of the microstructures 1284 may be lines extending to the direction of the z-axis. In some embodiments, the curvature of the envelope of the vertices of the microstructures 1284 may match the curvature of the stack of waveguides 1286, 1290, 1292 to provide mechanical support and protection to the waveguides 1286, 1290, 1292, while helping to maintain the curvature of those waveguides. Such outer cover plates with a plurality of microstructures may also be fabricated by casting as discussed above. The depths and/or shapes of the features in the mold for the cover plate may be selected to match the height and shape of the microstructures 1284, such that the envelope or surface defined by the vertices of the microstructures have a curvature matching the curvature of the one of the waveguides 1286, 1290, 1292 contacted by the microstructures 1284. In some embodiments, the cover plates 1282, 1294 and their associated spacers may be less deformable (e.g., stiffer) than the waveguides 1286, 1290, 1292, and the spacers of the cover plates 1282, 1294 may be utilized to conform the waveguides 1286, 1290, 1292 to a particular curvature defined by those spacers. In some embodiments, the curvature may be selected to impart a desired curvature to light outputted by the waveguides, to correspond to a particular focal depth defined by the curvature. In some embodiments, the heights of the spacers on individual ones of the waveguides 1286, 1290, 1292 may also be selected to provide different curvatures for the waveguides 1286, 1290, 1292. For example, different waveguides of the waveguide stack may have different curvatures due to differences in the heights of immediately adjacent spacers, which serve to constrain the waveguides to assume the different curvatures. In some embodiments, a first of the waveguides may be placed in contact with one of the cover plates, such that the curvature of the spacers on a cover plate imparts the desired curvature to the waveguide and other waveguides may be sequentially stacked on the waveguide that is in contact with the cover plate.

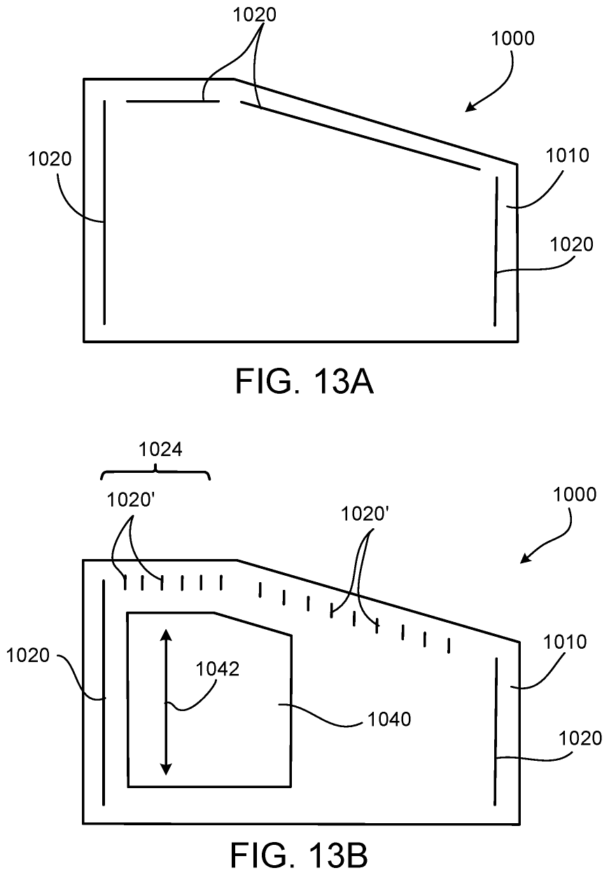

It will be appreciated that the spacers are preferably formed predominantly at locations away from the path of propagation of light between incoupling and outcoupling optical elements of a waveguide. FIGS. 13A-13B illustrate examples of top-down plan views of waveguides comprising spacers. As shown in FIG. 13A, the spacers 1020 are preferably positioned along the periphery of the waveguide 1000. It will be appreciated that the spacers 1020 may thus surround an area in which diffractive optical elements, such as incoupling and outcoupling optical elements, are disposed. As discussed herein, in some embodiments, spacers may also be provided in an area with the diffractive optical elements. In such embodiments, the spacers are preferably sized and spaced such that they are substantially not visible to the user.

In some embodiments, with reference to FIG. 13B, the spacers 1020 may be elongated along the same axis 1042 as the surface relief features 1040. In such embodiments, the spacers 1020 may include spacers having a relatively long expanse along the axis 1042, and a plurality of other spacers 1020′ having relatively shorter expenses. For example, these other spacers 1020′ may be spaced-apart and arrayed in groups 1024, with the groups of spacers spaced-apart along an axis that crosses the axis 1042. Advantageously, having the spacers 1020, 1020′ elongated along the same axis 1042 as the surface relief features 1040 may facilitate consistent manufacturing of the spacers and the surface relief features. For example, in some embodiments, the spacers and the surface relief features may be formed by imprinting using a mold that is subsequently removed by peeling the mold and the waveguide away from one another. It will be appreciated that this peeling away may be performed along the axis 1042 and that spacers or surface relief features elongated along a different axis may face an increased likelihood of breakage or deformation upon removal of the mold.

### Example Methods for Forming a Waveguide

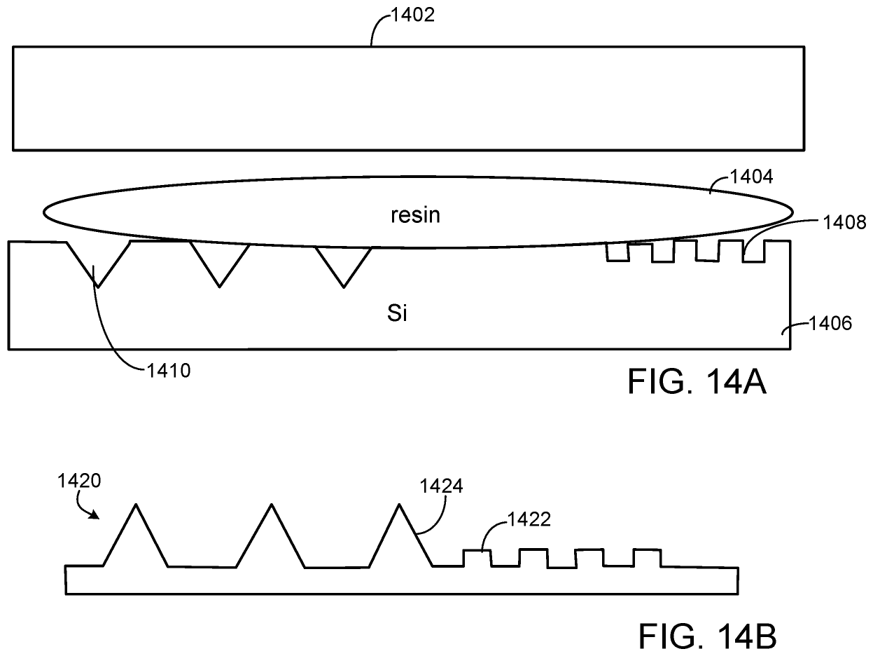

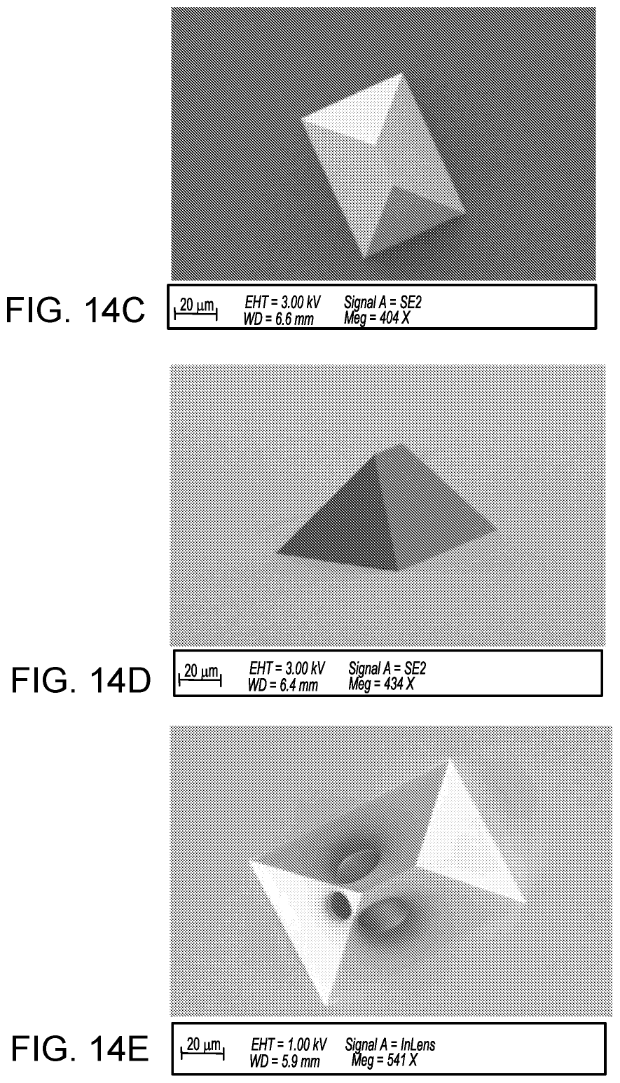

With reference now to FIGS. 14A-14B, an example of a method for forming a waveguide with spacers is illustrated. With reference to FIG. 14A, a pair of molds 1402, 1406 is provided. The mold 1406 comprises a pattern of features 1408, which may be the negative of a desired pattern to be defined in the waveguide to be formed. In some embodiments, the mold 1406 includes a plurality of large features 1410, which may be used for forming spacers in the waveguide to be formed. The depth of the large features 1410 may be between approximately 1 μm and 1000 μm in some embodiments.

A mass of material 1404 for forming the waveguide is applied on the mold 1406. The molds 1402, 1406 may be brought together to compress the material 1404 and force the material 1404 into the openings 1408 and 1410. It will be appreciated that the mold 1402 may have a flat surface, to define a flat surface of the eventual waveguide, or may have a surface with its own pattern of openings, to define protrusions in the waveguide, thereby allowing spacers and/or other features to be formed on both opposing major surfaces of the waveguide. In some embodiments, the material may subsequently be subjected to a curing process (e.g., exposure to UV light and/or heat) to harden that material. The hardened material may then be removed from the molds 1402, 1406 to form the waveguide 1420 as illustrated in FIG. 14B. As illustrated, the pattern 1408 defines the patterned structure 1422, which may be surface relief structure such as diffractive optical elements.

With continued reference to FIG. 14A, in some embodiments, the surface of mold 1402 in contact with the material 1404 may be flat. In some embodiments, additional negative patterns may be provided on the mold 1406 to form an additional structure, including surface relief features such as diffractive optical elements, spacers, and/or indentations, as desired. The negative pattern may include openings on the surface of the mold (to form, e.g., spacers and/or optical gratings) and/or protrusions on that surface (to form indentations in the eventual waveguide that is formed). In some embodiments where the mold 1406 does not include negative patterns to form indentations, the spacers of underlying waveguides simply rest on the bottom major surface of the overlying waveguides. In some embodiments where the mold 1406 includes negative patterns to form indentations, the spacers of underlying waveguides may be in contact with the matching indentations.

With reference to FIG. 14B, the molds 1402, 1406 are moved apart relative to one another. The waveguide 1420 is released from the molds, thereby forming the waveguide.

In some other embodiments, only one mold 1406 is used and the mold 1402 is not used. The material 1404 not filling the features 1410 and/or 1408 may be removed, e.g., by scrapping off the surface of the mold. In some embodiments, only microstructures formed corresponding to the large features 1410 are fabricated. For example, such microstructures may be glued to an adjacent waveguide and used as spacers to separate waveguides.

It will be appreciated that it may challenging to fully fill the large features 1410 with material. In some embodiments, the features may have a depth of approximately 1 μm and 1000 μm, to thereby form features on a waveguide with a similar height. It is has been found that filling the material into a cylinder shape large features may be difficult, while filling the material into a large feature with sharp edges may be easier. FIGS. 14C-D show examples of the fabricated microstructures using a mold having large openings with sharp edges, such as the openings 1410 (FIG. 14A). FIGS. 14C and 14D are different views of the elongated pyramid microstructure. The spacer has a width of 70 μm, a length of 110 μm and a height of 50 μm and was formed in a mold opening that was fully filled with material during a casting process. It will be appreciated that the filling performance of the etched features may be different depending on the casting speed, any mold surface treatments, and filling material properties. FIG. 14E shows an SEM image of a spacer with a bubble trapped. Notably, although there is a bubble trapped when filling the material into the etched features, the sharp edges nevertheless help the spreading of the material, with the edges guiding the material so that it reaches the bottom corner of the opening. It will be appreciated that as long as the corner is filled with material, the resulting spacer may function properly as a spacer since the height of the spacer is at the desired height. FIG. 14E shows that, in some embodiments, spacers formed in openings have the shapes disclosed herein may provide an advantageously high tolerance for air bubbles, thereby improving the uniformity of the heights of spacers formed in those openings.

With reference again to FIG. 14A, the material 1404 may be a flowable material (e.g., a flowable polymer) which may be flowed onto a surface and subsequently hardened, e.g., by curing. Preferably, the material 1404 has a high refractive index, which may provide advantages for providing a large field of view. In some embodiments, the material 1404 has a refractive index greater than 1.5, or greater than 1.65. The material 1404 forming the waveguide may be a highly transparent polymer material, e.g., an organic polymer material. Examples of high refractive index materials include polyimide-based high index resins, halogen-containing (e.g., bromine or iodine-containing) polymers, phosphorous containing polymers, thiol-ene based polymers, and high refractive index resin materials. Examples of high refractive index resin materials include those commercially available from NTT-AT of Kawasaki-shi, Kanagawa, Japan, such as the high refractive index resins sold under the name #565 and #566; and high refractive index resin materials commercially available from Akron Polymer System of Akron, Ohio, USA, such as the high refractive index resins sold under the name APS-1000, APS2004, APS-4001, and as part of the APS 3000 series.

In some embodiments, the material 1404 is a lower refractive index material (e.g., having a refractive index lower than 1.65). Examples of lower refractive index materials include organic polymer materials, low refractive index resins, sol-gel based hybrid polymers (e.g., TiO2, ZrO2, and ITO sol-gel materials), polymers doped with nanoparticles (such as TiO2, ZrO₂), and active materials (e.g., polymers doped with quantum dots). Examples of low refractive index organic polymer materials include those commercially available from Sigma-Aldrich of St. Louis, Missouri, USA, such as the polymer material sold under the names CPS 1040 UV, CPS1040 UV-A, CPS1030, CPS 1020UV, CPS 1040UV-VIS, CPS 1030 UV-VIS, and CPS 1020 UV-VIS. Examples of low refractive index resins include those commercially available from Miwon of the Nagase Group, Osaka, Japan.

In some embodiments, the waveguide may be a hybrid waveguide formed by multiple layers of different materials. For example, the hybrid waveguide may include a core layer and at least one auxiliary layer. Preferably, the core layer is formed of a highly transparent material and the auxiliary layer is formed of a thinner layer of material, in which surface relief structures, such as diffractive optical elements, are provided. In some embodiments, the material forming the core layer is a highly transparent polymer, e.g., having a transparency relay transmission of greater than 85%, greater than 90%, or greater than 96% in the visible light spectrum across the thickness of the core layer. The material may be a flowable material (e.g., a flowable polymer) which may be flowed onto a surface and subsequently hardened, e.g., by curing. The auxiliary layer may be thinner than the core layer and is preferably formed of a different material than the core layer. In some embodiments, the auxiliary layer may be formed of a material having better compatibility with molding processes then the material forming the core layer. For example, the material forming the auxiliary layer may more easily or completely fill openings in a mold than the material forming the core layer. In some embodiments, the auxiliary layer is formed of a polymer (e.g., an organic polymer), an inorganic material, a hybrid organic/inorganic material, or combinations thereof. In some embodiments, for a given thickness, the auxiliary layer may have lower transparency in the visible spectrum and/or have lower homogeneity (in composition and/or optical properties such as transparency) than the core layer. However, this lower transparency and/or lower homogeneity may be ameliorated by the relative thinness of the auxiliary layer in comparison to the core layer. Additional details regarding hybrid waveguides are disclosed in U.S. application Ser. No. 17/186,902, filed on Feb. 26, 2021, entitled METHOD OF FABRICATING MOLDS FOR FORMING EYEPIECES WITH INTEGRATED SPACERS, and U.S. application Ser. No. 17/044,798, filed on Oct. 10, 2020, entitled HYBRID POLYMER WAVEGUIDE AND METHODS FOR MAKING THE SAME, the entirety of which are incorporated by reference herein.

With reference again to FIGS. 14A-14B, it will be appreciated that the molds 1402 and 1406 may be patterned with negatives of the spacers and the surface relief features to be formed. In addition, the molds preferably have sufficient rigidity to imprint features into the various flowable materials used to form the waveguides. Examples of materials for forming the molds include glass, fused silica, quartz, silicon, and metals. Where the molds include openings, the molds are preferably formed of a crystalline material as disclosed herein.

Negatives the of features to be formed (e.g., spacers or diffractive gratings) may be defined in these materials using various processes, depending upon whether the features have vertical or inclined sidewalls. For features with vertical sidewalls, the corresponding openings in a mold for forming these features may be formed by patterning the openings in a mask layer, e.g., by photolithographically patterning a photoresist deposited on a substrate forming the mold, and then etching through the patterned mask layer using a directional etch selective for exposed material in the substrate relative to the mask layer. Examples of directional etches include dry etches such as RIE, ICP, and sputter etching. In some other embodiments, a wet etch (e.g., comprising HF) may be utilized.

For features with inclined sidewalls, corresponding openings in a mold for forming these features may be formed by patterning the openings in a mask layer, e.g., by photolithographically patterning a photoresist deposited on a substrate forming the mold, and then etching through the patterned mask layer using a wet etch selective for exposed material in the substrate relative to the mask layer. As discussed herein, the substrate is preferably formed of a crystalline material, such as crystalline silicon. Examples of wet etches for etching silicon include KOH and TMAH.

### Example Methods for Forming a Mold for Casting

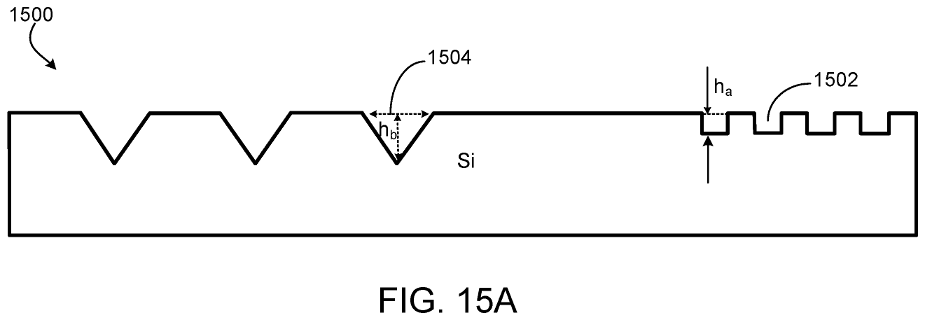

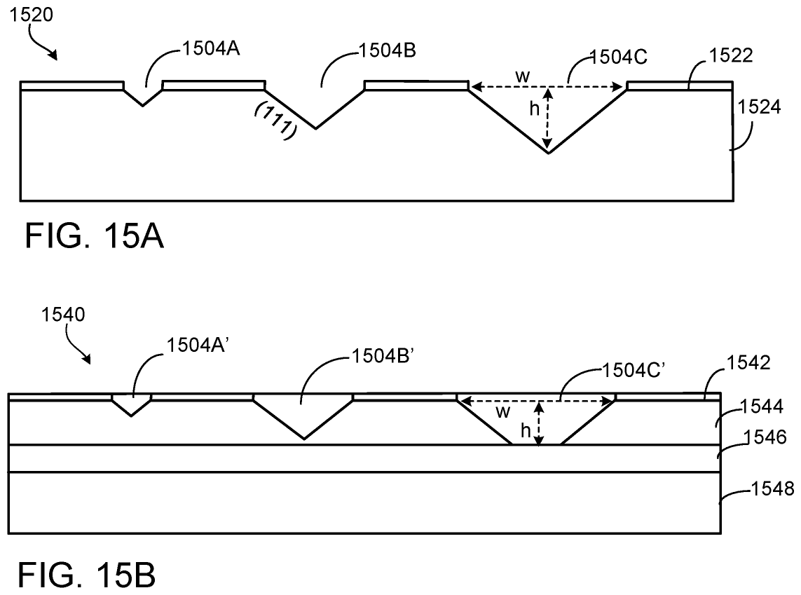

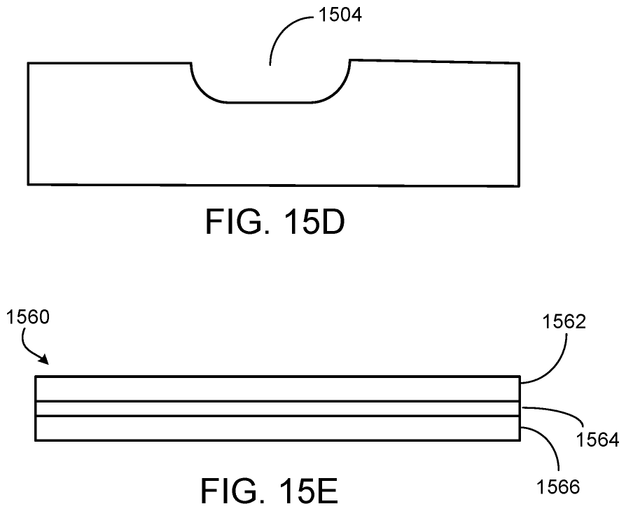

An example of a mold 1500 is shown in FIG. 15A. The mold 1500 includes a pattern of features made up of small features 1502 and large features 1504, which may be openings on the surface of the mold 1500. As examples, small features 1502 may have a height (or depth) ha between approximately 10 nm and 500 nm while large features may have a height (or depth) hb between approximately 1 μm and 1000 μm. In some embodiments, the small features 1502 correspond to diffractive optical elements and large features 1504 correspond to integrated spacers. As evident from the discussion above, it will be appreciated that small features 1502 and large features 1504 are “small” and “large” in the sense that the features 1502 are smaller than the features 1504. This difference in dimensions may apply both to the critical dimensions of the features and to the depths/heights of the features. In some embodiments, the ratios of the heights of the large features 1504 to the small features 1504 may be about 20:1 or greater, 500:1 or greater, 4000:1 or greater. Additionally, the ratio of the heights of the large features 1504 to the small features 1502 may be about 100000:1 or less.

In some embodiments, the mold 1500 does not include small features 1502. In some embodiments, the dimensions or shapes of one or more large features 1504 are different from other large features 1504 in the same mold. FIG. 15B shows another example of mold 1520. The mold 1520 includes a pattern of large features 1504A, 1504B, 1504C with different dimensions, such as different heights (or depth) and/or different sizes of openings. FIG. 15C shows another example of mold 1540 having a pattern of large features 1504A, 1504B, 1504C with different heights (or depths) and/or different shapes.

When the etch is a wet etch, it will be appreciated that the wet etch may typically etch the substrate material both vertically (downwards) and laterally, thereby forming a large feature 1504 with rounded walls or corners as illustrated in FIG. 15D. Without being limited by theory, this is understood to occur because wet etching is an isotropic process and the substrate etchant attacks both the exposed horizontal surface of the substrate and the vertical surfaces (the walls) of the opening formed in the substrate. It will be appreciated that large features 1504 formed by an isotropic wet etch may be difficult to fully fill with high index polymer such as resin during the casting process. Moreover, it will be appreciated that the depth of the features in such isotropic wet etch is normally controlled by etch rate and etch duration. Therefore, it may be hard to accurately control the depth of the large features 1504 formed by the isotropic wet etch. Furthermore, forming a mold with features of different depths may be complicated and time consuming when using an isotropic wet etch because different etch masks need to be applied to form features with different depths.

Methods described herein enable fabrication of a mold with large (e.g., micron or millimeter scale) features while maintaining low total thickness variation and surface roughness in unpatterned areas of the mold. In addition, the methods described herein enable accurate control of depths of the large features in a mold during the fabrication of the mold. The methods described herein may also enable the fabrication of a mold with large features having different depths and/or critical dimensions with simplified steps. The methods described herein may also be used to fabricate a mold for a waveguide comprising integrated millimeter scale spacers and other functional nanostructures such as diffractive optical elements. In addition, in some embodiments, openings of different tabs may be formed simultaneously, by etching a substrate through the same mask, the mask having holes of different widths, the widths corresponding to the depths of the openings to be etched.

### Wet Etch Processes

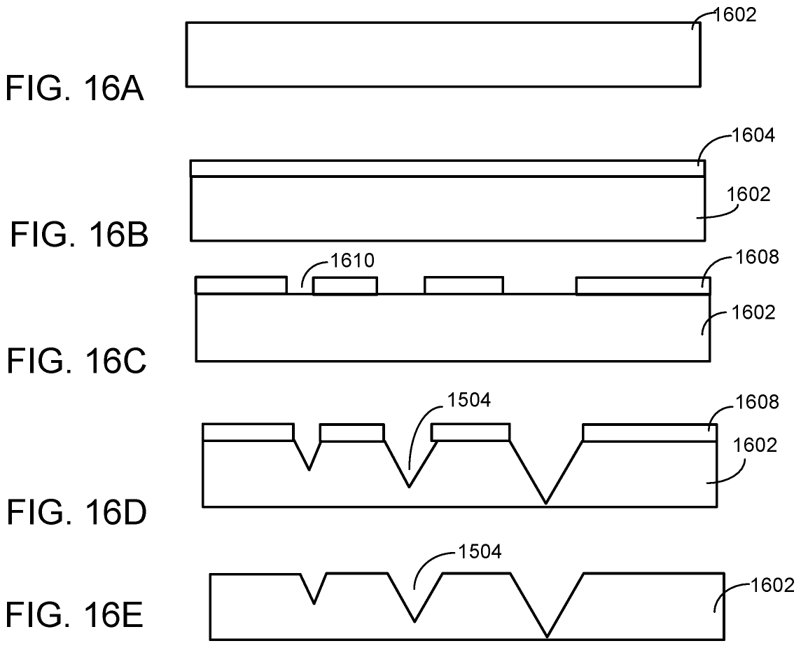

FIGS. 16A-16E show an example method for forming a mold with large features. Referring to FIG. 16A, fabrication of a mold may include providing a substrate 1602, which will be processed to form the mold as discussed herein. Preferably, the substrate 1602 has a flat, smooth surface and may have a thickness between approximately 0.3 mm and 20 mm. The substrate may have a total thickness variation (TTV) less than about 1 μm and a surface roughness (Rq) less than about 0.5 nm. In some embodiments, the substrate may comprise a single crystalline material. In some embodiments, the substrate may be single crystalline silicon or germanium. Other single crystalline materials may also be used. In some embodiments, the substrate may be a wafer. In some embodiments, the substrate may be a silicon on insulator (SOI) substrate, such as a SiO2-based SOI wafer.

FIG. 15E shows an example of a SOI substrate. With reference to FIG. 15E, the SOI wafter 1560 may comprise a single crystalline silicon layer 1562, an insulator layer 1564, and another single crystalline silicon layer 1566. The insulator layer 1564 is between and in contact with the two single crystalline silicon layers 1562 and 1566. Preferably, the top surface of the single crystalline silicon or the single crystalline silicon in the SOI substrate is not (111) plane. In some embodiments, the top surface of the single crystalline silicon is (100) or (110) plane.

With reference now to FIG. 16B, in some embodiments, a layer 1604 of selectively definable material, such as resist, such as photoresist, may be applied onto the substrate, e.g., by spin coating, and may subsequently be patterned to form a patterned layer 1608. For example, were the selectively definable material is photoresist, the layer 1604 may be patterned using a lithography process such as electron beam, ultraviolet (UV), or nanoimprint lithography.

With reference now to FIG. 16C, the patterned layer 1608 may be used as a etch mask for etching the underlying substrate 1602. In some embodiments, the etch mask 1608 may comprise a pattern of holes 1610 extending therethrough. In some embodiments, the shape of the holes 1610 may be a rectangle or a square. In some embodiments, the sizes and/or shapes of one or more of the holes 1610 may be different from the other holes 1610. The 2-dimensional sizes and shapes of the holes 1610, as seen in a top-down view, may determine the depth and 3-dimensional shape of the etched large features 1504. In some embodiments, at least one of the edges of the holes in the etch mask 1608 may be aligned in a crystal axis of the substrate 1602. For example, at least one of the edges of the holes in the etch mask 1608 may be aligned along the <110> direction, substantially parallel to the <110> direction, when the wafer is a (100) wafer.

With reference to FIG. 16D, the substrate is exposed to a wet etch, such as an edge comprising a KOH and/or TMAH solution. It will be appreciated that the openings in a mold etched by the wet etch may provide exceptional filling performance during a casting process, as discussed herein.

With continued reference to FIG. 16D, it will be appreciated that the etch rates during etching of the openings 1504 are highly dependent on the crystallographic directions of the substrate. Without being limited by theory, for material having a face-centered cubic lattice such as Si and Ge, it is believed that the rate of etching of {110} and {100} planes is faster than that of {111} planes of a single crystalline material, such that the wet etch effectively stops or slows significantly at the more stable {111} planes. Thus, the etching may automatically stop when all the {111} planes meet at a point or line, and the opening is sufficiently large that the planes extend out to meet the sidewalls of holes in the overlying etch mask; that is, without being limited by theory, the etch rate of the etch is understood to decrease substantially when the opening in the substrate is expanded such that crystal planes in the substrate meet sidewalls of the holes in the overlying etch mask with the planes extending downwards to also meet at a point or line, such that etchant “sees” only a plurality of crystal planes in contact with one another. In some embodiments, the etch may be understood to automatically stop, since the etch rate may decrease by 40% or more, 50% or more, 60% or more, 70% or more, or 80% or more, relative to the etch rate before the size of the opening is sufficiently large that crystal planes in the substrate converge at a point or line and extend upwards to meet sidewalls of the holes in the overlying etch mask, such that the etchant “sees” only a plurality of crystal planes in contact with one another.

In some embodiments, the shape of the etched large features 1504 in the substrate 1602 is determined at least partially by the slower etching planes {111}. The shape of the etched features 1504 may be at least partially determined by the alignment of the etch mask 1608 and/or the wafer crystallographic orientation of the substrate.

Advantageously, because the etch effectively stops automatically, etching of the features 1504 is highly tolerant of variations in etch duration; that is, in some preferred embodiments, once a particular depth is reached, such that the etch automatically stops, further exposure of the substrate to the etch is not expected to cause the substrate opening to further deepen. In some embodiments, the duration of exposing the substrate to the etchant may have some variation and/or may be chosen such that it is simply longer than a time needed for the etching to substantially stop, as discussed herein.

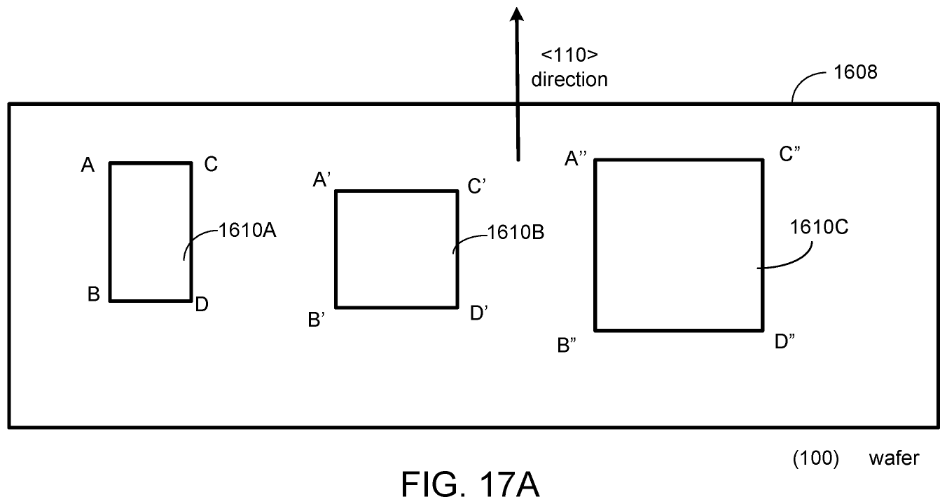

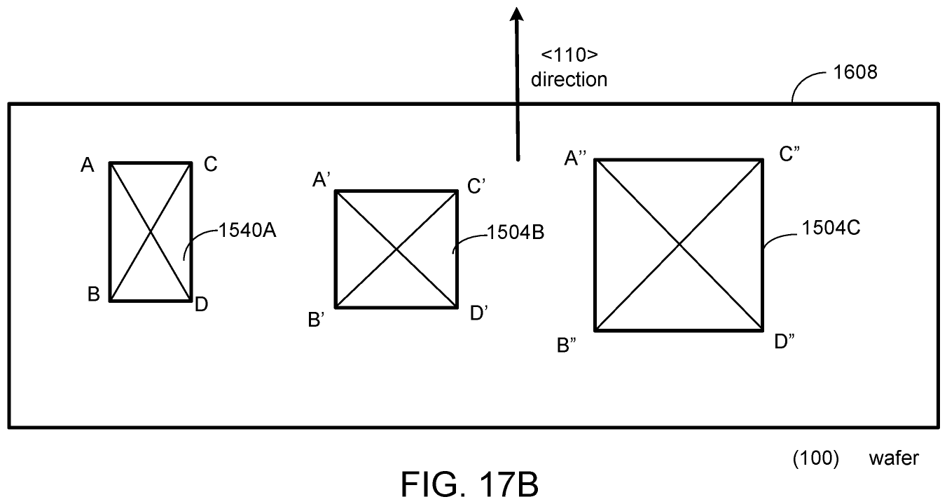

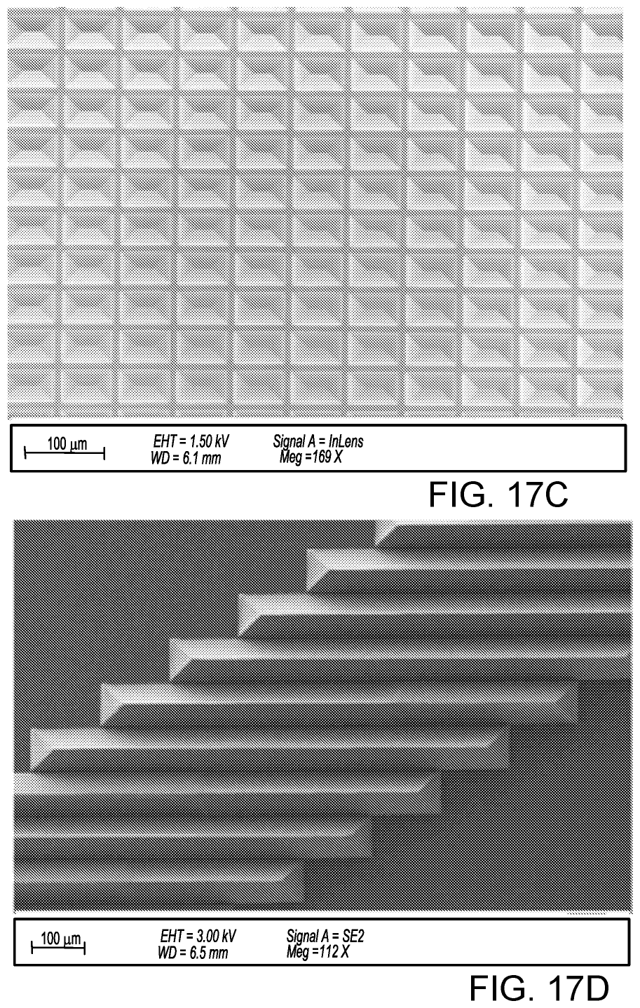

FIGS. 17A-17B show the top-down view of an example alignment directions and shapes and sizes of openings in the etch mask 1608. These figures show examples of the crystallographic orientation of the substrate 1602 before and after etching. FIG. 17A is a top-down view of the substrate 1602 covered by the etch mask 1608 before etching. With reference to FIG. 17A, in some embodiments, the holes 1610 in the etch mask 1608 may be different shapes or the same shapes. In some embodiments, the top-down view of the holes 1610 may be rectangular or square. The size of the holes 1610 may be different or the same. For example, in the top-down view, holes 1610B and 1610C may have square shapes, and holes 1610A may be rectangular in shape. In some embodiments, the pattern in the etch mask 1608 is aligned in the <110> directions as edges AB, CD, A′B′, C′D′, A″B″, C″D″ are aligned along the <110> directions. In some embodiments, the substrate 1602 is a (100) Si wafer. The shape of the holes in the etch mask is transferred to the surface of the substrate.

FIG. 17B is a top-down view of the substrate 1602 covered by the etch mask 1608 after etching. In some embodiments, after sufficient etching, the large features 1504A formed through the hole 1610A, the large feature 1504B formed through hole 1610B, and the large feature 1504C formed through hole 1610C may take the shape of an inverted pyramid. The four surfaces of the inverted pyramid may be {111} planes.

The depth of the large features 1504 may be at least partially related to the size and/or shape of the holes 1610 in the etch mask. In some embodiments, the larger the hole is, the greater the depth of the large features 1504. With reference to FIG. 15B, the hole in the etch mask 1522 corresponding to feature 1504A is smaller than the hole corresponding to feature 1504B, which is smaller than the hole corresponding to hole 1504C, and the depth of the feature 1504A is less than the depth of 1504B, which is less than the depth of feature 1504C.

The shape and/or depth of the etched features 1504 may be at least partially related to the substrate used. For example, with reference back to FIGS. 15B and 15C, molds fabricated with different substrates are shown. FIG. 15B shows an example of a mold 1520 using a substrate of single crystalline material such as a Si wafer. FIG. 15C shows an example of a mold 1540 using a SOI substrate, in which layer 1544 and 1548 are formed of single crystalline material and layer 1546 is an insulator layer. The corresponding holes in the etch mask 1522 and 1542 may be the same and the substrates in FIGS. 15B and 15C may be exposed to the same etchant for the same amount of time. Although the sizes of holes in the etch masks corresponding to 1504C and 1504C′ are the same, the heights of the etched features 1504C and 1504C′ are different because the etching in FIG. 15C stops at the insulator layer 1546. The heights of the etched features 1504B and 1504B′ are still the same since the etching in FIG. 15C stops before reaching the insulator layer 1546. With reference to 15C, the depth of an etched feature may not be larger than feature 1504C′ even if the hole corresponding to the deeper feature is larger than the hole corresponding to the feature 1504C′ because the etching of both reaches the insulator layer before the etching stops.

In some embodiments, the correlation between the depth of the etched feature and the sizes and/or shapes of the holes in the etch mask may be determined empirically, by calibration, or other means. The size of the holes in the etch mask may be precisely controlled by lithography.

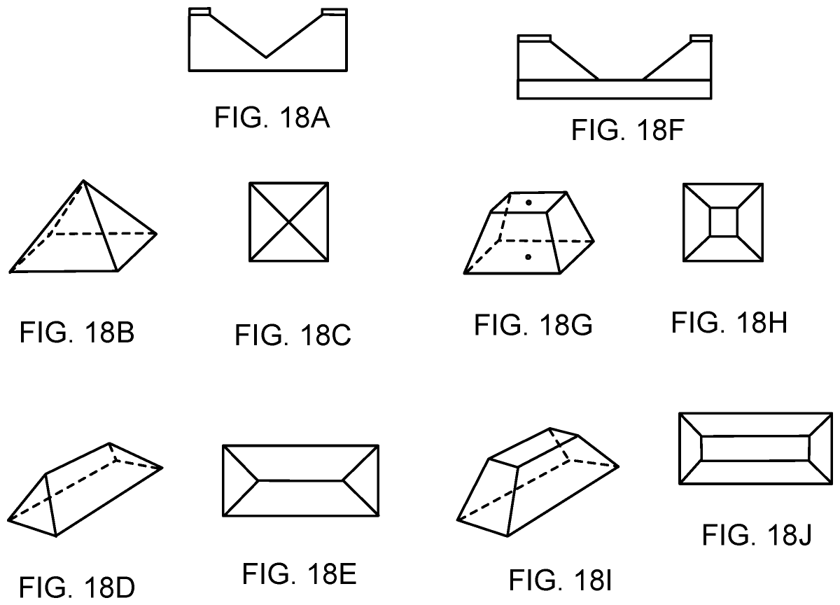

FIGS. 18A-18J show the correlation between the shape of holes in the etch mask, the substrate type, and the shape of the etched features in the substrate. FIGS. 18B-C are perspective and top-down views, respectively, of an example etched feature when the hole in the etch mask is a square and the material in a substrate exposed to etchant is only a single crystalline material. FIGS. 18D-E are perspective and top-down views different views of example etched features when the hole in the etch mask is a rectangle and the material in a substrate is a only single crystalline material. FIGS. 18G-H are perspective and top-down views of an example etched feature when the hole in the etch mask is a square and the substrate is a SOI substrate, with the insulator layer acting as an etch stop. FIGS. 18I-J are perspective and top-down views of example an etched feature when the hole in the etch mask is a rectangle and the substrate is a SOI substrate, with the insulator layer acting as an etch stop.

It will be appreciated that, in some embodiments, when a single crystalline material is used or the etching stops before reaching the insulator layer in an SOI substrate, the shapes of the etched features are pointed structures or elongated pyramids, as shown in FIGS. 18B-18E. In some embodiments, when an SOI substrate is used and the etching stops after reaching the insulator layer, the shapes of the etched features are frusta. In some embodiments, when the shape of the hole in the etch mask is a square, the etched opening in the substrate has the shape of a square pyramid or frustum of a square pyramid. In some embodiments, when the hole in the etch mask is a rectangle with sides of different lengths, the etched opening in the substrate has the shape of an elongated rectangular pyramid or a frustum.

### Example Method to Form a Mold Including Both Small and Large Features

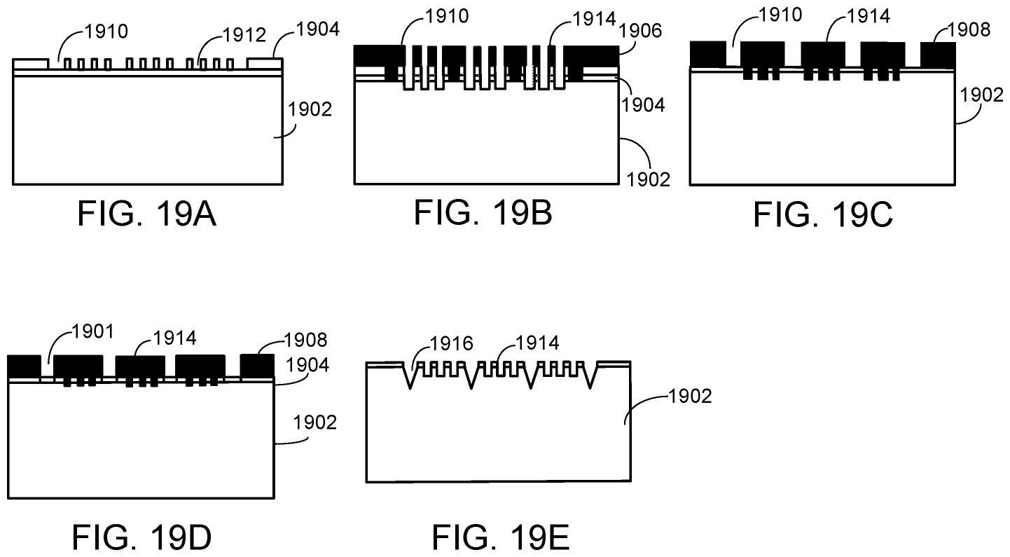

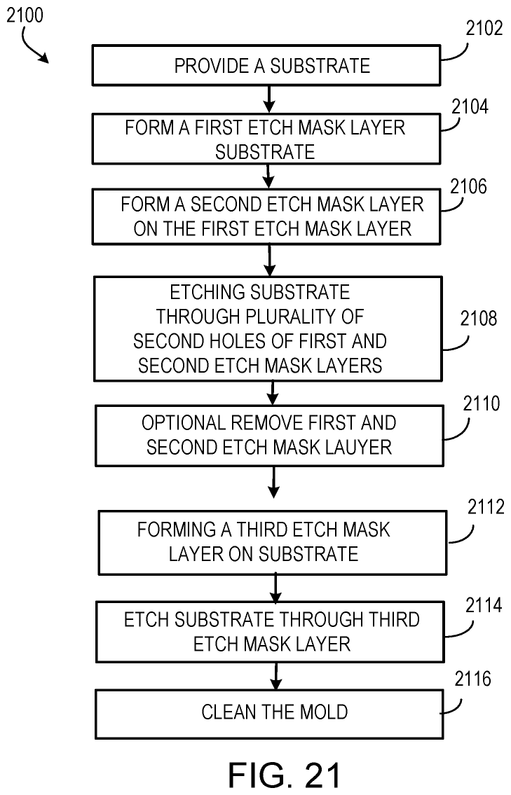

FIGS. 19A-19E show an example method of forming a mold with large features 1504 and small features 1502, such as shown in FIG. 15A. FIG. 21 shows a flow chart for fabricating a mold according to the method illustrated in FIGS. 19A-19E. Consequently, references to a “block” below corresponds to a block in FIG. 21 and references to structural reference numerals correspond to structures illustrated in FIGS. 19A-19E.

With reference to FIG. 19A and FIG. 21, at block 2102, a substrate 1902 is provided. The substrate may comprise a single crystalline material, as discussed herein. In some embodiments, the single crystalline material may comprise silicon and/or germanium. In some embodiments the substrate may be a silicon wafer. In some embodiments, the silicon wafer may be a (100) silicon Wafer.

At block 2104 (FIG. 21), a first etch mask layer 1904 may be formed on the substrate 1902, by depositing a layer of etch mask material and then patterning that layer. In some embodiments, the first etch mask layer 1904 may comprise a plurality of first holes 1910 and a plurality of second holes 1912. The plurality of first holes 1910 and a plurality of second holes 1912 may be different sizes, for example, with the first holes 1910 being larger than the second holes 1912. In some embodiments, the plurality of first holes 1910 may be aligned with a crystal axis of the single crystalline material. In some embodiments, the first holes 1910 may be aligned in a crystal axis of <110> direction, with the first holes 1910 having a rectangular opening and with a side of the rectangle parallel to the crystal axis of <110> direction, as seen in a top-down view. In some embodiments, the plurality of first holes 1910 and a plurality of second holes 1912 may be formed by photolithography and the first etch mask layer 1904 may be a photoresist layer.

At block 2106 of FIG. 21 and with reference to FIG. 19B, a second etch mask layer 1906 may be formed on the first etch mask layer 1904, by depositing a layer of etch mask material and then patterning that layer. In some embodiments, the second etch mask layer 1906 may be patterned to expose the plurality of second holes 1912 while filling and extend over the plurality of first holes 1910. In some embodiments, the second etch mask layer 1906 may be patterned by photolithography. In some embodiments, the second etch mask layer 1906 may be a photoresist layer. In some embodiments, the second etch mask layer 1906 may be a hard mask layer, such as metal layer.

At block 2108 of FIG. 21 and with continued reference to FIG. 19B, the substrate may be etched through the plurality of second holes 1912 of the first mask layer 1904 and the second etch mask layer 1906 to form a plurality of second openings 1914 corresponding to the plurality of second holes 1912. In some embodiments, the etch in this step may be a directional etch. Examples of directional etches include dry etches such as reactive-ion etching, inductively coupled plasma RIE, ion milling, or sputter etching. Details about dry etch can be found in U.S. application Ser. No. 17/186,902, filed on Feb. 26, 2021, entitled METHOD OF FABRICATING MOLDS FOR FORMING EYEPIECES WITH INTEGRATED SPACERS.

At block 2110 of FIG. 21, in some embodiments, the first and second mask layers 1904, 1906 may be removed. At block 2112 of FIG. 21 and with reference to FIG. 19C, a third etch mask layer 1908 may be formed on the substrate 1902, by depositing a layer of etch mask material and then patterning that layer. In some embodiments, the third etch mask layer 1908 may expose the plurality of first holes 1910 while extending over the plurality of second openings 1914. In some embodiments, the third etch mask layer 1908 may be patterned by photolithography. In some embodiments, the third etch mask layer 1908 may be a photoresist layer. In some embodiments, the second etch mask layer 1906 may be a hard mask layer such as metal layer, e.g., a chromium layer.

At block 2114 of FIG. 21 and with reference now to FIG. 19D, the substrate 1902 may be etched through the first plurality of holes 1901 of the third etch mask layer 1908 to form a plurality of first openings 1916 (FIG. 19E) corresponding to the plurality of first holes 1901. In some embodiments, the etch in this step is a wet etch, as disclosed herein. In some embodiments, the etchant may be a KOH or TMAH solution. In some embodiments, the duration of the etch is sufficiently long for the etch to automatically stop. It will be appreciated that when all the stable exposed crystalline planes meet at a point or a line with another stable crystalline plane, the etching may “stop”.

At block 2116 with reference to FIG. 19E, the substrate 1902 may be cleaned, and the etched substrate 1902 is now converted into a mold. In some embodiments, the plurality of second holes 1912 (FIG. 19A) are sized and spaced to define second openings 1914 for forming a diffractive grating for redirecting light of visible wavelengths. In some embodiments, the final depths of the plurality of first openings 1916 in the mold are more than about 1 micrometer, more than about 5 micrometer, more than about 10 micrometer, more than about 100 micrometers, or other depth. In some embodiments, the final depths of the plurality of second openings 1914 in the mold are less than about 500 nm, less than about 300 nm, less than about 100 nm, or less than about 50 nm.

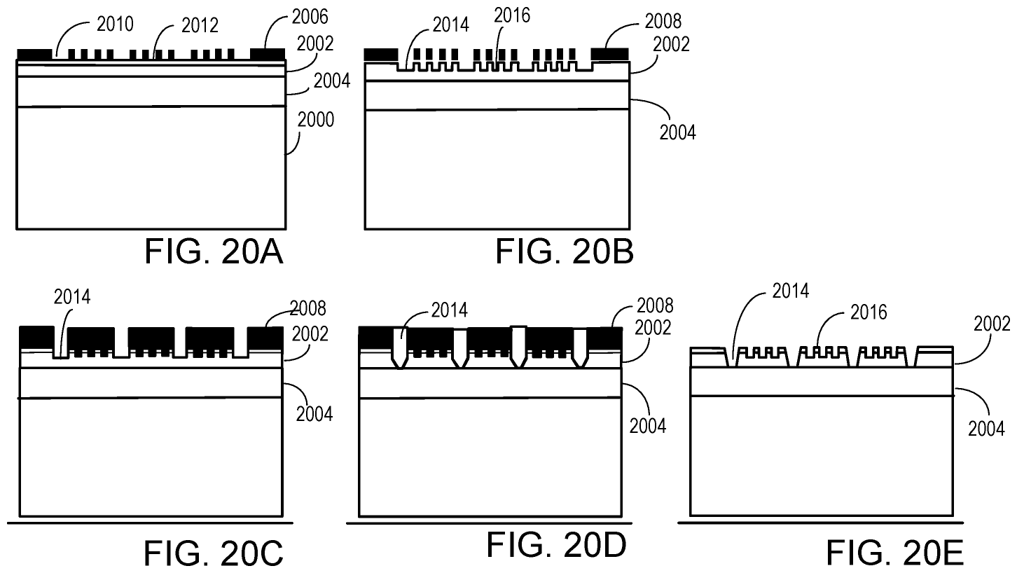

FIGS. 20A-20E show an example method of forming a mold including large features 1504 and small features 1502 as shown in FIG. 15A with an SOI substrate.

With reference to FIG. 20A, a substrate 2000 comprising a single crystalline material layer 2002 and an oxide layer 2004 is provided. In some embodiments, the single crystalline material may comprise silicon and/or germanium. In some embodiments, the oxide may be silicon oxide. In some embodiments, the orientation of the surface of the single crystalline material may be a (100) plane.

A first etch mask layer 2006 may then be formed on the substrate 2000, by depositing a layer of etch mask material and then patterning that layer. In some embodiments, the first etch mask layer 2006 may comprise a plurality of first holes 2010 and a plurality of second holes 2012. In some embodiments, the plurality of first holes 2010 may be aligned with a crystal axis of the single crystalline material layer 2002, with the first holes 2010 having a rectangular opening and with a side of the rectangle parallel to the crystal axis of <110> direction, as seen in a top-down view. In some embodiments, the plurality of first holes 2010 and the plurality of second holes 2012 may be formed by photolithography. The first etch mask layer 2006 may be a photoresist layer.

With reference to FIG. 20B, the substrate 2000 may be etched through the plurality of first holes 2010 and the plurality of second holes 2012 of the first etch mask 2006 to form a plurality of first openings 2014 corresponding to the plurality of first holes 2010 and a plurality of second openings 2016 corresponding to the plurality of second holes 2012 to a desired depth. In some embodiments, the desired depth may correspond to the height of small features 1502. In some embodiments, the etch in this step may be a directional etch such as dry etch. Examples of directional etches include dry etches such as reactive-ion etching, inductively coupled plasma RIE, ion milling, or sputter etching. Details about dry etch can be found in U.S. application Ser. No. 17/186,902, filed on Feb. 26, 2021, entitled METHOD OF FABRICATING MOLDS FOR FORMING EYEPIECES WITH INTEGRATED SPACERS.

With reference to FIG. 20C, the first etch mask layer may be optionally removed. A second etch mask layer 2008 may be formed on substrate 2000, by depositing a layer of etch mask material and then patterning that layer. In some embodiments, the second etch mask layer 2008 may expose the plurality of first openings 2014 while extend over and protecting the plurality of second openings 2012. In some embodiments, the second etch mask layer may be formed by photolithography and the second etch mask layer 2008 may be a photoresist layer.

With reference to FIG. 20D, the substrate 2000 may be etched through the second etch mask layer 2008 and to further etch the plurality of first openings 2014. In some embodiments, the etch in this step is a wet etch. In some embodiments, the etchant may comprise a KOH or TMAH solution. In some embodiments, the duration of the etch is sufficiently long for the etch to automatically stop, and the shape of the plurality of first openings 2014 may be a truncated frustum with a flat bottom. It will be appreciated that the etching stops when the etching reaches the oxide layer 2004. If the etching stops before reaching the oxide layer 2004, it may be because the first holes 2010 were sized sufficiently narrow such that all the stable crystalline planes in the etched substrate meet at a point or a line with another stable crystalline plane and the shape of the plurality of first openings 2014 may be pyramid or elongated pyramid depending on the shape of the plurality of first holes 2010. With reference to FIG. 20E, the substrate may be cleaned, and a mold is formed.

In some embodiments, the plurality of second holes 2012 are sized and space for defining a diffractive grating for redirecting light of visible wavelengths. In some embodiments, the final depths of the plurality of first openings 2014 in the mold are more than about 1 micrometer, more than about 5 micrometer, more than about 10 micrometer, or more than about 100 micrometers. In some embodiments, the final depths of the plurality of second openings 2016 in the mold are less than about 500 nm, less than about 300 nm, less than about 100 nm, or less than about 50 nm.

### Partial Etching

It will be appreciated that some photoresists may not provide the desired masking capability when exposed to in some etchants, such as KOH. A “partial” etching method discussed herein may provide good making capability during the etching.

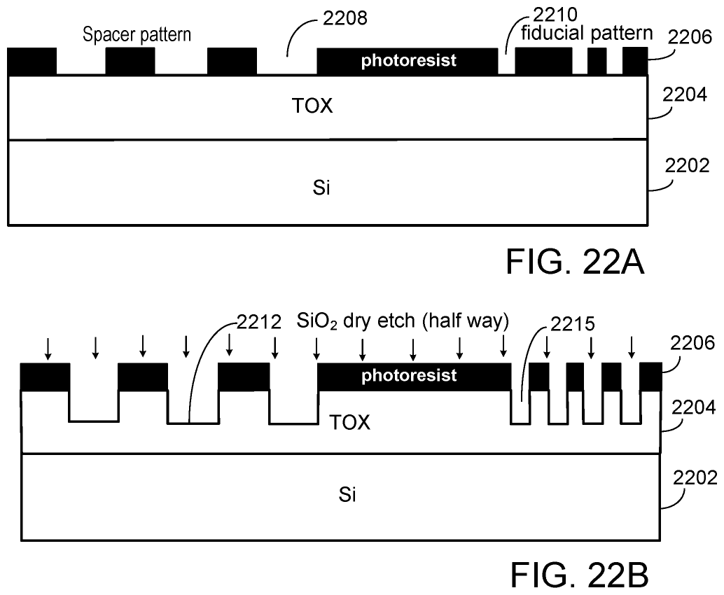

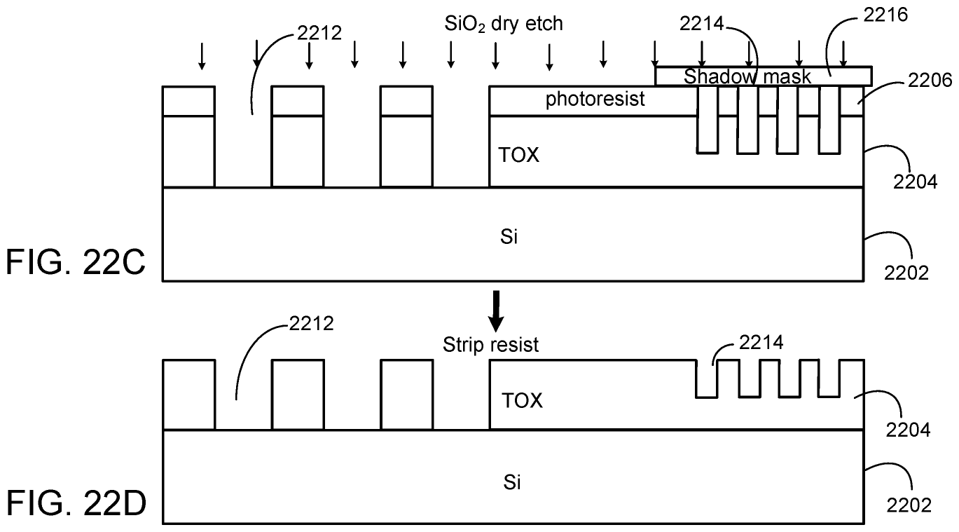

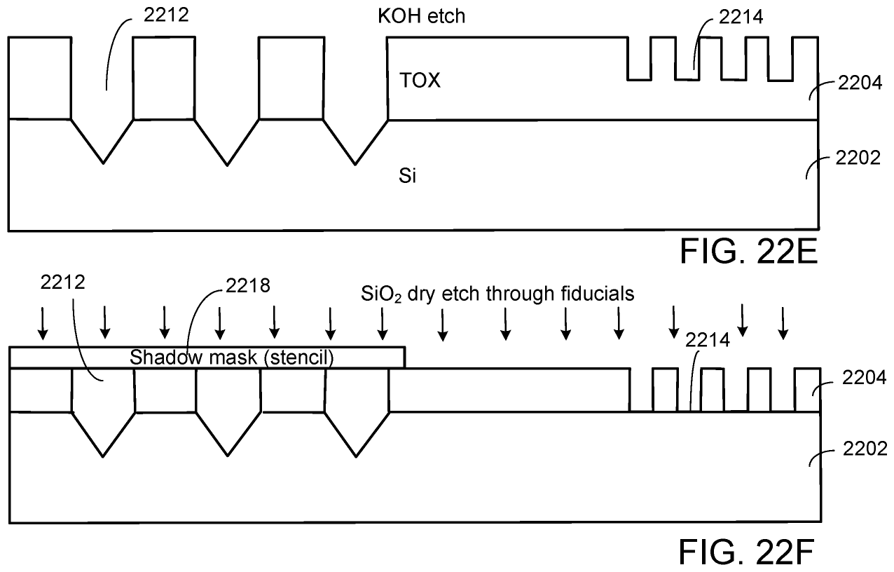

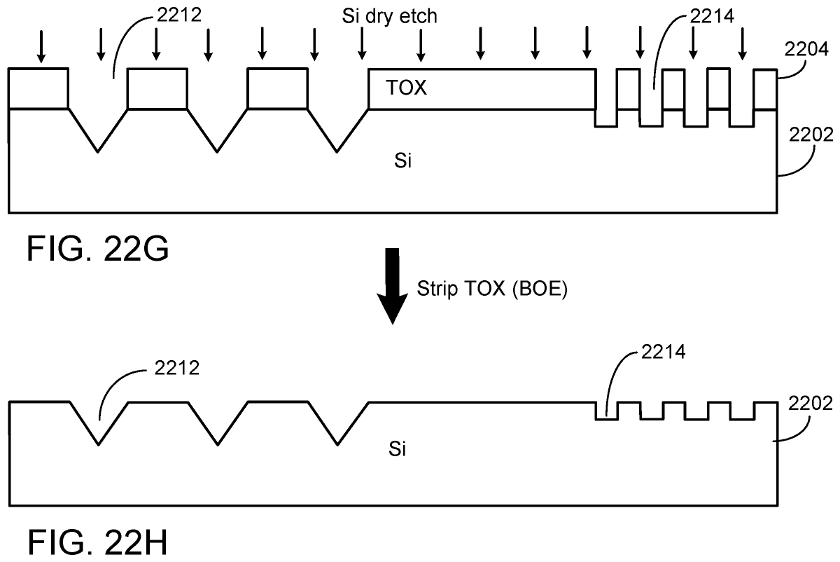

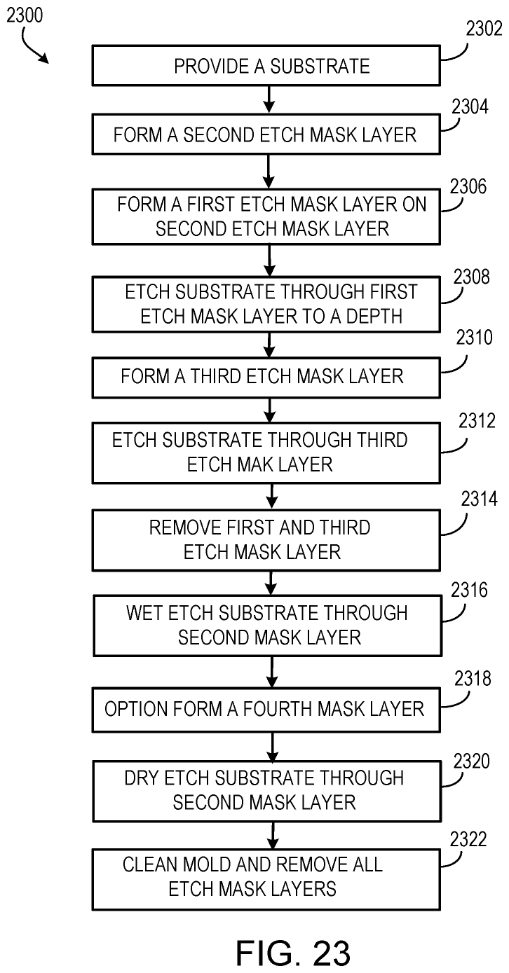

FIGS. 22A-H shows an example partial etching method to form a mold including small features and large features. FIG. 23 is an example flow chart of the actions involved with forming the structures of FIGS. 22A-H.

At block 2302 of FIG. 23 and with reference to FIG. 22A, a substrate 2202 is provided. The substrate may comprise a single crystalline material such as a single crystalline silicon substrate or a silicon-on-insulator (SOI) substrate. In some embodiments, the orientation of the surface of the single crystalline material may be a (100) plane. In some embodiments, the single crystalline material may comprise silicon and/or germanium.

At block 2304 of FIG. 23, a second etch mask layer 2204 may be formed on the substrate 2202. In some embodiments, the second etch mask layer may be a thermal oxide layer. In some embodiments, the second etch mask layer may be silicon oxide. In some embodiments, the substrate is has a thermal oxide layer naturally formed on top of the single crystalline layer. In some other embodiments, the thermal oxide may be formed by exposure to an oxidant and heat.

At block 2306 of FIG. 23, a first etch mask layer 2206 may be formed on the second etch mask layer 2204. In some embodiments, the first etch mask layer 2206 may comprise a plurality of first holes 2208 and a plurality of second holes 2210. In some embodiments, the plurality of first holes 2208 may be aligned with a crystal axis of the single crystalline material. In some embodiments, the first holes 2208 may be aligned in a crystal axis of <110> directions, with the first holes 2208 having a rectangular opening and with a side of the rectangle parallel to the crystal axis of <110> direction, as seen in a top-down view. In some embodiments, the first etch mask layer 2210 may be formed by photolithography. The first etch mask layer 2210 may be a photoresist layer.

At block 2308 of FIG. 23 and with reference to FIG. 22B, the second etch mask layer may be etched through the first etch mask layer to a depth to form a plurality of first openings 2212 corresponding to the plurality of first holes 2208 and a plurality of second openings 2214 corresponding to the plurality of second holes 2210. In some embodiments, the depth is less than the thickness of the second etch mask layer. In some embodiments, the etch in this step may be a directional etch such as dry etch. Examples of directional etches include dry etches such as reactive-ion etching, inductively coupled plasma RIE, ion milling, or sputter etching. Details about dry etch can be found in U.S. application Ser. No. 17/186,902, filed on Feb. 26, 2021, entitled METHOD OF FABRICATING MOLDS FOR FORMING EYEPIECES WITH INTEGRATED SPACERS.

At block 2310 of FIG. 23 and with reference to FIG. 22C, a third etch mask layer 2216 may be formed on the substrate. In some embodiments, the third etch mask layer 2216 may expose the plurality of first openings 2212 while extending over the plurality of second openings 2214. In some embodiments, the third etch mask layer 2216 is a shadow mask or a stencil mask. In some embodiments, the third mask layer 2216 is formed by lithography. In some embodiments, the third mask layer 2216 comprises photoresist. In some embodiments, the third mask layer 2216 is a hard mask and may comprise an oxide or metal.

In block 2312 of FIG. 23 and with reference to FIG. 22C, the second etch mask layer 2204 maybe etched through the third etch mask layer 2216 until the plurality of first openings 2212 extend to the layer of crystalline material. In some embodiments, the etch in this step may be a directional etch such as dry etch. Examples of directional etches include dry etches such as reactive-ion etching, inductively coupled plasma RIE, ion milling, or sputter etching. Details about dry etch can be found in U.S. application Ser. No. 17/186,902, filed on Feb. 26, 2021, entitled METHOD OF FABRICATING MOLDS FOR FORMING EYEPIECES WITH INTEGRATED SPACERS.

In block 2314 of FIG. 23 and with reference also to FIG. 22D, the first etch mask layer 2206 and the third etch mask layer 2216 are removed. In block 2316 of FIG. 23 and with reference to FIG. 22E, the substrate 2202 may be etched through the second etch mask layer 2204. In some embodiments, the etch in this step is a wet etch. In some embodiments, the etchant may be KOH or TMAH solution. In some embodiments, the duration of the etch is sufficiently long for the etch to automatically stop, and the shape of the plurality of first holes may be a truncated frustum with a flat bottom. The etching may automatically stop when all the exposed stable crystalline planes meet at a point or a line with another exposed stable crystalline plane and the shape of the plurality of first openings may be pyramid or elongated pyramid depending on the shape of the plurality of first openings.

In block 2318 of FIG. 23 and with reference to FIG. 22F, a fourth etch mask 2218 may be formed on the second etch mask layer 2204. In some embodiments, the fourth etch mask layer 2218 may be omitted. In some embodiments, the fourth etch mask 2218 may expose the plurality of second openings 2214 while extending over the plurality of first openings 2214.

At block of 2320 of FIG. 23 and with reference to FIG. 22G, the substrate 2202 may be further etched through the second etch mask layer 2204 until the plurality of second openings reach a desired depth in the layer of crystalline material. In some embodiments, the etch in this step may be a directional etch such as dry etch. Examples of directional etch include dry etches such as reactive-ion etching, inductively coupled plasma RIE, ion milling, or sputter etching. Details about dry etch can be found in U.S. application Ser. No. 17/186,902, filed on Feb. 26, 2021, entitled METHOD OF FABRICATING MOLDS FOR FORMING EYEPIECES WITH INTEGRATED SPACERS.

At block 2322 of FIG. 23 and with reference to FIG. 22H, all the etch mask layers may be removed, the substrate may be cleaned and a mold is formed.

In some embodiments, the plurality of second holes 2214 are sized and spaced to define a diffractive grating for redirecting light of visible wavelengths. In some embodiments, the final depths of the plurality of first openings 2212 in the mold are more than about 1 micrometer, more than about 5 micrometer, more than about 10 micrometer, or more than about 100 micrometers. In some embodiments, the final depths of the plurality of second openings 2214 in the mold are less than about 500 nm, less than about 300 nm, less than about 100 nm, or less than about 50 nm.

### Applications

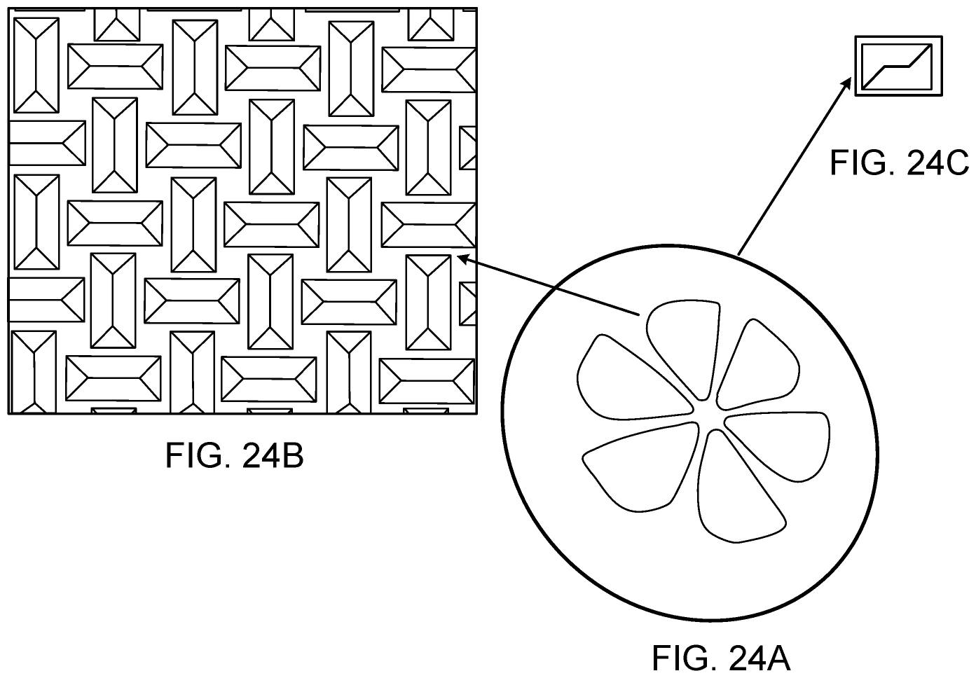

FIG. 24A shows an image of example wet etched mold on a 200 mm Si wafer. FIG. 24B is an SEM image of the edge of the eye piece (EP). FIG. 24C shows an SEM image of a single spacer formed in the active area of eye piece, where light with image information may be outputted to form images. In some embodiments, there may be a plurality of spacers, e.g., 1-20 spacers, distributed inside the active area of the waveguide, the spacers being used to maintain a certain distance between the neighboring waveguides. On the edge of an eyepiece, glue will be applied to seal the EP stack, and preferably a high density of spacers are arranged at the edge of the eyepiece to provide strong mechanical support.

In some embodiments, a “maze” pattern may be used to make the glue spreading more isotropic, such as the pattern shown in FIG. 24B. FIGS. 17C and 17D shows other edge patterns of an eye piece. These patterns may form channels. In FIG. 17C, the channels are arranged both horizontally and vertically to guide the glue into a desired area. In FIG. 17D, the channels are arranged horizontally to guide the glue into the desired area. In some embodiments, the “maze” pattern such as the pattern in FIG. 24B may break the channels to help the glue spreading more evenly comparing to other patterns.

### Example System for Checking Flatness or Curvature

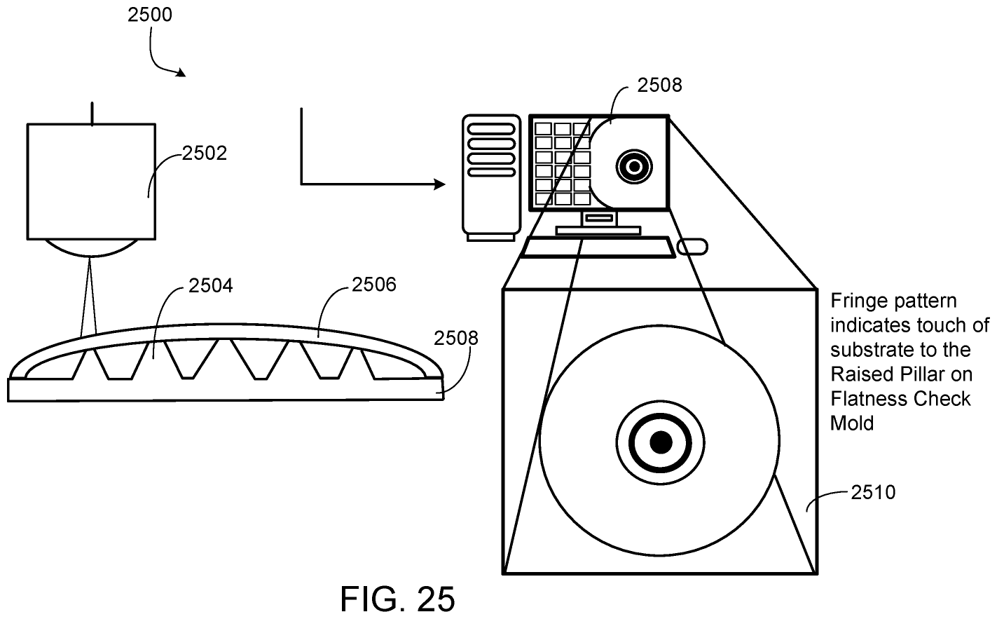

With reference to FIG. 25, an example of system 2500 to check the flatness or curvature of a sample is illustrated. In some embodiments, the system 2500 may comprise a platform 2508 to hold a sample 2506 to be tested, and a detector 2502 to collect the light reflected by the sample 2506. In some embodiments, the system 2500 may further comprise a light source to illuminate the sample.

In some embodiments, the platform 2508 may comprises a pattern of microstructures 2504. In some embodiments, the microstructures may be pointed microstructures. The arrangement and the heights of the microstructures are configured such that the envelope or curve defined by the vertices of the microstructures may have a curvature that is the desired curvature of the sample.

When a sample 2506 is placed on the platform 2508, the light reflected and collected by the detector 2503 may have a fringe pattern such as a Newton's ring. If the there is such a fringe pattern, the sample 2506 is in contact with the microstructure 2504. In some embodiments, a reflectometry may be used to determine whether the sample is in contact with the microstructure at a certain point. If there is no air gap detected by the reflectometry, the sample and the microstructure 2504 are understood to be in contact at that point.

If the curvature of the sample matches the curvature of the envelope of the vertices of the microstructures, the sample 2506 will be in contact with each vertex of the microstructures and have a fringe pattern indicating the contact at each point or at most of the points. It will be appreciated that the method to check the flatness or curvature herein has the advantage of convenience and may be used for quality control. For example, one or more samples may be selected from a batch to provide process feedback.

In some embodiments, envelope or surface defined by the vertices of the microstructures may be a flat surface, which may be used to check the flatness of the sample.

In some embodiments, the platform 2508 may be fabricated by casting, similar to the method for forming a waveguide discussed above. In some embodiments, the method to form a mold to cast a platform 2508 may be similar to the mold forming methods discussed above. In some embodiments, the shape of the holes in the etch mask may be square. In some embodiments, the size of each hole may be at least partially related to the height of the corresponding microstructure 2504.

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than restrictive sense.

Indeed, it will be appreciated that the systems and methods of the disclosure each have several innovative aspects, no single one of which is solely responsible or required for the desirable attributes disclosed herein. The various features and processes described above may be used independently of one another, or may be combined in various ways. All possible combinations and subcombinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination. No single feature or group of features is necessary or indispensable to each and every embodiment.

It will be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Accordingly, the claims are not intended to be limited to the embodiments shown herein, but are to be accorded the widest scope consistent with this disclosure, the principles and the novel features disclosed herein.

1. A method for forming a mold for casting, the method comprising:
providing a substrate comprising a layer of single crystalline material;
forming an etch mask layer on the substrate, the etch mask layer having a pattern of holes extending therethrough, the holes aligned with a crystal axis of the layer of single crystalline material; and
etching the substrate through the etch mask layer to form openings in the substrate, wherein the mold comprises the etched substrate.

2. The method of claim 1, wherein the single crystalline material is silicon or germanium.

3. The method of claim 2, wherein the substrate is a silicon on insulator (SOI) substrate.

4. The method of claim 2, wherein the layer of single crystalline material is not (111) oriented.

5. The method of claim 1, wherein 2-dimensional shape, as seen in a top-down view, of at least one hole in the etch mask is a rectangle.

6. The method of claim 5, wherein the shape of an opening in the substrate corresponding to the at least one hole is an inverted pyramid or an inverted frustum.

7. The method of claim 6, wherein a thickness of the single crystalline material is larger than a depth of the opening, and the 3-dimensional shape of the opening is an inverted pyramid.

8. The method of claim 1, wherein aligning the holes with a crystal axis comprises aligning at least one edge of the holes with a crystal axis so that the at least one edge is parallel with the crystal axis.

9. The method of claim 1, wherein the substrate is a (100) silicon wafer and the crystal axis is one of <110> crystal axes.

10. The method of claim 1, wherein the pattern of holes comprises holes of different sizes, wherein the openings corresponding to the pattern of holes have different depths.

11. The method of claim 1, wherein the etch mask layer comprises photoresist.

12. The method of claim 1, wherein etching the substrate through the etch mask layer comprises subjecting the substrate to a wet etch.

13. The method of claim 1, further comprising removing the etch mask layer after etching the substrate.

14. The method of claim 1, wherein a depth of one or more of the openings in the substrate is more than about 1 micrometer.

15. A method for forming a mold for casting, the method comprising:
providing a substrate comprising a layer of single crystalline material;
forming a first etch mask layer on the substrate, the first etch mask layer comprising a plurality of first holes and a plurality of second holes, the plurality of first holes aligned with a crystal axis of the single crystalline material;
forming a second etch mask layer on the first etch mask layer, the second etch mask layer exposing the plurality of second holes while extending over the plurality of first holes;
etching the substrate through the plurality of second holes of the first and second etch mask layers to form a plurality of second openings corresponding to the plurality of second holes;
forming a third etch mask layer on the substrate, the third etch mask layer exposing the plurality of first holes while extending over the plurality of second openings; and
etching the substrate through the third etch mask layer to form a plurality of first openings corresponding to the plurality of first holes.

16. The method of claim 15, wherein further etching the substrate through the third etch mask layer automatically stops at a stable crystalline plane.

17. The method of claim 15, wherein the plurality of second holes are sized and spaced to define a diffractive grating for redirecting light of visible wavelengths.

18. The method of claim 15, wherein final depths of the plurality of first openings in the mold are more than about 1 micrometer.

19. The method of claim 18, wherein final depths of the plurality of second openings in the mold are less than about 500 nm.

20. The method of claim 15, wherein etching the substrate through the plurality of second holes of the first and second etch mask layers comprises a dry etch.

21. The method of claim 15, wherein etching the substrate through the third etch mask layer comprises a wet etch.

22. The method of claim 15, wherein the single crystalline material comprises one or both of silicon and germanium.

23. The method of claim 15, wherein the substrate is a silicon wafer or a silicon on insulator (SOI) substrate.

24. The method of claim 15, wherein the layer of single crystalline material is not (111) oriented.

25. The method of claim 15, wherein the first etch mask layer comprises photoresist.

26. The method of claim 15, wherein the second etch mask layer comprises photoresist.

27. The method of claim 15, further comprising removing the first and second etch mask layers before forming the third etch mask layer.

28. The method of claim 15, further comprising removing the third etch mask layer.

29. (canceled)

30. A method for forming a mold for casting, comprising:
providing a substrate comprising a layer of single crystalline material and a second etch mask layer on the single crystalline material;
forming a first etch mask layer on the second etch mask layer, the first etch mask layer comprising a plurality of first holes and a plurality of second holes, the plurality of first holes aligned with a crystal axis of the single crystalline material;
etching the substrate through the first etch mask layer to a depth to form a plurality of first openings corresponding to the plurality of first holes and a plurality of second openings corresponding to the plurality of second holes, wherein the depth is less than thickness of the first etch mask layer;
forming a third etch mask layer on the substrate, the third etch mask layer exposing the plurality of first openings while extending over the plurality of second openings;
etching the second etch mask layer through the third etch mask layer until the plurality of first openings extend to the layer of crystalline material;
removing the first etch mask layer and the third etch mask layer; etching the substrate through the second etch mask layer;
further etching the substrate through the second etch mask layer until the plurality of second openings reach a desired depth in the layer of crystalline material; and
removing the second etch mask layer.

31. The method of claim 30, further comprising forming a fourth etch mask layer on the second etch mask layer, the fourth etch mask layer exposing the plurality of first openings while extending over the plurality of second openings before further etching through the second etch mask layer.

32. The method of claim 30, wherein etching the substrate through the first etch mask layer comprises a dry etch.

33. The method of claim 30, wherein etching the substrate through the third etch mask layer comprises a dry etch.

34. The method of claim 30, wherein etching the substrate through the second etch mask layer comprises a wet etch.

35. The method of claim 30, wherein further etching the substrate through the second etch mask layer comprises a dry etch.

36. The method of claim 30, wherein the plurality of second holes are sized and spaced to define a diffractive grating for redirecting light of visible wavelengths.

37. The method of claim 30, wherein final depths of the plurality of first openings in the mold are more than about 1 micrometer.

38. The method of claim 37, wherein final depths of the plurality of second openings in the mold are less than about 500 nm.

39. The method of claim 30, wherein the first etch mask layer comprises photoresist.

40. The method of claim 30, wherein the second etch mask layer comprises silicon oxide.

41. The method of claim 30, wherein the third etch mask layer comprises metal.

42. The method of claim 30, wherein the fourth etch mask layer comprises metal.

43-63. (canceled)
